(19) United States
(12) Patent Application Publication
(10) Pub. No.: US 2025/0226277 A1
(43) Pub. Date: Jul. 10, 2025

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Sam Vaziri, San Jose, CA (US); Isha Datye, Hsinchu (TW); Xinyu BAO, Fremont, CA (US)

(73) Assignee: Taiwan Semiconductor Manufacturing Company, Ltd., Hsinchu (TW)

(21) Appl. No.: 18/407,342

(22) Filed: Jan. 8, 2024

(51) Int. Cl. H01L 23/36; H01L 21/768; H01L 23/31; H01L 23/48; H01L 25/065

(52) U.S. Cl. CPC H01L 23/36; H01L 21/76898; H01L 23/3107; H01L 23/481; H01L 25/0657

(57) ABSTRACT

A semiconductor device includes a semiconductor substrate, an interconnect, and at least one thermal via. The semiconductor substrate includes at least one active component. The interconnect is disposed over and electrically coupled to the at least one active component. The at least one thermal via penetrates through the interconnect and is thermally coupled to the at least one active component, where a thermal conductivity of the at least one thermal via is different than a thermal conductivity of a dielectric layer of the interconnect.

### BACKGROUND

Developments in shrinking sizes of semiconductor devices and electronic components make the integration of more devices and components into a given volume possible and lead to high integration density of various semiconductor devices and/or electronic components.

### BRIEF DESCRIPTION OF THE DRAWINGS

Aspects of the disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 21 are schematic cross-sectional views of various stages in a manufacturing method of a semiconductor device in accordance with some embodiments of the disclosure.

FIG. 22 through FIG. 27 are schematic cross-sectional views respectively showing a semiconductor device in accordance with alternative embodiments of the disclosure.

FIG. 28 and FIG. 31 are schematic plane views showing a positioning configuration of a hotspot and a thermal control element included in a semiconductor device in accordance with various embodiments of the disclosure.

FIG. 32 through FIG. 37 are schematic three-dimensional side-views respectively illustrating various configurations of a thermal via in accordance with some embodiments of the disclosure.

FIG. 38 to FIG. 41 are schematic cross-sectional views of various stages in a manufacturing method of a semiconductor device in accordance with some embodiments of the disclosure.

FIG. 42 through FIG. 43 are schematic cross-sectional views respectively showing a semiconductor device in accordance with alternative embodiments of the disclosure.

FIG. 44 is a schematic cross-sectional view showing an application of a semiconductor device in accordance with some embodiments of the disclosure.

### DETAILED DESCRIPTION

The following disclosure provides many different embodiments, or examples, for implementing different features of the provided subject matter. Specific examples of components, values, operations, materials, arrangements, or the like, are described below to simplify the disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first”, “second”, “third”, “fourth”, and the like, may be used herein for ease of description to describe similar or different element(s) or feature(s) as illustrated in the figures, and may be used interchangeably depending on the order of the presence or the contexts of the description.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

It should be appreciated that the following embodiment(s) of the disclosure provides applicable concepts that can be embodied in a wide variety of specific contexts. The specific embodiment(s) described herein is related to a semiconductor device (or a semiconductor package or structure) having a stacking structure of multi-tiers each including at least one semiconductor die or chip, and is not intended to limit the scope of the disclosure. Due to a thermal control element of thermal energy storage material being adopted in an interconnect of one or more tiers of the stacking structure, the thermal management of the semiconductor device is well-controlled. That is, a heat dissipation of a hotspot of the semiconductor device is greatly improved, thereby obtaining a better reliability of the semiconductor device. In embodiments of the disclosure, the thermal control element of thermal energy storage material may be disposed in the interconnect of one or more tiers of the stacking structure, where the thermal control element of thermal energy storage material each may include a vertical portion and a horizontal portion connecting to the vertical portion, where the thermal control element of thermal energy storage material may be formed to penetrate through one or more dielectric layers of the interconnect(s) of one or more tiers of the stacking structure. In a non-limiting example, the vertical portion of the thermal control element of thermal energy storage material may be in form of a pillar or a column shape next to or surrounding the hotspot. In a non-limiting example, on the other hand, the horizontal portion of the thermal control element of thermal energy storage material may be in form of a segment, slab or plate shape next to or overlapped with the hotspot. The disclosure is not specifically limited to the embodiments disclosed herein, any combination of the vertical portion and the horizontal portion of the thermal control element of thermal energy storage material mentioned herein may be adopted.

In some embodiments, the manufacturing method is part of a wafer level packaging process. It is understood that additional processes may be provided before, during, and after the illustrated method, and that some other processes may only be briefly described herein. In the disclosure, it should be appreciated that the illustration of components throughout all figures is schematic and is not in scale. Throughout the various views and illustrative embodiments of the disclosure, the elements similar to or substantially the same as the elements described previously will use the same reference numbers, and certain details or descriptions (e.g., the materials, formation processes, positioning configurations, electrical connections, etc.) of the same elements would not be repeated. For clarity of illustrations, the drawings are illustrated with orthogonal axes (X, Y and Z) of a Cartesian coordinate system according to which the views are oriented; however, the disclosure is not specifically limited thereto.

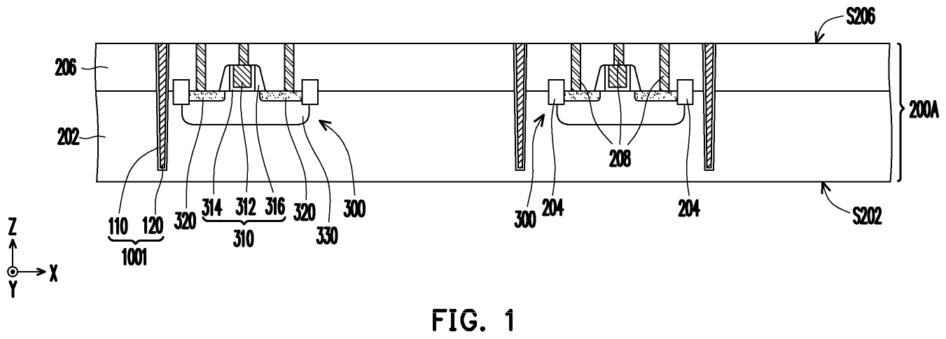

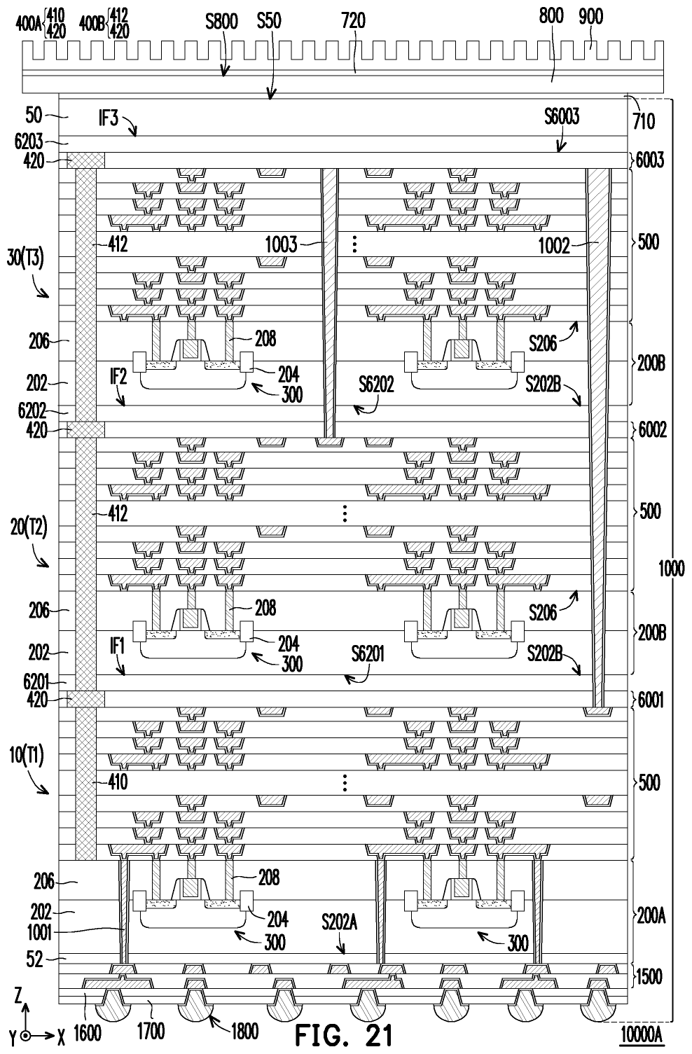

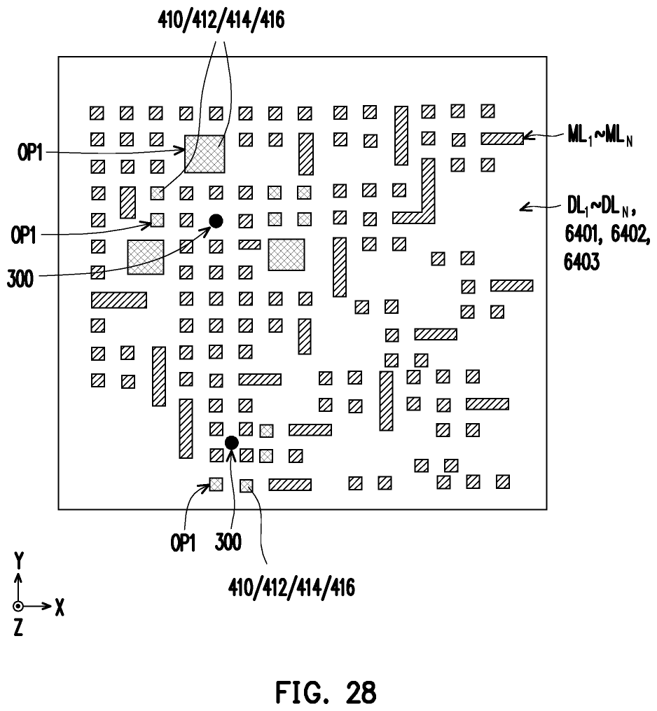

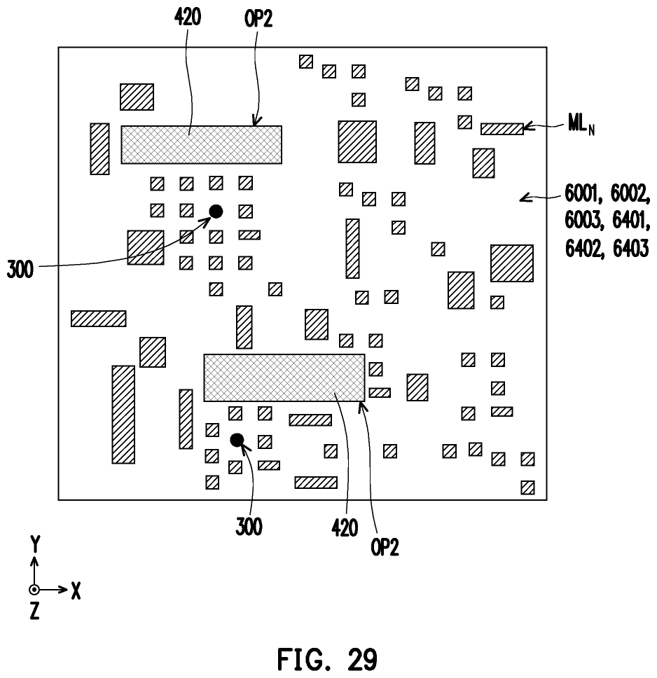

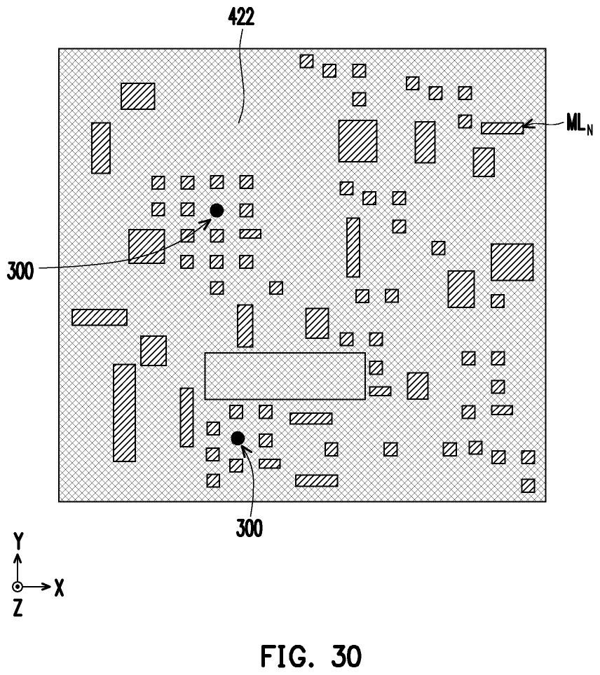

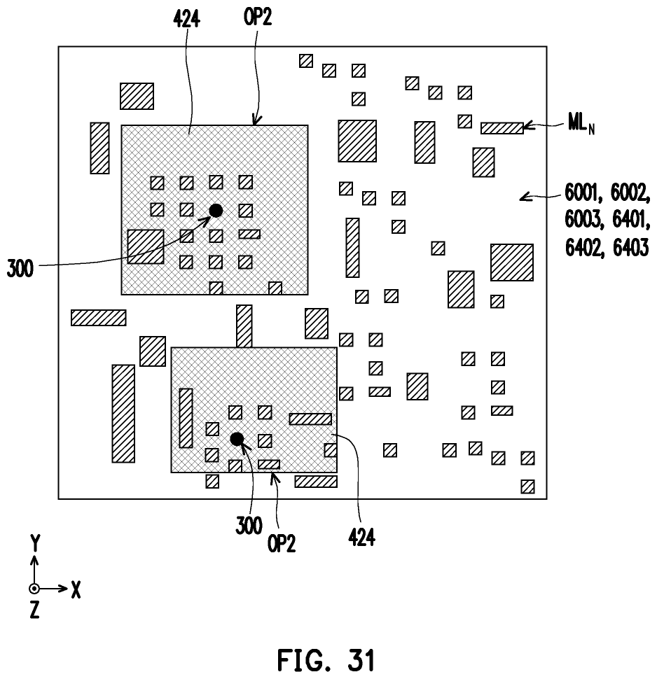

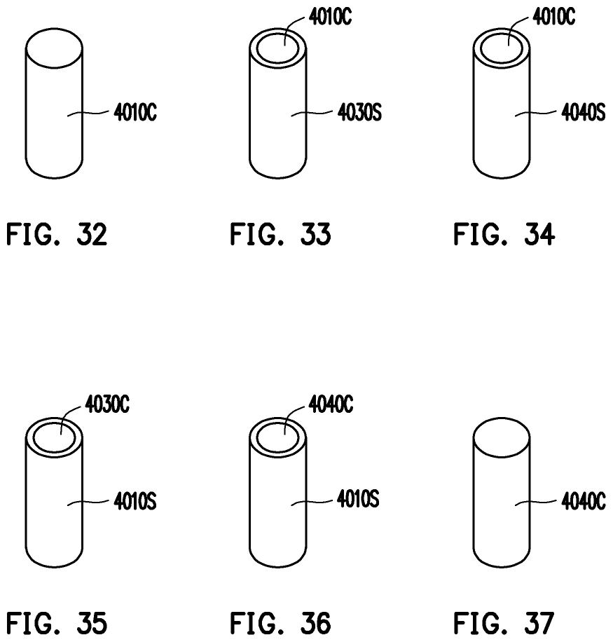

FIG. 1 to FIG. 21 are schematic cross-sectional views of various stages in a manufacturing method of a semiconductor device (e.g., 10000A) in accordance with some embodiments of the disclosure. FIG. 22 through FIG. 27 are schematic cross-sectional views respectively showing a semiconductor device (e.g., 10000B, 10000C, 10000D, 10000E, 10000F, 10000G) in accordance with alternative embodiments of the disclosure. FIG. 28 and FIG. 31 are schematic plane views showing a positioning configuration of a hotspot (e.g., 300 or the like) and a thermal control element (e.g., 400A, 400B, 400C, 400D, 400E, or 400F) included in a semiconductor device in accordance with various embodiments of the disclosure. FIG. 28 and FIG. 31 are schematic plane views showing a positioning configuration of a hotspot (e.g., 300 or the like) and a thermal control element (e.g., 400A, 400B, 400C, 400D, 400E, or 400F) included in a semiconductor device in accordance with various embodiments of the disclosure, where the schematic plane views show the relative relationship in various positioning configurations of a hotspot (e.g., 300 or the like) and a portion of a thermal control element (e.g., 400A, 400B, 400C, 400D, 400E, or 400F). FIG. 32 through FIG. 37 are schematic three-dimensional side-views respectively illustrating various configurations of a thermal via (e.g., 410, 412, 414, 416) in accordance with some embodiments of the disclosure. The embodiments are intended to provide further explanations but are not used to limit the scope of the disclosure.

Referring to FIG. 1, in some embodiments, a substrate 200A is provided. For example, the substrate 200A includes a wide variety of components (also referred to as semiconductor components) formed in a semiconductor substrate 202, as shown in FIG. 1. The components may include active components, passive components, or a combination thereof. The components may include integrated circuit (IC) devices. The components may include transistors, capacitors, resistors, diodes, photodiodes, fuse devices, jumpers, inductors, or other similar devices. The functions of the components may include memory, processors, sensors, amplifiers, power distribution, input/output circuitry, or the like. The components each may be referred to as a semiconductor component of the disclosure.

In some embodiments, the semiconductor substrate 202 includes a bulk semiconductor substrate, a crystalline silicon substrate, a doped semiconductor substrate (e.g., p-type semiconductor substrate or n-type semiconductor substrate), a semiconductor-on-insulator (SOI) substrate, or the like. In certain embodiments, the semiconductor substrate 202 includes one or more doped regions or various types of doped regions, depending on the demand and/or product design requirements/layout. In some embodiments, the doped regions are doped with p-type and/or n-type dopants. For example, the p-type dopants are boron or BF₂ and the n-type dopants are phosphorus or arsenic. The doped regions may be configured for an n-type metal-oxide-semiconductor (NMOS) transistor or a p-type MOS (PMOS) transistor. The semiconductor substrate 202 may be a wafer, such as a silicon wafer. Generally, the SOI substrate is a layer of a semiconductor material formed on an insulator layer. The insulator layer is, for example, a buried oxide (BOX) layer, a silicon oxide layer, or the like. Other substrates, such as a multi-layered or gradient substrate may also be used. In some alternative embodiments, the semiconductor substrate 202 includes a semiconductor substrate made of other suitable elemental semiconductor, such as diamond or germanium; a suitable compound semiconductor, such as gallium arsenide, silicon carbide, gallium phosphide, indium phosphide, indium arsenide and indium antimonide, an alloy semiconductor such as SiGe, GaAsP, AlInAs, AlGaAs, GaInAs, GaInP and GaInAsP or combinations thereof. For example, the semiconductor substrate 202 is a silicon bulk substrate.

As shown in FIG. 1, the components (such as one or more transistors 300) may be formed in the semiconductor substrate 202. In some embodiments, a plurality of isolation structures 204 are formed in the semiconductor substrate 202 for separating the transistors 300. In certain embodiments, the isolation structures 204 are trench isolation structures. In other embodiments, the isolation structures 204 includes local oxidation of silicon (LOCOS) structures. In some embodiments, the insulator material of the isolation structures 204 includes silicon oxide, silicon nitride, silicon oxynitride, a spin-on dielectric material, or a low-k dielectric material. For example, the low-k dielectric material generally has a dielectric constant lower than 3.9. In one embodiment, the insulator material may be formed by chemical vapor deposition (CVD) such as high-density plasma CVD (HDP-CVD) and sub-atmospheric CVD (SACVD) or formed by spin-on. In certain embodiments, the components (such as the transistors 300) and the isolation structures 204 are formed in the substrate 200A during the front-end-of-line (FEOL) processes. In one embodiment, the transistors 300 are formed following the complementary MOS (CMOS) processes. The number and configurations of the components formed in the semiconductor substrate 202 should not be limited by the embodiments or drawings of this disclosure. That is, the number of the components may be more than two. It is understood that the number and configurations of the components may have different material or configurations depending on the demand and/or product design requirements/layout.

The transistors 300 independently may be a PMOS transistor. For example, the transistors 300 each include a gate structure 310 and source/drain regions 320 located at two opposite sides of the gate structure 310, where the gate structure 310 is formed on an n-well region 330, and the source/drain regions 320 are formed in the n-well region 330. In one embodiment, the gate structure 310 includes a gate electrode 312, a gate dielectric layer 314 and a gate spacer 316. The gate dielectric layer 314 may spread between the gate electrode 312 and the semiconductor substrate 202, and may or may not further cover a sidewall of the gate electrode 312. The gate spacer 316 may laterally surround the gate electrode 312 and the gate dielectric layer 314. In one embodiment, the source/drain regions 320 include doped regions of p-type dopant that are formed in the n-well region 330 by ion implantation. In an alternative embodiment, the source/drain regions 320 include epitaxial structures formed in and protruding from a surface of the semiconductor substrate 202 that are formed by epitaxial growth.

Alternatively, the transistors 300 independently may be a NMOS transistor. For example, the transistors 300 each include a gate structure 310 and source/drain regions 320 located at two opposite sides of the gate structure 310, where the gate structure 310 is formed on an p-well region 330, and the source/drain regions 320 are formed in the p-well region 330. In one embodiment, the gate structure 310 includes a gate electrode 312, a gate dielectric layer 314 and a gate spacer 316. The gate dielectric layer 314 may spread between the gate electrode 312 and the semiconductor substrate 202, and may or may not further cover a sidewall of the gate electrode 312. The gate spacer 316 may laterally surround the gate electrode 312 and the gate dielectric layer 314. In one embodiment, the source/drain regions 320 include doped regions of n-type dopant that are formed in the p-well region 330 by ion implantation. In an alternative embodiment, the source/drain regions 320 include epitaxial structures formed in and protruding from a surface of the semiconductor substrate 202 that are formed by epitaxial growth.

In a non-limiting example, all of the transistors 300 may have the same type. For example, all of the transistors 300 are NMOS transistors. For another example, the transistors 300 are PMOS transistors. The disclosure is not limited thereto. In another non-limiting example, one or some of the transistors 300 may have a type being different from the types of the rest of the transistors 300. For example, one or some of the transistors 300 are NMOS transistors, and the rest of the transistors 300 are PMOS transistors, or vice versa.

In some embodiments, some or all of the transistors 300 are or are part of a logic component(s) with or without interaction there-between. In addition, at least some of the transistors 300 are or are part of a memory component(s), such as a static random-access memory (SRAM), with or without interaction there-between, where the transistors 300 serving as logic components and the transistors 300 serving as memory components are electrically coupled and electrically communicated.

For illustrative purposes, the transistors 300 are illustrated in form of planar transistors, however the disclosure is not limited thereto. The transistors 300 independently may be a field-effect transistor (FET), such as a planar FET, a tunnel field-effect transistor (TFET), or a fin-type FET (FinFET); a gate all around (GAA) transistor; a nanosheet transistor; a nanowire transistor; the like; or combinations thereof, depending on the demand and/or product design requirements/layout. In accordance with some embodiments, the transistors 300 may be or include a portion of a planar FET and/or a TFET device, which may include a silicon body standing on a substrate, and a gate is standing on the silicon body (i.e., the channel region) providing control from a top side of the channel region. In accordance with some embodiments, the transistors 300 may be or include a portion of a FinFET device, which may include a thin (vertical) fin of silicon body on a substrate, and a gate is wrapped around the fin (i.e., the channel region) providing control from three sides of the channel region. In accordance with some embodiments, the transistors 300 may be or include a portion of a nanostructure transistor device (such as a GAA transistor device, a nanosheet transistor or a nanowire transistor), which may include a gate structure wrapping around (e.g., engaging) the perimeter of one or more nanostructures (i.e., channel regions) for improved control of channel current flow.

As illustrated in FIG. 1, for example, the substrate 200A further includes a dielectric layer 206 stacked on the semiconductor substrate 202 and a plurality of contact plugs 208 penetrating through the dielectric layer 206 to electrically connect to the transistors 300. In certain embodiments, the dielectric layer 206 and the contact plugs 208 are also formed in the structure 200A during the FEOL processes. The dielectric layer 206 may laterally surround the gate structures 310 and cover the source/drain regions 320 for providing protections to the components formed in/on the semiconductor substrate 202. Some of the contact plugs 208 may penetrate through the dielectric layer 206 in order to establish electrical connection with the source/drain regions 320, while others of the contact plugs 208 (not shown) may partially penetrate through the dielectric layer 206 to establish electrical connection with the gate electrodes (e.g. the gate electrodes 312) of the gate structures 310, in order to provide terminals for electrical connections to later-formed components (e.g. an interconnect or interconnect structure) or external components.

The dielectric layer 206 may be referred to as an interlayer dielectric (ILD) layer, while the contact plugs 208 may be referred to as metal contacts or metallic contacts. For example, the contact plugs 208 electrically connected to the source/drain regions 320 are referred to as source/drain contacts, and the contact plugs 208 electrically connected to the gate electrodes 312 are referred to as gate contacts. In some embodiments, the contact plugs 208 may include copper (Cu), copper alloys, nickel (Ni), aluminum (Al), manganese (Mn), magnesium (Mg), silver (Ag), gold (Au), tungsten (W), a combination of thereof, or the like. The contact plugs 208 may be formed by, for example, plating such as electroplating or electroless plating, CVD such as plasma enhanced CVD (PECVD), atomic layer deposition (ALD), and physical vapor deposition (PVD), a combination thereof, or the like. Throughout the description, the term “copper” is intended to include substantially pure elemental copper, copper containing unavoidable impurities, and copper alloys containing minor amounts of elements such as tantalum, indium, tin, zinc, manganese, chromium, titanium, germanium, strontium, platinum, magnesium, aluminum or zirconium, etc.

In some embodiments, the dielectric layer 206 includes silicon oxide, silicon nitride, silicon carbide, silicon oxynitride, silicon carbonitride, silicon carbide oxynitride, spin-on glass (SOG), phosphosilicate glass (PSG), borosilicate glass (BSG), borophosphosilicate glass (BPSG), fluorinated silica glass (FSG), carbon doped silicon oxide (e.g., SiCOH), polyimide, and/or a combination thereof. In alternative embodiments, the dielectric layer 206 include low-k dielectric materials. For example, the low-k dielectric material generally has a dielectric constant lower than 3.9. Examples of low-k dielectric materials may include BLACK DIAMOND® (Applied Materials of Santa Clara, Calif.), Xerogel, Aerogel, amorphous fluorinated carbon, Parylene, benzocyclobutene (BCB), Flare, SILK® (Dow Chemical, Midland, Mich.), hydrogen silsesquioxane (HSQ) or fluorinated silicon oxide (SiOF), and/or a combination thereof. It is understood that the dielectric layer 206 may include one or more dielectric materials. For example, the dielectric layer 206 include a single-layer structure or a multilayer structure. In some embodiments, the dielectric layer 206 is formed to a suitable thickness by CVD such as flowable chemical vapor deposition (FCVD), HDP-CVD, and SACVD, spin-on, sputtering, or other suitable methods.

A seed layer (not shown) may be optionally formed between the dielectric layer 206 and the contact plugs 208. That is, for example, the seed layer covers a bottom surface and sidewalls of each of the contact plugs 208. In some embodiments, the seed layer is a metal layer, which may be a single layer or a composite layer comprising a plurality of sub-layers formed of different materials. In some embodiments, the seed layer includes copper layer and the seed layer includes a titanium layer and a copper layer over the titanium layer. The seed layer is formed using, for example, PVD or the like. In one embodiment, the seed layer may be omitted.

In addition, an additional barrier layer or adhesive layer (not shown) may be optionally formed between the contact plugs 208 and the dielectric layer 206. Owing to the additional barrier layer or adhesive layer, it is able to prevent the seed layer and/or the contact plugs 208 from diffusing to the underlying layers and/or the surrounding layers. The additional barrier layer or adhesive layer may include Ti, TiN, Ta, TaN, a combination thereof, a multilayer thereof, or the like, and may be formed using CVD, ALD, PVD, a combination thereof, or the like. In an alternative embodiment of which the seed layer is included, the additional barrier layer or adhesive layer is interposed between the dielectric layer 206 and the seed layer, and the seed layer is interposed between the contact plugs 208 and the additional barrier layer or adhesive layer. In one embodiment, the additional barrier layer or adhesive layer may be omitted.

As illustrated in FIG. 1, for example, the substrate 200A further includes a plurality of through vias 1001. In some embodiments, the through vias 1001 are formed to be laterally next to the transistors 300, vertically penetrate through the dielectric layer 206 and further extend into a position inside the semiconductor substrate 202. In some embodiments, the through vias 1001 each includes a liner 110 and a conductive via 120, where a bottom and a sidewall of the conductive via 120 are lined with the liner 110. That is, the conductive vias 120 of the through vias 1001 are separated from the semiconductor substrate 202 and the dielectric layer 206 through the respective liners 110. In some embodiments, the through vias 1001 may be tapered from the dielectric layer 206 to the semiconductor substrate 202. Alternatively, the through vias 1001 may have substantially vertical sidewalls. In a cross-sectional view along the direction Z, the shape of the through vias 1001 may depend on the demand and/or product design requirements/layout, and is not intended to be limited in the disclosure. On the other hand, in the top (plane) view on the X-Y plane, the shape of the through vias 1001 is circular shape. However, depending on the design requirements, and the shape of the through vias 1001 may be an oval shape, a rectangular shape, a polygonal shape, or combinations thereof; the disclosure is not limited thereto. In some embodiments, the through vias 1001 are not accessibly revealed by a rear surface S202 of the semiconductor substrate 202, and are accessibly revealed by a surface S206 of the dielectric layer 206. The number of the through vias 1001 is not limited in the disclosure, and may be selected and designated based on the demand and/or product design requirements/layout.

The conductive vias 120 may be formed of a conductive material, such as copper, tungsten, aluminum, silver, combinations thereof, or the like. The liners 110 may be formed of a barrier material, such as TiN, Ta, TaN, Ti, or the like. In alternative embodiments, a dielectric liner (not shown) (e.g., silicon nitride, an oxide, a polymer, a combination thereof, etc.) may be further optionally formed between the liners 110 and the semiconductor substrate 202 and between the liners 110 and the dielectric layer 206. In addition to or alternatively, the liners 110 may be omitted.

The liners 110, the conductive vias 120 and the optional dielectric liners may be formed by, but not limited to, forming a plurality of recesses in the dielectric layer 206 and the substrate 202; respectively depositing the optional dielectric material, the barrier material and the conductive material in the recesses; and removing excess materials on a plane where illustrated top openings of the recesses located at. For example, the recesses are lined with the optional dielectric liners so as to laterally separate the liners 110 lining the sidewalls and illustrated bottom surfaces of the conductive vias 120 from the semiconductor substrate 202 and the dielectric layer 206. The through vias 1001 are formed by using a via-first approach, in some embodiments. In such embodiments, the through vias 1001 are formed prior to the formation of an interconnect (e.g., 500). Alternatively, the through vias 1001 may be formed by using a via-last approach, where the through vias 1001 may be formed after the formation of an interconnect (e.g., 500).

In some embodiments, if considering a top or plane view (e.g., a X-Y plane) along a direction Z, the semiconductor substrate 202 is in a wafer or panel form. The semiconductor substrate 202 may be in a form of wafer-size having a diameter of about 4 inches or more. The semiconductor substrate 202 may be in a form of wafer-size having a diameter of about 6 inches or more. The semiconductor substrate 202 may be in a form of wafer-size having a diameter of about 8 inches or more. Or alternatively, the semiconductor substrate 202 may be in a form of wafer-size having a diameter of about 12 inches or more. The transistors 300 formed in the substrate 200A may be arranged in a form of an array along a direction X and a direction Y. The direction X, the direction Y and the direction Z may be different from each other. For example, the direction X is perpendicular to the direction Y, and the direction X and the direction Y are independently perpendicular to the direction Z, as shown in FIG. 1. In the disclosure, the direction Z may be referred to as a stacking direction, and the X-Y plane defined by the direction X and the direction Y may be referred to as the plane view or top view.

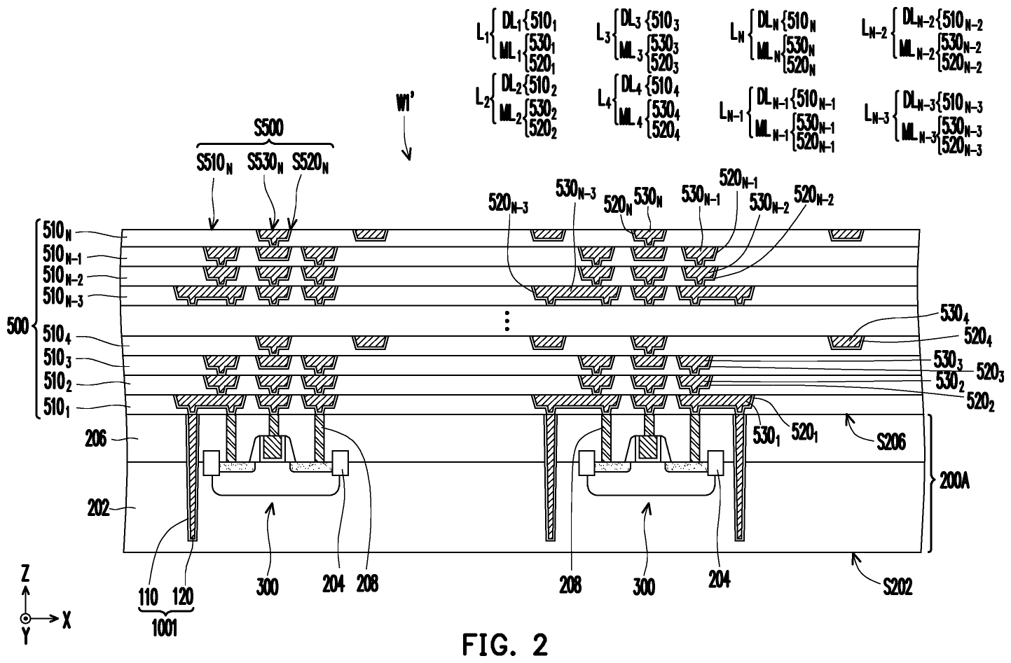

Referring to FIG. 2, in some embodiments, an interconnect 500 is disposed on the dielectric layer 206 and over the substrate 202 of the substrate 200A. For example, the interconnect 500 includes a plurality of build-up layers (e.g., L₁, L₂, L₃, L₄ . . . , L_{N-3}, L_{N-2}, L_{N-1} and L_{N}) stacked thereon along the direction Z and electrically connected to each other. In the disclosure, for illustrative purposes, the interconnect 500 includes a first portion including four build-up layers (e.g., L₁, L₂, L₃, L₄) and a second portion including (N−4) build-up layers (e.g., . . . , L_{N-3}, L_{N-2}, L_{N-1} and L_{N}) stacked on and electrically connected thereto, wherein N is greater than four. However, the disclosure is not limited thereto, as an alternative, the first portion may include one, two, three, four or more build-up layers, while the second portion may include one, two, three, four or more build-up layers. The number of build-up layers included in the first portion of the interconnect 500 and the number of build-up layers included in the second portion of the interconnect 500 are selected and designed based on the demand and/or product design requirements/layout. In some embodiments, the first portion is referred to as local interconnection formed in a middle-end-of-line (MEOL) processes, and the second portion is referred to as global interconnection formed in a back-end-of-line (BEOL) fabrication process.

The interconnect 500 may be electrically coupled to the components formed in the substrate 200A, as shown in FIG. 2. That is, the interconnect 500 provides the routing functions to the components formed in the substrate 200A. In some embodiments, at least some of the components formed in the substrate 200A are electrically communicated to one another by the interconnect 500 (e.g., the first portion of the interconnect 500) and are electrically communicated to external electronic devices/components by the interconnect 500 (e.g., the second portion of the interconnect 500). As shown in FIG. 2, the interconnect 500 includes one or more dielectric layers 510 (e.g., 510₁, 510₂, 510₃, 510₄, . . . , 510_{N-3}, 510_{N-2}, 510_{N-1}, and 510_{N}), one or more seed layers 520 (e.g., 520₁, 520₂, 520₃, 520₄, . . . , 520_{N-3}, 520_{N-2}, 520_{N-1}, and 520_{N}), or one or more conductive layers 530 (e.g., 530₁, 530₂, 530₃, 530₄, . . . , 530_{N-3}, 530_{N-2}, 530_{N-1}, and 530_{N}). In some embodiments, the seed layers 520 each line a sidewall and bottom of a respective one of the conductive layers 530 (e.g., a sidewall and a bottom thereof). In some embodiments, each conductive layer 530 (e.g., 530₁, 530₂, 530₃, 530₄, . . . , 530_{N-3}, 530_{N-2}, 530_{N-1}, and 530_{N}) includes a line portion extending along a horizontal direction (e.g., the direction X or the direction Y), a via portion extending along a vertical direction (e.g., the direction Z), and/or a combination thereof. The seed layers 520 (e.g., 520₁, 520₂, 520₃, 520₄, . . . , 520_{N-3}, 520_{N-2}, 520_{N-1}, and 520_{N}) and respective conductive layers 530 (e.g., 530₁, 530₂, 530₃, 530₄, . . . , 530_{N-3}, 530_{N-2}, 530_{N-1}, and 530_{N}) may be referred to as metallization layers ML (e.g., ML₁, ML₂, ML₃, ML₄, . . . ML_{N-3}, ML_{N-2}, ML_{N-1}, and ML_{N}) or redistribution layers of the interconnect 500 to provide routing functions, and may be collectively referred to as a routing structure of the interconnect 500. The dielectric layers 510 (e.g., 510₁, 510₂, 510₃, 510₄, . . . , 510_{N-3}, 510_{N-2}, 510_{N-1}, and 510_{N}) may be collectively referred to as a dielectric structure of the interconnect 500 to provide protection for the routing structure, the metallization layers or redistribution layers of the interconnect 500.

One dielectric layer and a respective one metallization layer together may be considered as one build-up layer (e.g., 510₁, 520₁ and 530₁; 510₂, 520₂ and 530₂; 510₃, 520₃ and 530₃; 510₄, 520₄ and 530₄; . . . ; 510_{N-3}, 520_{N-3} and 530_{N-3}; 510_{N-2}, 520_{N-2} and 530_{N-2}; 510_{N-1}, 520_{N-1} and 530_{N-1}; 510_{N}, 520_{N} and 530_{N}; or the like) of the interconnect 500. As shown in FIG. 2, for example, a topmost layer (e.g., 520_{N}) of the seed layers 520 and a topmost layer (e.g., 530_{N}) of the conductive layers 530 may be accessibly revealed by a topmost layer (e.g., 510_{N}) of the dielectric layers 510 for external connection. In some embodiments, line dimensions (e.g., thickness and width) of the metallization layers ML₁ to ML_{N} of the interconnect 500 are gradually increased along a direction from the substrate 200A to the interconnect 500.

However, the disclosure is not limited thereto, alternatively, the seed layers 520 may be omitted. In such alternative embodiments, the conductive layers 530 (e.g., 530₁, 530₂, 530₃, 530₄, . . . , 530_{N-3}, 530_{N-2}, 530_{N-1}, and 530_{N}) may be referred to as metallization layers ML (e.g., ML₁, ML₂, ML₃, ML₄, . . . , ML_{N-3}, ML_{N-2}, ML_{N-1}, and ML_{N}) or redistribution layers of the interconnect 500 to provide routing functions, and may be collectively referred to as a routing structure of the interconnect 500. One dielectric layer and a respective one metallization layer together may be considered as one build-up layer (e.g., 510₁ and 530₁; 510₂ and 530₂; 510₃ and 530₃; 510₄ and 530₄; . . . ; 510_{N-3} and 530_{N-3}; 510_{N-2} and 530_{N-2}; 510_{N-1} and 530_{N-1}; 510_{N} and 530_{N}; or the like) of the interconnect 500.

In some embodiments, the interconnect 500 may be formed by, but not limited to, forming a blanket layer of first dielectric material over the dielectric layer 206; patterning the first dielectric material blanket layer to form a dielectric layer 510₁ having a plurality of first openings (not labeled) penetrating there-through and accessibly revealing portions of the through vias 1001 and the components such as the transistors 300; optionally forming a blanket layer of first seed layer material over the dielectric layer 510₁, the first seed layer material blanket layer extending into the first openings to line the first openings and in contact with the exposed portions of the through vias 1001 and the components such as the transistors 300; forming a blanket layer of a first conductive material over the first seed layer material blanket layer, the first conductive material blanket layer filled the first openings; removing excess amount of the first seed layer material blanket layer and first conductive material blanket layer over the illustrated top surface of the dielectric layer 510₁ so to form the metallization layer ML₁ including the seed layer 520₁ and the conductive layer 530₁, thereby forming one build-up layer L₁ (e.g., a first build-up layer including 510₁, 520₁ and 530₁); forming a blanket layer of second dielectric material over the first build-up layer L₁; patterning the second dielectric material blanket layer to form a dielectric layer 510₂ having a plurality of second openings (not labeled) penetrating there-through and accessibly revealing portions of the metallization layer ML₁; optionally forming a blanket layer of second seed layer material over the dielectric layer 510₂, the second seed layer material blanket layer extending into the second openings to line the second openings and in contact with the exposed portions of the metallization layer ML₁; forming a blanket layer of a second conductive material over the second seed layer material blanket layer, the second conductive material blanket layer filled the second openings; removing excess amount of the second seed layer material blanket layer and second conductive material blanket layer over the illustrated top surface of the dielectric layer 510₂ so to form the metallization layer ML₂ including the seed layer 520₂ and the conductive layer 530₂, thereby forming one build-up layer L₂ (e.g., a second build-up layer including 510₂, 520₂ and 530₂); then repeating the formation steps of forming the first and/or second build-up layers to form the rest of build-up layers (e.g., a third build-up layer L₃ (e.g., including 510₃, 520₃ and 530₃), a fourth build-up layer L₄ (e.g., including 510₄, 520₄ and 530₄), . . . , a (N−3)^{th} build-up layer L_{N-3} (e.g., including 510_{N-3}, 520_{N-3} and 530_{N-3}), a (N−2)^{th} build-up layer (e.g., including 510_{N-2}, 520_{N-2} and 530_{N-2}), a (N−1)^{th} build-up layer L_{N-1} (e.g., including 510_{N-1}, 520_{N-1} and 530_{N-1}), and a (N)^{th} build-up layer L_{N} (e.g., including 510_{N}, 520_{N} and 530_{N})). Upon this, the interconnect 500 is manufactured. The interconnect 500 may be formed on the substrate 200A by single or dual damascene process. The disclosure is not limited thereto.

In some embodiments, the material of the dielectric layers 510 (e.g., 510₁, 510₂, 510₃, 510₄, . . . , 510_{N-3}, 510_{N-2}, 510_{N-1}, and 510_{N}) may be polyimide (PI), polybenzoxazole (PBO), BCB, a nitride such as silicon nitride, an oxide such as silicon oxide, phosphosilicate glass (PSG), borosilicate glass (BSG), borophosphosilicate glass (BPSG), a combination thereof or the like, which may be patterned using a photolithography and/or etching process. Or, the material of the dielectric layers 510 (e.g., 510₁, 510₂, 510₃, 510₄, . . . , 510_{N-3}, 510_{N-2}, 510_{N-1}, and 510_{N}) may be AlN, BN, diamond-like carbon, Al₂O₃, BeO. The etching process may include a dry etching, a wet etching, or a combination thereof. After the etching process, a cleaning step may be optionally performed, for example, to clean and remove the residue generated from the etching process. In some embodiments, the dielectric material blanket layer is formed by suitable fabrication techniques such as spin-on coating, CVD (e.g., PECVD), or the like. For example, the material of the dielectric layer 510₁ is silicon oxide. In one embodiment, the materials of the dielectric layers 510 (e.g., 510₁, 510₂, 510₃, 510₄, . . . , 510_{N-3}, 510_{N-2}, 510_{N-1}, and 510_{N}) are the same to each other. Alternatively, the materials of the dielectric layers 510 (e.g., 510₁, 510₂, 510₃, 510₄, . . . , 510_{N-3}, 510_{N-2}, 510_{N-1}, and 510_{N}) may be different to one another, in part or all.

The openings formed in the dielectric layers 510 (e.g., 510₁, 510₂, 510₃, 510₄, . . . 510_{N-3}, 510_{N-2}, 510_{N-1}, and 510_{N}) each may include a trench hole and a via hole underlying and spatially communicated to the trench hole. A lateral size of the trench holes may be greater than a lateral size of the via holes. In some embodiments, a sidewall of each of the via holes is a slant sidewall. In alternative embodiments, the sidewall of each of the via holes is a vertical sidewall. In some embodiments, a sidewall of each of the trench holes is a slant sidewall. In alternative embodiments, the sidewall of each of the trench holes is a vertical sidewall. The sidewall of one via hole and the sidewall of a respective one trench hole may be collectively referred to as a sidewall of one opening formed in the dielectric layers 510 (e.g., 510₁, 510₂, 510₃, 510₄, . . . , 510_{N-3}, 510_{N-2}, 510_{N-1}, and 510_{N}). In some embodiments, the openings formed in the dielectric layers 510 (e.g., 510₁, 510₂, 510₃, 510₄, . . . , 510_{N-3}, 510_{N-2}, 510_{N-1}, and 510_{N}) each include a dual damascene structure. The formation of the openings is not limited to the disclosure. The formation of openings (with the dual damascene structure) formed in the dielectric layers 510 (e.g., 510₁, 510₂, 510₃, 510₄, . . . , 510_{N-3}, 510_{N-2}, 510_{N-1}, and 510_{N}) can be formed by any suitable forming process, such as a via first approach or a trench first approach. For illustrative purposes, the number of the openings formed in the dielectric layers 510 (e.g., 510₁, 510₂, 510₃, 510₄, . . . , 510_{N-3}, 510_{N-2}, 510_{N-1}, and 510_{N}) does not limit the disclosure, and may be designated and selected based on the demand and/or layout design requirements/layout. Portions of the metallization layers ML (e.g., ML₁, ML₂, ML₃, ML₄, . . . , ML_{N-3}, ML_{N-2}, ML_{N-1}, ML_{N}) formed in the trench holes may be referred to as conductive lines, conductive traces, conductive wires, metallization lines, routing lines or redistribution lines horizontally extended (e.g., extending in the direction X and/or the direction Y), and portions of the metallization layers ML (e.g., ML₁, ML₂, ML₃, ML₄, . . . , ML_{N-3}, ML_{N-2}, ML_{N-1}, ML_{N}) formed in the via holes may be referred to as conductive vias, metallization vias, routing vias or redistribution vias vertically extended (e.g., extending in the direction Z).

In other alternative embodiments, the dielectric material blanket layer used for the formation of the dielectric layers 510 (e.g., 510₁, 510₂, 510₃, 510₄, . . . , 510_{N-3}, 510_{N-2}, 510_{N-1}, and 510_{N}) includes two-layer structure, where a first dielectric layer includes a silicon carbide (SiC) layer, a silicon nitride (Si₃N₄) layer, an aluminum oxide layer, or the like, and the second dielectric layer (stacking on the first dielectric layer) includes a silicon oxide layer (e.g., a silicon-rich oxide (SRO) layer), a silicon nitride layer, a silicon oxynitride layer, a spin-on dielectric layer, or a low-k dielectric layer. It should be noted that the low-k dielectric layer is generally made of dielectric materials having a dielectric constant lower than 3.9. In some alternative embodiments, the first dielectric layer and the second dielectric layer have different etching selectivities. For example, in the case of the first build-up layer L₁, the first dielectric layer may be referred to as an etching stop layer (ESL) to prevent the underlying elements (e.g., the contact plugs 208 and the dielectric layer 206) from damage caused by the over-etching, while the second dielectric layer may be referred to as an inter-metallic layer (IML). In such alternative embodiments, the first dielectric layer and the second dielectric layer are patterned through a set(s) of photolithography and etching processes. The etching process may include a dry etching, a wet etching, or a combination thereof. After the etching process, a cleaning step may be optionally performed, for example to clean and remove the residue generated from the etching process. However, the disclosure is not limited thereto, and the etching process may be performed through any other suitable method. The openings formed in the first dielectric layer and the second dielectric layer each may include a trench hole and a via hole underlying and spatially communicated to the trench hole. For example, the trench holes are formed in the second dielectric layer and extend from an illustrated top surface of the second dielectric layer to a position inside the second dielectric layer. For example, the via holes are formed in the second dielectric layer and the first dielectric layer and extend from the position inside the second dielectric layer to an illustrated bottom surface of the first dielectric layer. The position may be about ½ to about ⅓ of a thickness of the second dielectric layer; however, the disclosure is not limited thereto.

The seed layer material blanket layers used to form the seed layers 520 (e.g., 520₁, 520₂, 520₃, 520₄, . . . , 520_{N-3}, 520_{N-2}, 520_{N-1}, and 520_{N}) may be formed in a manner of a blanket layer made of metal or metal alloy materials, the disclosure is not limited thereto. The material of each of the seed layers material blanket layers may include titanium, copper, molybdenum, tungsten, titanium nitride, titanium tungsten, combinations thereof, or the like, which may be formed using, for example, sputtering, physical vapor deposition (PVD), or the like. The seed layer material blanket layers may be patterned by etching, such as a dry etching process, a wet etching process, or a combination thereof; the disclosure is not limited thereto. The seed layers 520 (e.g., 520₁, 520₂, 520₃, 520₄, . . . , 520_{N-3}, 520_{N-2}, 520_{N-1}, and 520_{N}) individually are referred to as a metal layer, which can be a single layer or a composite layer including a plurality of sub-layers formed of different materials. For example, the seed layers 520 (e.g., 520₁, 520₂, 520₃, 520₄, . . . , 520_{N-3}, 520_{N-2}, 520_{N-1}, and 520_{N}) each may be or include a titanium layer and a copper layer over the titanium layer. In one embodiment, the materials of the seed layers 520 (e.g., 520₁, 520₂, 520₃, 520₄, . . . , 520_{N-3}, 520_{N-2}, 520_{N-1}, and 520_{N}) are the same to each other. Alternatively, the materials of the seed layers 520 (e.g., 520₁, 520₂, 520₃, 520₄, . . . , 520_{N-3}, 520_{N-2}, 520_{N-1}, and 520_{N}) may be different to one another.

The material of each of the conductive material blanket layers for forming the conductive layers 530 (e.g., 530₁, 530₂, 530₃, 530₄, . . . , 530_{N-3}, 530_{N-2}, 530_{N-1}, and 530_{N}) may be made of conductive materials formed by plating (such as electroplating or electroless plating) or deposition, such as copper, copper alloy, aluminum, aluminum alloy, combinations thereof (e.g., AlCu) or the like, which may be patterned to form a plurality of conductive patterns/segments using a photolithography and etching process. In one embodiment, the materials of the conductive layers 530 (e.g., 530₁, 530₂, 530₃, 530₄, . . . 530_{N-3}, 530_{N-2}, 530_{N-1}, and 530_{N}) are the same to each other. Alternatively, the materials of the conductive layers 530 (e.g., 530₁, 530₂, 530₃, 530₄, . . . , 530_{N-3}, 530_{N-2}, 530_{N-1}, and 530_{N}) may be different to one another.

In the case, an illustrated top surface (e.g., including a surface S520_{N} of the seed layer 520_{N} and a surface S530_{N} of the conductive layer 530_{N}) of the metallization layer ML_{N} is substantially level with an illustrated top surface (e.g., a surface of S510_{N} of the dielectric layer 510_{N}) of the dielectric structure DL_{N}. That is, the illustrated top surface of the metallization layer ML_{N} is substantially coplanar to the illustrated top surface of the dielectric structure DL_{N}. An illustrated top surface S500 (e.g., including the surface S510_{N} of the dielectric layer 510_{N}, the surface S520_{N} of the seed layer 520_{N} and the surface S530_{N} of the conductive layer 530_{N}) of the interconnect 500 may be level and may have a high degree of coplanarity, as shown in FIG. 2.

The removal of excess amount of the seed layer material blanket layer and conductive material blanket layer may be performed by a planarizing process such as a mechanical grinding, a chemical mechanical polishing (CMP), and/or an etching process. After the planarizing process, a cleaning process may be optionally performed, for example to clean and remove the residue generated from the planarizing process. However, the disclosure is not limited thereto, and the planarizing process may be performed through any other suitable method.

In some embodiments, the build-up layer L₁ (including 510₁, 520₁ and a 530₁) is disposed on (e.g., in physical contact with) and electrically coupled to the through vias 1001 and the components (such as the transistors 300) through the contact plugs 208 for providing routing function thereto, the build-up layer L₂ (including 510₂, 520₂ and 530₂) is disposed on (e.g., in physical contact with) and electrically connected to the build-up layer L₁, and thus is electrically coupled to the through vias 1001 and the components (e.g., transistors 300) formed in the semiconductor substrate 202 through the contact plugs 208 and the build-up layer L₁ for providing routing function thereto; the build-up layer L₃ (including 510₃, 520₃ and 530₃) is disposed on (e.g., in physical contact with) and electrically connected to the build-up layer L₂, and thus is electrically coupled to the through vias 1001 and the components (e.g., transistors 300) formed in the semiconductor substrate 202 through the contact plugs 208 and the build-up layers L₁-L₂ for providing routing function thereto; and the build-up layer L₄ (including 510₄, 520₄ and 530₄) is disposed on (e.g., in physical contact with) and electrically connected to the build-up layer L₃, and thus is electrically coupled to the through vias 1001 and the components (e.g., transistors 300) formed in the semiconductor substrate 202 through the contact plugs 208 and the build-up layers L₁-L₃ for providing routing function thereto. As shown in FIG. 2, the build-up layer L_{N-3} (including 510_{N-3}, 520_{N-3} and 530_{N-3}) may be disposed over and electrically coupled to the build-up layer L₄ (e.g., through additional build-up layers formed there-between, if any), and thus is electrically coupled to the through vias 1001 and the components (e.g., transistors 300) formed in the semiconductor substrate 202 through the contact plugs 208, the build-up layers L₁ to L₄ and the additional build-up layers formed there-between (if any) for providing routing function thereto; the build-up layer L_{N-2} (including 510_{N-2}, 520_{N-2} and 530_{N-2}) may be disposed on (e.g., in physical contact with) and electrically connected to the build-up layer L_{N-3}, and thus is electrically coupled to the through vias 1001 and the components (e.g., transistors 300) formed in the semiconductor substrate 202 through the contact plugs 208 and the build-up layers L₁ to L_{N-3} for providing routing function thereto; the build-up layer L_{N-1} (including 510_{N-1}, 520_{N-1} and 530_{N-1}) may be disposed on (e.g., in physical contact with) and electrically connected to the build-up layer L_{N-2}, and thus is electrically coupled to the through vias 1001 and the components (e.g., transistors 300) formed in the semiconductor substrate 202 through the contact plugs 208 and the build-up layers L₁ to L_{N-2} for providing routing function thereto; and the build-up layer L_{N} (including 510_{N}, 520_{N} and 530_{N}) may be disposed on (e.g., in physical contact with) and electrically connected to the build-up layer L_{N-1}, and thus is electrically coupled to the through vias 1001 and the components (e.g., transistors 300) formed in the semiconductor substrate 202 through the contact plugs 208 and the build-up layers L₁ to L_{N-1} for providing routing function thereto. Up to here, a circuit wafer W1′ is formed.

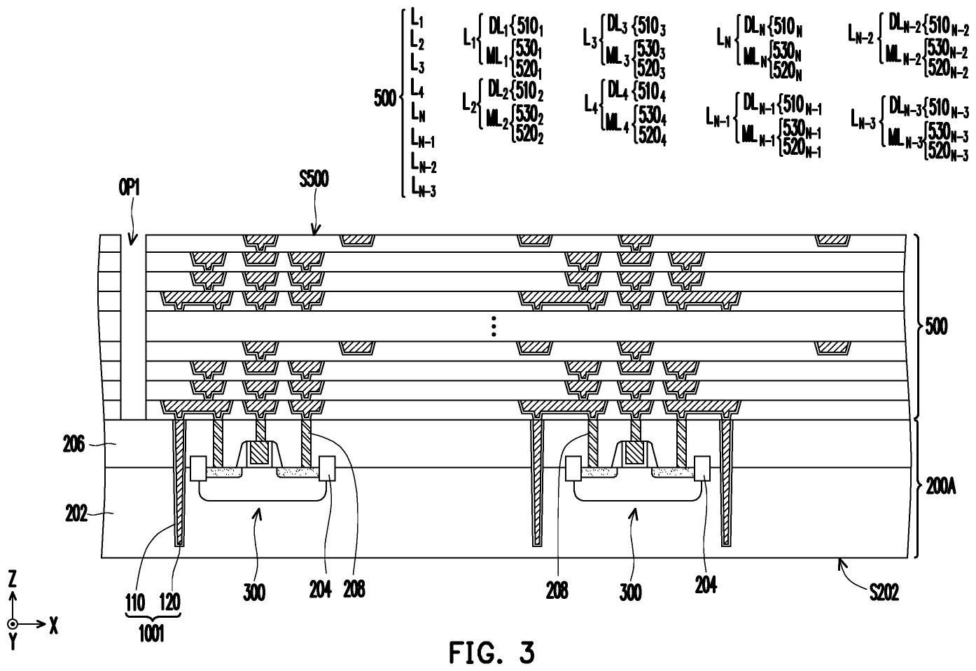

Referring to FIG. 3, in some embodiments, the interconnect 500 is patterned to form an openings OP1 penetrating through the dielectric layers 510 (e.g., 510₁, 510₂, 510₃, 510₄, . . . , 510_{N-3}, 510_{N-2}, 510_{N-1}, and 510_{N}), where the opening OP1 accessibly reveals the dielectric layer 206. In some embodiments, the opening OP1 has substantially vertical sidewalls, as shown in FIG. 3. Alternatively, the opening OP1 may be tapered from the dielectric layer 510_{N} of the interconnect 500 to the dielectric layer 206 of the substrate 200A. In a cross-sectional view along the direction Z, the shape of the opening OP1 may depend on the demand and/or product design requirements/layout, and is not intended to be limiting in the disclosure. On the other hand, in the top (plane) view on the X-Y plane, the shape of the opening OP1 is in a form of square shape (see FIG. 28). However, depending on the demand and/or product design requirements/layout, and the shape of the opening OP1 may be in form of an oval shape, a circular shape, a rectangular shape, a polygonal shape, or combinations thereof; the disclosure is not limited thereto. Only one opening OP1 is shown in FIG. 3 for illustrative purposes, however the disclosure is not limited thereto. The number of the opening OP1 can be one, two or more (see openings OP1 shown in FIG. 28), which may be selected and/or designated depending on the demand and/or product design requirements/layout.

In the embodiments of which a plurality of openings OP1 are included, sizes of the openings OP1 may vary to each other. In a non-limiting example, the sizes of some of the openings OP1 are substantially identical to each other, and the sizes of some of the openings OP1 are different from each other, as shown in FIG. 28. Alternatively, the sizes of all of the openings OP1 may be substantially identical to each other. Or, the sizes of all of the openings OP1 may be different from each other. The disclosure is not limited thereto.

The patterning process may be performed by using a photolithography and/or etching process. The etching process may include a dry etching, a wet etching, or a combination thereof. After the etching process, a cleaning step may be optionally performed, for example to clean and remove the residue generated from the etching process.

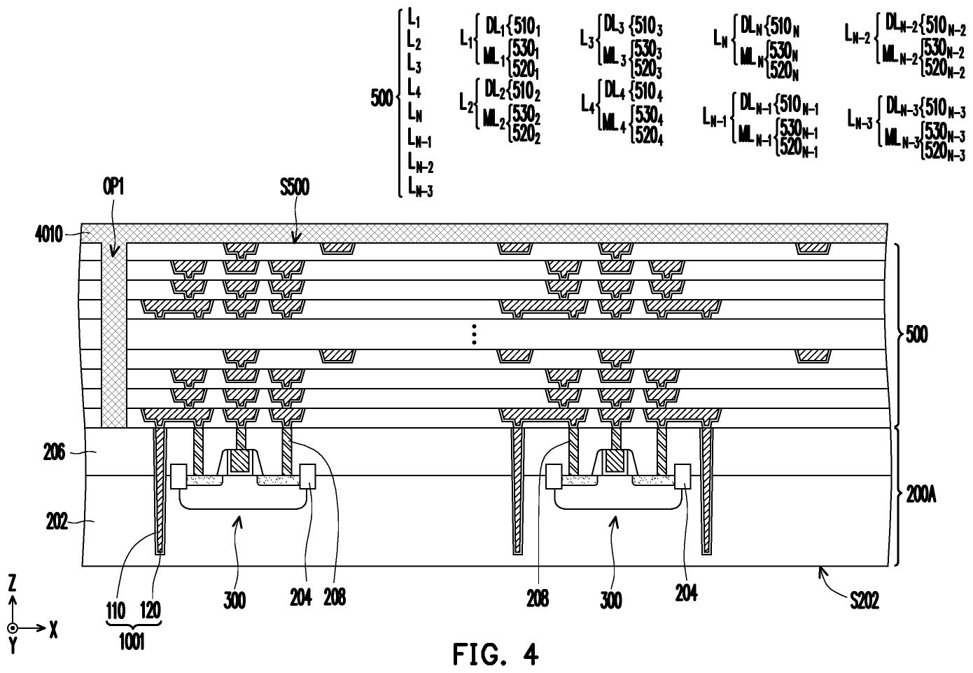

Referring to FIG. 4, in some embodiments, a thermal energy storage material 4010 is deposited on the interconnect 500 and further extend into the opening OP1. The opening OP1 is fully filled by the thermal energy storage material 4010, for example. As shown in FIG. 4, the thermal energy storage material 4010 may be in (e.g., physical) contact with the dielectric layer 206 exposed by the opening OP1. The thermal energy storage material 4010 may be formed by deposition (such as PVD or CVD) or the like. In a non-limiting example, the thermal energy storage material 4010 includes a thermal (energy) storage solid-solid phase change material, which is configured to readily undergo a solid-solid martensitic transformation from one crystalline structure to another different crystalline structure during a change in temperature. In some embodiments, the solid-solid martensitic transformation from one crystalline structure to another different crystalline structure is reversible. In such case, the thermal energy storage material 4010 is capable of storing the thermal energy (e.g., a heat generated by a hotspot such as the transistors 300) in form of mechanical deformation (e.g., from a first crystalline structure to a second different crystalline structure) and later release the thermal energy (e.g., heat) with a slower rate in form of mechanical deformation (e.g., from the second crystalline structure to the first different crystalline structure). Owing to such mechanism, the heat spikes in the semiconductor device of the disclosure can be alleviated. In other words, if considering the thermal energy storage material 4010 may be made of NiTi, the energy (generated from the hotspot(s) inside the semiconductor device) needs to go through the phase change phenomena (e.g., a shape change in the case of NiTi), where the energy has been used for phase change instead of immediately increasing the temperature (near and/at the hotspot(s) inside the semiconductor device), and later, the energy may be released in a lower rate, which helps to alleviate the problem of heat spikes (e.g., near and/at the hotspot(s) inside the semiconductor device). A material of the thermal energy storage material 4010 may include germanium(Ge)-antimony(Sb)-tellurium(Te) (GST), vanadium dioxide (VO₂), titanium (III) oxide, metal alloys, any other suitable metal alloys (such as a nickel-tin-based system including NiTi, NiTiHf, NiCuTi, NiCuTiHf or NiTiV, with or without doping nitrogen; or the like), or the like. For example, the thermal energy storage material 4010 includes a shape memory alloy (SMA) which is readily undergoing the solid-solid martensitic transformation. The disclosure is not specifically limited thereto. In some embodiments, a thermal conductivity of the thermal energy storage material 4010 is different from (e.g., greater than) a thermal conductivity of the dielectric layers 510 (e.g., 510₁, 510₂, 510₃, 510₄, . . . , 510_{N-3}, 510_{N-2}, 510_{N-1}, and 510_{N}).

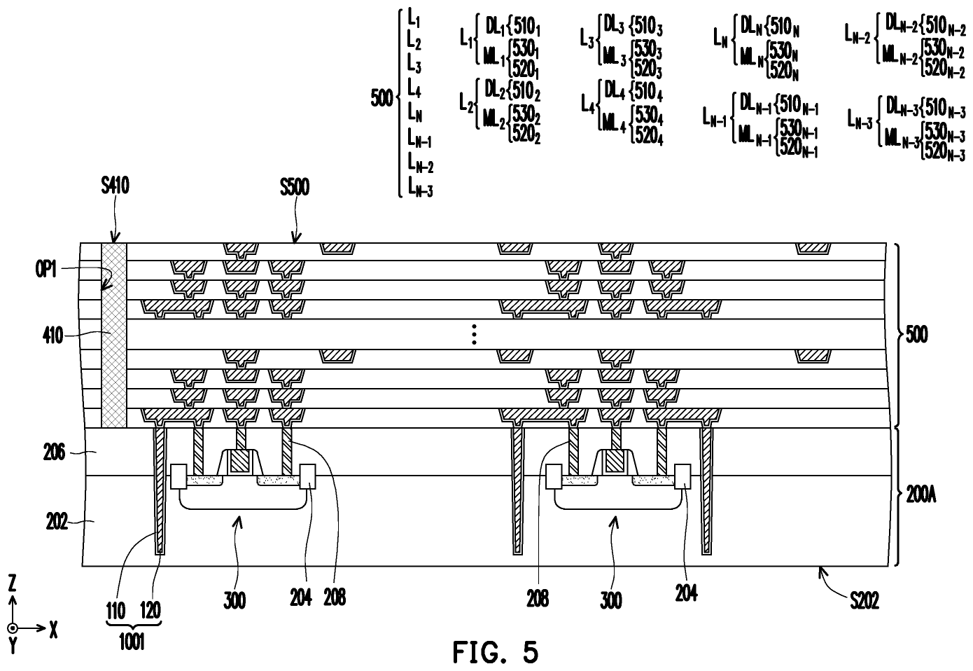

Referring to FIG. 5, in some embodiments, a planarization process is performed on the thermal energy storage material 4010 to form a thermal control portion 410 in the opening OP1. For example, the thermal energy storage material 4010 is planarized to remove the excess amount thereof located on the surface S510_{N} of the dielectric layer 510_{N} to form the thermal control portion 410 inside the opening OP1 and laterally next to the metallization layers ML₁ to ML_{N} of the interconnect 500. In some embodiments, the thermal control portion 410 is laterally covered by (e.g., in physical contact with) the dielectric structures DL₁ to DL_{N} of the interconnect 500. The thermal control portion 410 may be embedded in the build-up layers L₁ to L_{N} of the interconnect 500. In some embodiments, a surface S410 of the thermal control portion 410 is substantially level with the illustrated top surface S500 of the interconnect 500. In other words, the surface S410 of the thermal control portion 410 is substantially coplanar to the illustrated top surface S500 of the interconnect 500. As shown in FIG. 5, the thermal control portion 410 may completely penetrate through the interconnect 500. For example, the thermal control portion 410 is in form of a pillar or a column shape and next to the hotspot (such as the transistors 300). In a non-limiting example, the pillar form or the columnar form of the thermal control portion 410 is extended along the direction Z. Only one thermal control portion 410 is shown in FIG. 5 for illustrative purposes, however the disclosure is not limited thereto. The number of the thermal control portion 410 can be one, two or more (see FIG. 28), which may be selected and/or designated depending on the demand and/or product design requirements/layout.

The planarization process may include a grinding process, a CMP process, an etching process, the like, or combinations thereof. During the planarization process, the dielectric layer 510_{N}, the seed layer 520_{N} and/or the conductive layer 530_{N} may also be planarized. After planarizing, a cleaning process may be optionally performed, for example to clean and remove the residue generated from the planarization process. However, the disclosure is not limited thereto, and the planarization process may be performed through any other suitable method.

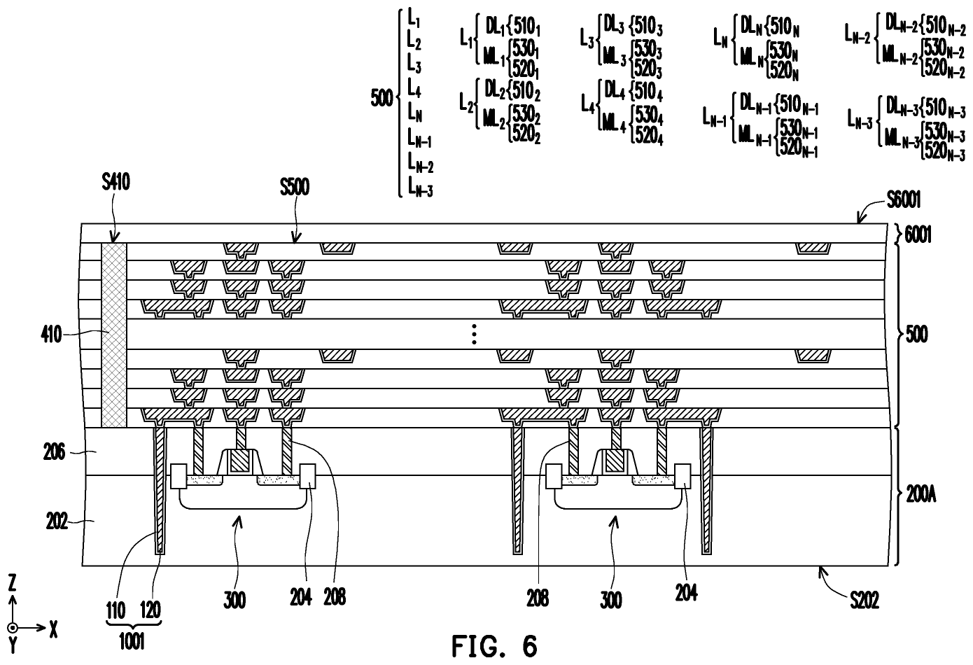

Referring to FIG. 6, in some embodiments, a dielectric layer 6001 is formed on the interconnect 500. For example, the dielectric layer 6001 is disposed on (e.g., in physical contact with) the illustrated top surface S500 (e.g., including S510_{N}, S520_{N} and S530_{N}) of the interconnect 500, where the interconnect 500 is disposed between the dielectric layer 6001 and the substrate 200A. The dielectric layer 6001 may be referred to as a bonding layer or a bonding dielectric layer. The dielectric layer 6001 may be a single layer or include a plurality of stacked dielectric sublayers. The dielectric layer 6001 may be formed by, but not limited to, conformally forming a blanket layer of the material used for forming the dielectric layer 6001 over the structure depicted in FIG. 5. In a non-limiting example, the material of the dielectric layer 6001 may include inorganic materials such as silicon oxide, silicon nitride, silicon oxynitride, silicon carbonitride or silicon oxy-carbonitride; other suitable dielectric layer; or a combination thereof. The dielectric layer 6001 may be formed by suitable fabrication techniques such as spin-on coating, CVD, ALD, PVD, or the like. An illustrated top surface S6001 of the dielectric layer 6001 may be level and may have a high degree of coplanarity, as shown in FIG. 6.

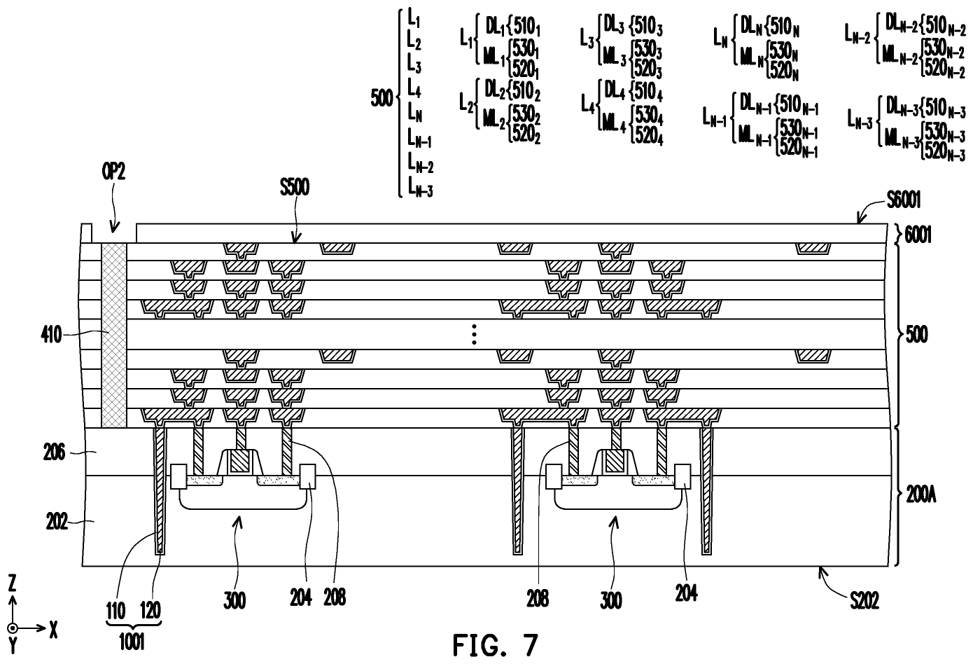

Referring to FIG. 7, in some embodiments, the dielectric layer 6001 is patterned to form an opening OP2 penetrating through the dielectric layer 6001, where the opening OP2 accessibly reveals the thermal control portion 410. In some embodiments, the opening OP2 has substantially vertical sidewalls, as shown in FIG. 7. Alternatively, the opening OP2 may be tapered from the illustrated top surface S6001 of the dielectric layer 6001 to the illustrated top surface S500 of the interconnect 500. In a cross-sectional view along the direction Z, the shape of the opening OP2 may depend on the demand and/or product design requirements/layout, and is not intended to be limiting in the disclosure. On the other hand, in the top (plane) view on the X-Y plane, the shape of the opening OP2 is in a form of rectangular shape (see FIG. 29). However, depending on the demand and/or product design requirements/layout, and the shape of the opening OP2 may be in form of an oval shape, a circular shape, a square shape, a polygonal shape, or combinations thereof; the disclosure is not limited thereto. Only one opening OP2 is shown in FIG. 3 for illustrative purposes, however the disclosure is not limited thereto. The number of the opening OP2 can be one, two or more (see openings OP2 shown in FIG. 29), which may be selected and/or designated depending on the demand and/or product design requirements/layout.

The patterning process may be performed by using a photolithography and/or etching process. The etching process may include a dry etching, a wet etching, or a combination thereof. After the etching process, a cleaning step may be optionally performed, for example to clean and remove the residue generated from the etching process.

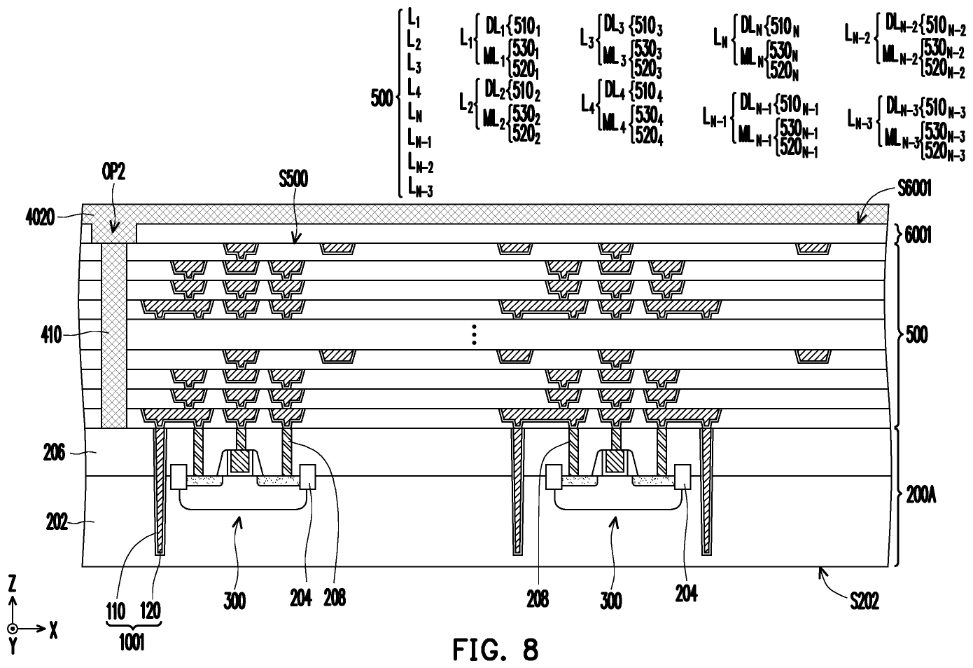

Referring to FIG. 8, in some embodiments, a thermal energy storage material 4020 is deposited on the dielectric layer 6001 and further extend into the opening OP2. The opening OP2 is fully filled by the thermal energy storage material 4020, for example. As shown in FIG. 8, the thermal energy storage material 4020 may be in (e.g., physical) contact with the thermal control portion 410 exposed by the opening OP2. The thermal energy storage material 4020 may be formed by deposition (such as PVD or CVD) or the like. In a non-limiting example, the thermal energy storage material 4020 includes a thermal (energy) storage solid-solid phase change material, which is configured to readily undergo a solid-solid martensitic transformation from one crystalline structure to another different crystalline structure during a change in temperature. In some embodiments, the solid-solid martensitic transformation from one crystalline structure to another different crystalline structure is reversible. In such case, the thermal energy storage material 4020 is capable of storing the thermal energy (e.g., a heat generated by a hotspot such as the transistors 300) in form of mechanical deformation (e.g., from a first crystalline structure to a second different crystalline structure) and later release the thermal energy (e.g., heat) with a slower rate in form of mechanical deformation (e.g., from the second crystalline structure to the first different crystalline structure). Owing to such mechanism, the heat spikes in the semiconductor device of the disclosure can be alleviated. Similarly, if considering the thermal energy storage material 4020 may be made of NiTi, the energy (generated from the hotspot(s) inside the semiconductor device) needs to go through the phase change phenomena (e.g., a shape change in the case of NiTi), where the energy has been used for phase change instead of immediately increasing the temperature (near and/at the hotspot(s) inside the semiconductor device), and later, the energy may be released in a lower rate, which helps to alleviate the problem of heat spikes (e.g., near and/at the hotspot(s) inside the semiconductor device). A material of the thermal energy storage material 4020 may include germanium(Ge)-antimony(Sb)-tellurium(Te) (GST), vanadium dioxide (VO₂), titanium (III) oxide, metal alloys, any other suitable metal alloys (such as a nickel-tin-based system including NiTi, NiTiHf, NiCuTi, NiCuTiHf or NiTiV, with or without doping nitrogen; or the like), or the like. For example, the thermal energy storage material 4020 includes a shape memory alloy (SMA) which is readily undergoing the solid-solid martensitic transformation. The disclosure is not specifically limited thereto. In some embodiments, a thermal conductivity of the thermal energy storage material 4020 is different from (e.g., greater than) a thermal conductivity of the dielectric layers 510 (e.g., 510₁, 510₂, 510₃, 510₄, . . . , 510_{N-3}, 510_{N-2}, 510_{N-1}, and 510_{N}). In a non-limiting example, the thermal energy storage material 4020 is the same as the thermal energy storage material 4010. In other non-limiting example, the thermal energy storage material 4020 is different from the thermal energy storage material 4010. The disclosure is not limited thereto.

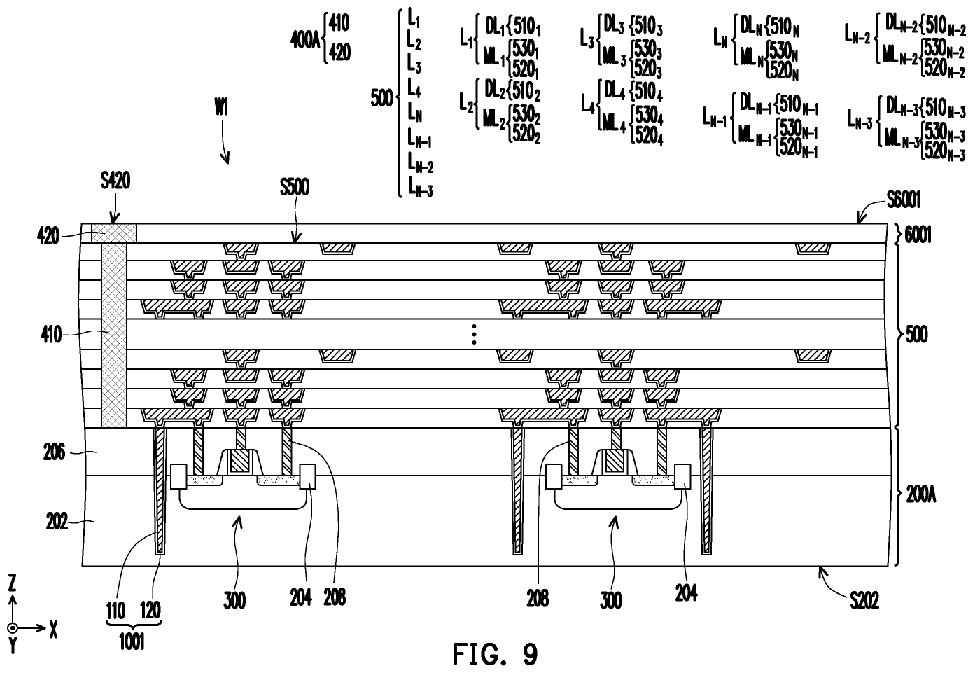

Referring to FIG. 9, in some embodiments, a planarization process is performed on the thermal energy storage material 4020 to form a thermal control portion 420 in the opening OP2. For example, the thermal energy storage material 4020 is planarized to remove the excess amount thereof located on the illustrated top surface S6001 of the dielectric layer 6001 so to form the thermal control portion 420 inside the opening OP2, where the thermal control portion 420 is laterally covered by the dielectric layer 6001. In some embodiments, the thermal control portion 420 is in physical contact with the dielectric layer 6001. The thermal control portions 420 may be embedded in the dielectric layer 6001 over the interconnect 500. In some embodiments, a surface S420 of the thermal control portion 420 is substantially level with the illustrated top surface S6001 of the dielectric layer 6001. In other words, the surface S420 of the thermal control portions 420 is substantially coplanar to the illustrated top surface S6001 of the dielectric layer 6001. As shown in FIG. 9, the thermal control portion 420 may completely penetrate through the dielectric layer 6001. For example, the thermal control portion 420 is in a segment, slab or plate form next to the hotspot (such as the transistors 300). Only one thermal control portion 420 is shown in FIG. 9 for illustrative purposes, however the disclosure is not limited thereto. The number of the thermal control portion 420 can be one, two or more (see FIG. 29), which may be selected and/or designated depending on the demand and/or product design requirements/layout.

The planarization process may include a grinding process, a CMP process, an etching process, the like, or combinations thereof. During the planarization process, the dielectric layer 6001 may also be planarized. After planarizing, a cleaning process may be optionally performed, for example to clean and remove the residue generated from the planarization process. However, the disclosure is not limited thereto, and the planarization process may be performed through any other suitable method. As shown in FIG. 9, the thermal control portion 410 may be physically connected to and thermally coupled to the thermal control portion 420, where the thermal control portion 410 and the thermal control portion 420 connected thereto may be collectively referred to as a thermal conductive element 400A. In the embodiments, the thermal control portion 410 is referred to as a vertical portion of the thermal conductive element 400A and the thermal control portion 420 is referred to as a horizontal portion of the thermal conductive element 400A. In some embodiments, a material of the thermal control portion 410 is the same as a material of the thermal control portion 420. In alternative embodiments, the material of the thermal control portion 410 is different from the material of the thermal control portion 420, which will be discussed in great details later. In some embodiments, for each thermal conductive element 400A, the thermal control portion 410 and the thermal control portion 420 are arranged in a one-to-one configuration.

In some embodiments, the thermal conductive element 400A is referred to as a thermal capacitor, thermal storage capacitor, a thermal control component, a thermal control module, a thermal management element, a thermal management component, or a thermal management module. Only one thermal control element 400A is shown in FIG. 9, however the number of the thermal control element 400A may be one, two, or more. The disclosure is not limited thereto. Owing to the thermal conductive element(s) 400A, the heat generated from the hotspot (e.g., the transistors 300) inside the semiconductor device of the disclosure can be drawn towards and stored inside the thermal conductive element(s) 400A, which alleviate the heat spikes in the hotspot (e.g., the transistors 300) inside the semiconductor device of the disclosure, thereby improving the reliability of the semiconductor device of the disclosure. In some embodiments, the thermal conductive element(s) 400A are electrically isolated from the interconnect 500 and the components (e.g., the transistors 300) of the substrate 200A and thermally coupled to the interconnect 500 and the components (e.g., the transistors 300) of the substrate 200A.

Up to here, a circuit wafer W1 is manufactured. For example, as shown in FIG. 9, the circuit tier W1 includes the substrate 200A (including a semiconductor substrate 202 formed with a plurality of transistors 300, a plurality of isolation structures 204, a dielectric layer 206, a plurality of contact plugs 208 and a plurality of through vias 1001), the interconnect 500 disposed on and electrically coupled to the substrate 200A, the dielectric layer 6001 disposed on the interconnect 500, and one or more thermal control elements 400A (including the thermal control portions 410 and 420) penetrating through the interconnect 500 and the dielectric layer 6001.

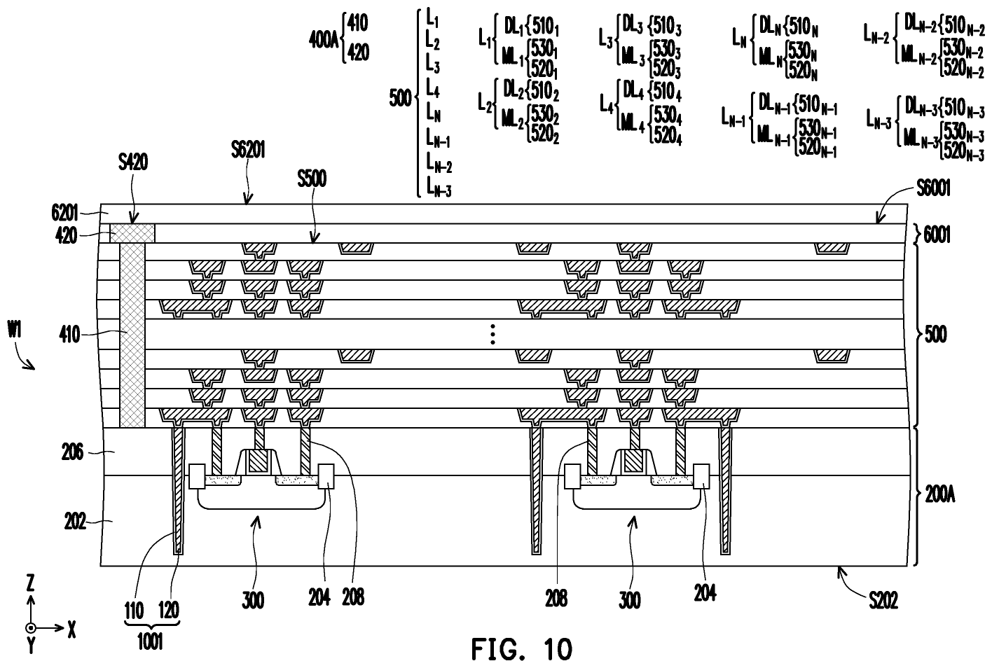

Referring to FIG. 10, in some embodiments, a bonding layer 6201 is formed on the dielectric layer 6001 and the thermal control element 400A. For example, the bonding layer 6201 is disposed on (e.g., in physical contact with) the illustrated top surface S6001 of the dielectric layer 6001 and the surface S420 of the thermal control portion 420, where the dielectric layer 6001 is disposed between the bonding layer 6201 and the interconnect 500. The bonding layer 6201 may be referred to as a dielectric layer or a bonding dielectric layer. The bonding layer 6201 may be a single layer or include a plurality of stacked dielectric sublayers. The bonding layer 6201 may be formed by, but not limited to, conformally forming a blanket layer of the material used for forming the bonding layer 6201 over the structure depicted in FIG. 9. In a non-limiting example, the material of the bonding layer 6201 may include inorganic materials such as silicon oxide, silicon nitride, silicon oxynitride, silicon carbonitride or silicon oxy-carbonitride; other suitable dielectric layer; or a combination thereof. The bonding layer 6201 may be formed by suitable fabrication techniques such as spin-on coating, CVD, ALD, PVD, or the like. An illustrated top surface S6201 of the bonding layer 6201 may be level and may have a high degree of coplanarity, as shown in FIG. 10. In some cases, the bonding layer 6201 may be considered as a part of the circuit wafer W1. Owing to the presence of the bonding layer 6201, a bonding process, which is performed later, can be more reliable due to the uniformity at the bonding surfaces.

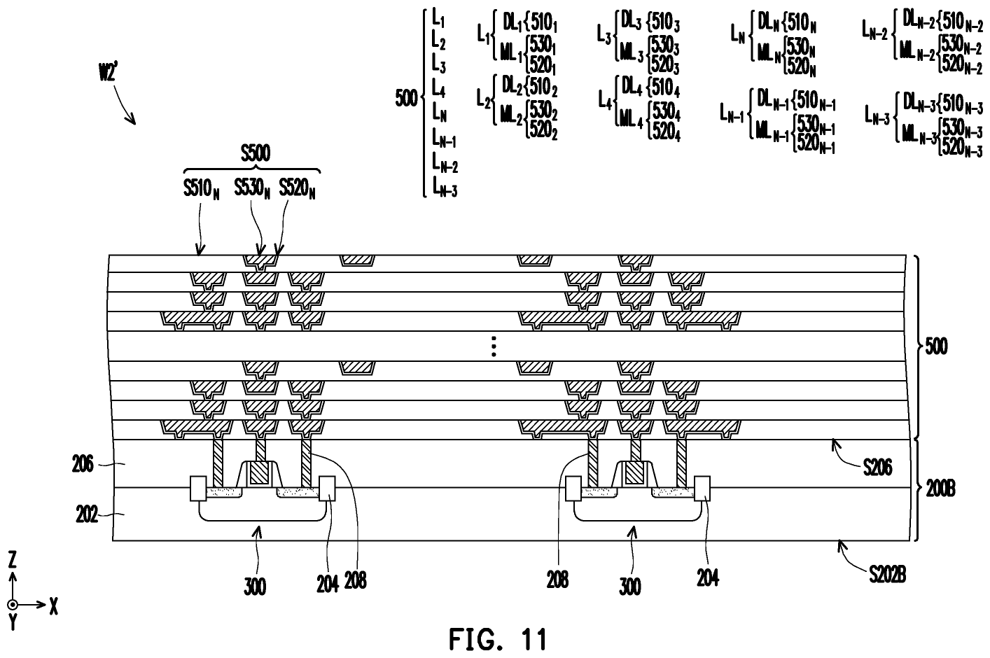

Referring to FIG. 11, in some embodiments, a circuit wafer W2′ is provided. For example, the circuit wafer W2′ includes a substrate 200B (including a semiconductor substrate 202 formed with a plurality of transistors 300, a plurality of isolation structures 204, a dielectric layer 206 and a plurality of contact plugs 208) and the interconnect 500 disposed on and electrically coupled to the substrate 200B. The details, formations and materials of the semiconductor substrate 202, the isolation structures 204, the dielectric layer 206, the contact plugs 208 and transistors 300 included in the substrate 200B and the interconnect 500 of the circuit wafer W2′ are similar to or substantially identical to the semiconductor substrate 202, the isolation structures 204, the dielectric layer 206, the contact plugs 208 and the transistors 300 included in the substrate 200A and the interconnect 500 of the circuit wafer W1 as described in FIG. 1 through FIG. 2, respectively; and thus are not repeated herein for brevity.

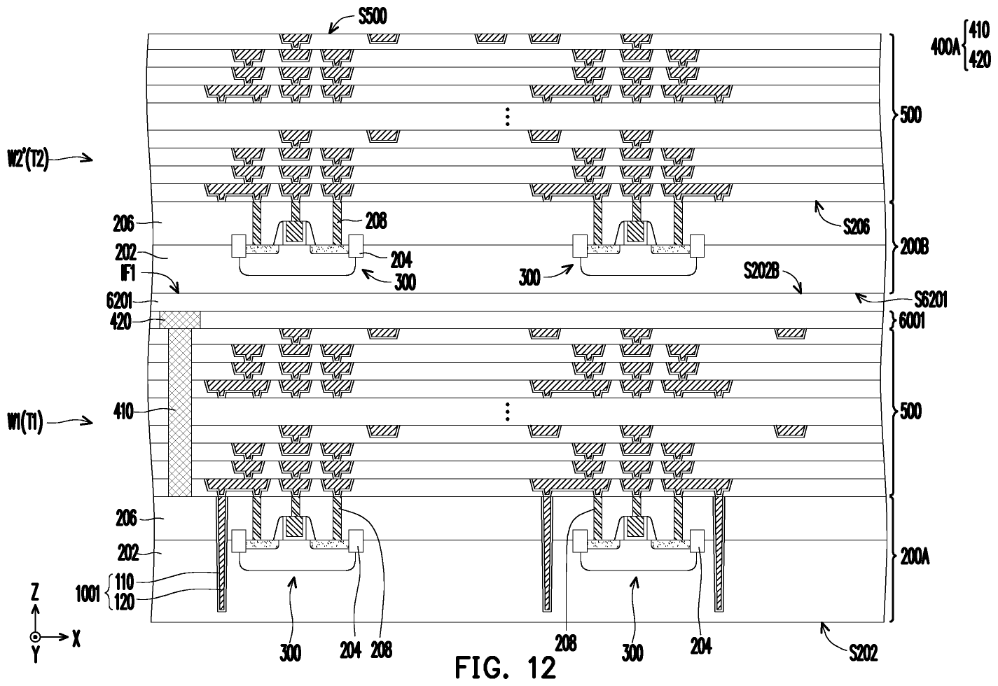

Referring to FIG. 12, in some embodiments, the circuit wafer W2′ is placed over and bonded to the circuit wafer W1 by wafer-on-wafer (WoW) bonding. In some embodiments, the circuit wafer W2′ is placed over the circuit wafer W1 for bonding by pick-and-place process. For example, the semiconductor substrate 202 of the circuit wafer W2′ is placed on (e.g., in physical contact with) the illustrated top surface S6201 of the bonding layer 6201 of the circuit wafer W1, and the semiconductor substrate 202 of the circuit wafer W2′ is then bonded to the illustrated top surface S6201 of the bonding layer 6201 of the circuit wafer W1 by bonding process including a dielectric-to-dielectric bonding (such as a ‘oxide’-to-‘silicon’ bonding or a ‘nitride’-to-‘silicon’ bonding). In such embodiments, a bonding interface IF1 including a dielectric-to-dielectric bonding interface (such as a ‘oxide’-to-‘silicon’ bonding interface or a ‘nitride’-to-‘silicon’ bonding interface) exists between the circuit wafer W2′ and the circuit wafer W1 (e.g., the bonding layer 6201), and which is considered as a bonding interface of the circuit wafer W2′ and the circuit wafer W1 (e.g., the bonding layer 6201). In certain embodiments, if there is a native oxide formed on the substrate 202 (e.g., a rear surface S202B) of the circuit wafer W2′, the bonding interface IF1 including a dielectric-to-dielectric bonding interface further includes a ‘oxide’-to-‘oxide’ bonding interface or a ‘nitride’-to-‘oxide’ bonding interface; the disclosure is not limited thereto. After bonding, the circuit wafer W1 may be referred to as a first tier T1 of a stacking structure depicted in FIG. 12, and the circuit wafer W2′ may be referred to as a second tier T2 of the stacking structure.

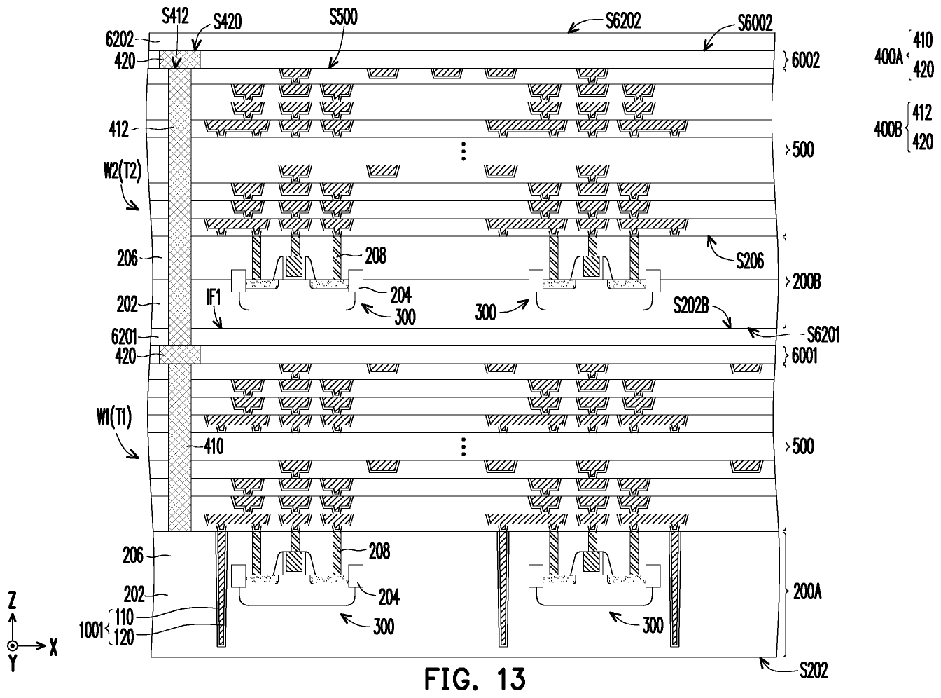

Referring to FIG. 13, in some embodiments, a thermal control portion 412, a dielectric layer 6002, and a thermal control portion 420 are sequentially formed over the circuit wafer W2′ to form a circuit wafer W2 (referred to as the second tier T2). As shown in FIG. 13, in the second tier T2, the thermal control portion 412 may be physically connected to and thermally coupled to the thermal control portion 420, where the thermal control portion 412 and the thermal control portion 420 connected thereto may be collectively referred to as a thermal conductive element 400B. In the embodiments, the thermal control portion 412 is referred to as a vertical portion of the thermal conductive element 400B and the thermal control portion 420 is referred to as a horizontal portion of the thermal conductive element 400B. In some embodiments, for the second tier T2, a material of the thermal control portion 412 is the same as a material of the thermal control portion 420. Alternatively, for the second tier T2, the material of the thermal control portion 412 may be different from the material of the thermal control portion 420, which will be discussed in great details later. In some embodiments, for each thermal conductive element 400B, the thermal control portion 412 and the thermal control portion 420 are arranged in a one-to-one configuration. As shown in FIG. 13, for each thermal control element 400B in the second tier T2, the thermal control portion 412 may completely penetrate through the interconnect 500, the substrate 200B and the bonding layer 6201, where the thermal control portion 412 is in form of a pillar or a column shape and next to the hotspot (such as the transistors 300).

In some embodiments, the thermal conductive element 400B is referred to as a thermal capacitor, a thermal storage capacitor, a thermal control component, a thermal control module, a thermal management element, a thermal management component, or a thermal management module. Only one thermal control element 400B is shown in FIG. 13, however the number of the thermal control element 400B may be one, two, or more. The disclosure is not limited thereto. Owing to the thermal conductive element(s) 400B, the heat generated from the hotspot (e.g., the transistors 300) in the second tier T2 inside the semiconductor device of the disclosure can be drawn towards and stored inside the thermal conductive element(s) 400B in the second tier T2, which alleviate the heat spikes in the hotspot (e.g., the transistors 300) inside the semiconductor device of the disclosure, thereby improving the reliability of the semiconductor device of the disclosure. In some embodiments, for the second tier T2, the thermal conductive element(s) 400B are electrically isolated from the interconnect 500 and the components (e.g., the transistors 300) of the substrate 200B and thermally coupled to the interconnect 500 and the components (e.g., the transistors 300) of the substrate 200B.

Up to here, a circuit wafer W2 is manufactured. For example, as shown in FIG. 13, the circuit tier W2 includes the substrate 200B (including a semiconductor substrate 202 formed with a plurality of transistors 300, a plurality of isolation structures 204, a dielectric layer 206, and a plurality of contact plugs 208), the interconnect 500 disposed on and electrically coupled to the substrate 200B, the dielectric layer 6002 disposed on the interconnect 500, and one or more thermal control elements 400B (including the thermal control portions 412 and 420) penetrating through the interconnect 500, the substrate 202B and the bonding layer 6201. The details, formation and material of the thermal control portion 412 and the dielectric layer 6002 are similar to or substantially identical to the details, formation and material of the thermal control portion 410 as described in FIGS. 3-5 in conjunction with FIG. 28 and the dielectric layer 6001 as described in FIG. 6, and the thermal control portion 420 have been described in FIGS. 7-9 in conjunction with FIG. 29; and thus, are not repeated herein for brevity.

In some embodiments, the thermal control portion 420 of the thermal control element 400B in the second tier T2 completely penetrates through the dielectric layer 6002 of the thermal control elements 400B in the second tier T2 so to physically connect to the thermal control portion 412 of the thermal control element 400B in the second tier T2, and the thermal control portion 412 of the thermal control element 400B in the second tier T2 completely penetrates through the interconnect 500, the substrate 202B and the bonding layer 6201 so to physically connect to and couple to the thermal control portion 420 of the thermal control element 400A in the first tier T1, as shown in FIG. 13. The thermal control portion 412 of the thermal control element 400B in the second tier T2 may be thermally coupled to the thermal control portion 420 of the thermal control element 400A in the first tier T1, as shown in FIG. 13. In certain embodiments, the thermal control portion 412 of the thermal control element 400B in the second tier T2 may be in physical contact with (e.g., directly contact) the thermal control portion 420 of the thermal control element 400A in the first tier T1.

Still referring to FIG. 13, in some embodiments, after forming the thermal control element 400B, a bonding layer 6202 is formed on the dielectric layer 6002 and the thermal control element 400B. For example, the bonding layer 6202 is disposed on (e.g., in physical contact with) the illustrated top surface S6002 of the dielectric layer 6002 and the surface S420 of the thermal control portion 420, where the dielectric layer 6002 is disposed between the bonding layer 6202 and the interconnect 500 of the circuit wafer W2. The bonding layer 6202 may be referred to as a dielectric layer or a bonding dielectric layer. The details, formation and material of the bonding layer 6202 are similar to or substantially identical to the details, formation and material of the bonding layer 6201 as described in FIG. 10, and thus are not repeated herein. An illustrated top surface S6202 of the bonding layer 6202 may be level and may have a high degree of coplanarity, as shown in FIG. 13. In some cases, the bonding layer 6202 may be considered as a part of the circuit wafer W2. Owing to the presence of the bonding layer 6202, a bonding process, which is performed later, can be more reliable due to the uniformity at the bonding surfaces.

Referring to FIG. 14, in some embodiments, a circuit wafer W3′ is provided. For example, the circuit wafer W3′ includes a substrate 200B (including a semiconductor substrate 202 formed with a plurality of transistors 300, a plurality of isolation structures 204, a dielectric layer 206 and a plurality of contact plugs 208) and the interconnect 500 disposed on and electrically coupled to the substrate 200B. The details, formations and materials of the semiconductor substrate 202, the isolation structures 204, the dielectric layer 206, the contact plugs 208 and transistors 300 included in the substrate 200B and the interconnect 500 of the circuit wafer W3′ are similar to or substantially identical to the semiconductor substrate 202, the isolation structures 204, the dielectric layer 206, the contact plugs 208 and transistors 300 included in the substrate 200A and the interconnect 500 of the circuit wafer W1 as described in FIG. 1 through FIG. 2, respectively; and thus are not repeated herein for brevity.

In some embodiments, the circuit wafer W3′ is placed over and bonded to the circuit wafer W2 by WoW bonding, as shown in FIG. 14. In some embodiments, the circuit wafer W3′ is placed over the circuit wafer W2 for bonding by pick-and-place process. For example, the semiconductor substrate 202 of the circuit wafer W3′ is placed on (e.g., in physical contact with) the illustrated top surface S6202 of the bonding layer 6202 of the circuit wafer W2, and the semiconductor substrate 202 of the circuit wafer W3′ is then bonded to the illustrated top surface S6202 of the bonding layer 6202 of the circuit wafer W2 by bonding process including a dielectric-to-dielectric bonding (such as a ‘oxide’-to-‘silicon’ bonding or a ‘nitride’-to-‘silicon’ bonding). In such embodiments, a bonding interface IF2 including a dielectric-to-dielectric bonding interface (such as a ‘oxide’-to-‘silicon’ bonding interface or a ‘nitride’-to-‘silicon’ bonding interface) exists between the circuit wafer W3′ and the circuit wafer W2 (e.g., the bonding layer 6202), and which is considered as a bonding interface of the circuit wafer W3′ and the circuit wafer W2 (e.g., the bonding layer 6202). In certain embodiments, if there is a native oxide on the substrate 202 (e.g., a rear surface S202B) of the circuit wafer W2′, the bonding interface IF2 including a dielectric-to-dielectric bonding interface further includes a ‘oxide’-to-‘oxide’ bonding interface or a ‘nitride’-to-‘oxide’ bonding interface; the disclosure is not limited thereto. After bonding, the circuit wafer W3′ may be referred to as a third tier T3 of the stacking structure depicted in FIG. 14.

Still referring to FIG. 14, in some embodiments, after bonding the circuit wafer W3′ to the circuit wafer W2, a thermal control portion 412 is formed to penetrate through the interconnect 500, the substrate 200B and the bonding layer 6202. The formation and material of the thermal control portion 412 are similar to or substantially identical to the details, formation and material of the thermal control portion 410 as described in FIGS. 3-5 in conjunction with FIG. 28, and thus are not repeated herein for brevity.

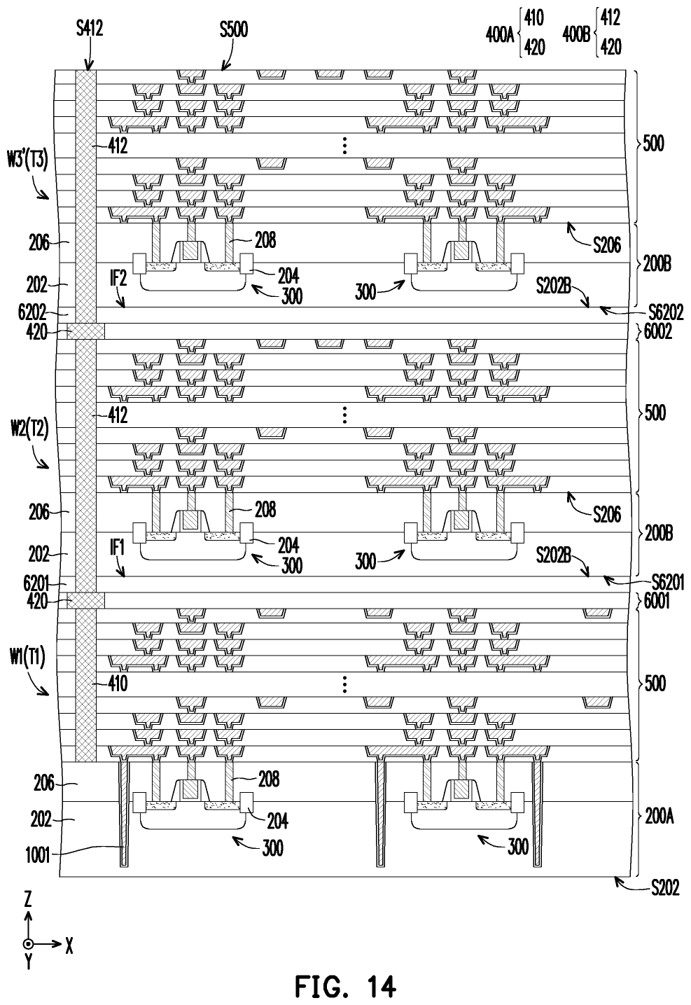

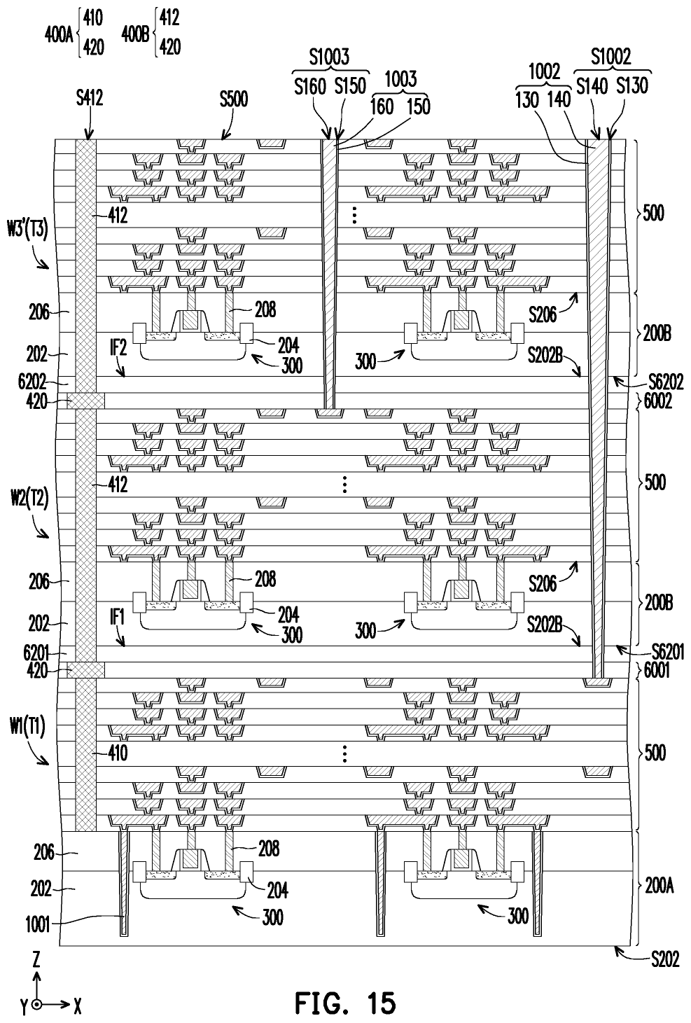

Referring to FIG. 15, in some embodiments, at least one through via 1002 (including a liner 130 and a conductive via 140) and at least one through via 1003 (including a liner 150 and a conductive via 160) are formed in the stacking structure depicted FIG. 14. As shown in FIG. 15, for illustrative purposes, the at least one through via 1002 may include one through via 1002 and the at least one through via 1003 may include one through via 1003, however the disclosure is not limited thereto. The number of each of the through via 1002 and the through via 1003 may be more than one, which can be selected and/or designated based on the demand and/or product design requirements/layout. The details, formation and material of the through vias 1002 and 1003 are similar to or substantially identical to the details (e.g., configuration such as shape), formation and material of the through vias 1001 as described in FIG. 1, and thus are not repeated therein. As shown in FIG. 15, a bottom of the conductive via 140 of the through vias 1002 is accessibly revealed by the liner 130, and a bottom of the conductive via 160 of the through vias 1003 is accessibly revealed by the liner 150, for example. Alternatively, the bottom and the sidewall of the conductive via 140 of the through vias 1002 is physically covered by the liner 130, and the bottom and the sidewall of the conductive via 160 of the through vias 1003 is physically covered by the liner 150.

In some embodiments, as shown in FIG. 15, an illustrated top surface S1002 (e.g., including a surface S130 of the liner 130 and a surface S140 of the conductive via 140) of the through via 1002 and an illustrated top surface S1003 (e.g., including a surface S150 of the liner 150 and a surface S160 of the conductive via 160) of the through via 1003 are substantially level with the illustrated top surface S500 (e.g., including S510_{N}, S520_{N} and S530_{N}) of the interconnect 500 of the third tier T3. In other words, the illustrated top surface S1002 (e.g., including S130 and S140) of the through via 1002 and the illustrated top surface S1003 (e.g., including S150 and S160) of the through via 1003 are substantially coplanar to the illustrated top surface S500 (e.g., including S510_{N}, S520_{N} and S530_{N}) of the interconnect 500.

In a non-limiting example, the through via 1002 penetrates through the second tier T2 and the third tier T3 of the stacking structure and further extending into the first tier T1 so to electrically connect the first tier T1, the second tier T2 and the third tier T3 to each other through (e.g., physically) contacting the through via 1002 and the metal features of the first tier T1, the second tier T2 and the third tier T3 (e.g., the metallization layers of the interconnects 500 thereof). In such case, the through via 1003 penetrates through the third tier T3 of the stacking structure and further extending into the second tier T2 so to electrically connect the second tier T2 and the third tier T3 to each other through (e.g., physically) contacting the through via 1003 and the metal features of the second tier T2 and the third tier T3 (e.g., the metallization layers of the interconnects 500 thereof).

In another non-limiting example, the through via 1002 penetrates through the second tier T2 and the third tier T3 of the stacking structure and further extending into the first tier T1 so to electrically connect the first tier T1 and the third tier T3 to each other through (e.g., physically) contacting the through via 1002 and the metal features of the first tier T1 and the third tier T3 (e.g., the metallization layers of the interconnects 500 thereof). In such alternative case, the through via 1003 penetrates through the third tier T3 of the stacking structure and further extending into the second tier T2 so to electrically connect the second tier T2 and the third tier T3 to each other through (e.g., physically) contacting the through via 1003 and the metal features of the second tier T2 and the third tier T3 (e.g., the metallization layers of the interconnects 500 thereof) and further electrically connect the first tier T1 and the second tier T2 to each other through contacting the through via 1002 and the third tier T3.

In the embodiments of which multiple through vias 1002 are included, the through vias 1002 penetrates through the second tier T2 and the third tier T3 of the stacking structure and further extending into the first tier T1, where one or some of the through vias 1002 electrically connect the first tier T1, the second tier T2 and the third tier T3 to each other through (e.g., physically) contacting the through via 1002 and the metal features of the first tier T1, the second tier T2 and the third tier T3 (e.g., the metallization layers of the interconnects 500 thereof), and the rest of the through vias 1002 electrically connect the first tier T1 and the third tier T3 to each other through (e.g., physically) contacting the through via 1002 and the metal features of the first tier T1 and the third tier T3 (e.g., the metallization layers of the interconnects 500 thereof), with one or more through vias 1003 penetrate through the third tier T3 of the stacking structure and further extending into the second tier T2 so to electrically connect the second tier T2 and the third tier T3 to each other through (e.g., physically) contacting the one or more through via 1003 and the metal features of the second tier T2 and the third tier T3 (e.g., the metallization layers of the interconnects 500 thereof). In certain embodiments of which the electrical connection among the first tier T1, the second tier T2 and the third tier T3 is properly established by the through vias 1002, the through vias 1003 may be omitted.

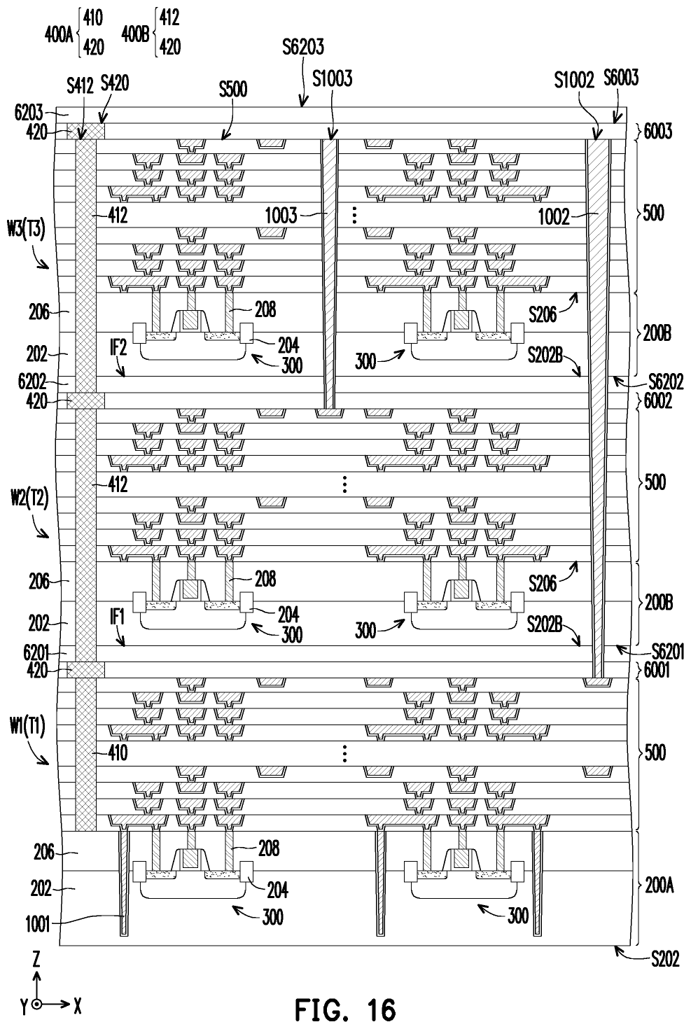

Referring to FIG. 16, in some embodiments, in some embodiments, after forming the through vias 1002 and 1003, a dielectric layer 6003 and a thermal control portion 420 are sequentially formed over the circuit wafer W3′ to form a circuit wafer W3 (referred to as the third tier T3). As shown in FIG. 16, in the third tier T3, the thermal control portion 412 may be physically connected to and thermally coupled to the thermal control portion 420, where the thermal control portion 412 and the thermal control portion 420 connected thereto may be collectively referred to as a thermal conductive element 400B of the third tier T3. In the embodiments, for the thermal conductive element 400B of the third tier T3, the thermal control portion 412 is referred to as a vertical portion of the thermal conductive element 400B and the thermal control portion 420 is referred to as a horizontal portion of the thermal conductive element 400B. In some embodiments, for the third tier T3, a material of the thermal control portion 412 is the same as a material of the thermal control portion 420. Alternately, for the third tier T3, the material of the thermal control portion 412 may be different from the material of the thermal control portion 420, which will be discussed in great details later. In some embodiments, for each thermal conductive element 400B in the third tier T3, the thermal control portion 412 and the thermal control portion 420 are arranged in a one-to-one configuration. As shown in FIG. 16, for each thermal control element 400B in the third tier T3, the thermal control portion 412 may completely penetrate through the interconnect 500, the substrate 200B and the bonding layer 6202, where the thermal control portion 412 is in form of a pillar or a column shape and next to the hotspot (such as the transistors 300).

Only one thermal control element 400B is shown in FIG. 16, however the number of the thermal control element 400B may be one, two, or more. The disclosure is not limited thereto. Owing to the thermal conductive element(s) 400B, the heat generated from the hotspot (e.g., the transistors 300) in the third tier T3 inside the semiconductor device of the disclosure can be drawn towards and stored inside the thermal conductive element(s) 400B, which alleviate the heat spikes in the hotspot (e.g., the transistors 300) inside the semiconductor device of the disclosure, thereby improving the reliability of the semiconductor device of the disclosure. In some embodiments, for in the third tier T3, the thermal conductive element(s) 400B are electrically isolated from the interconnect 500 and the components (e.g., the transistors 300) of the substrate 200B and thermally coupled to the interconnect 500 and the components (e.g., the transistors 300) of the substrate 200B.

Up to here, a circuit wafer W3 is manufactured. For example, as shown in FIG. 16, the circuit tier W3 includes the substrate 200B (including a semiconductor substrate 202 formed with a plurality of transistors 300, a plurality of isolation structures 204, a dielectric layer 206 and a plurality of contact plugs 208), the interconnect 500 disposed on and electrically coupled to the substrate 200B, the dielectric layer 6003 disposed on the interconnect 500, and one or more thermal control elements 400B (including the thermal control portions 412 and 420) penetrating through the interconnect 500, the substrate 202B and the bonding layer 6202. The details, formation and material of the dielectric layer 6003 are similar to or substantially identical to the details, formation and material of the dielectric layer 6001 as described in FIG. 6, and the thermal control portion 420 has been described in FIGS. 7-9 in conjunction with FIG. 29; and thus, are not repeated herein for brevity. In some embodiments, the thermal control portion 420 of the thermal control element 400B in the third their T3 completely penetrates through the dielectric layer 6003 so to physically connect to the thermal control portion 412 of the thermal control element 400B in the third their T3, and the thermal control portion 412 of the thermal control element 400B in the third their T3 completely penetrates through the interconnect 500, the substrate 202B and the bonding layer 6202 so to physically connect to and couple to the thermal control portion 420 of the thermal control element 400B in the second tier T2, as shown in FIG. 16. The thermal control portion 412 of the thermal control element 400B in the third tier T3 may be thermally coupled to the thermal control portion 420 of the thermal control element 400B in the second tier T2, as shown in FIG. 16. In certain embodiments, the thermal control portion 412 of the thermal control element 400B in the third tier T3 may be in physical contact with (e.g., directly contact) the thermal control portion 420 of the thermal control element 400B in the second tier T2.

Still referring to FIG. 16, in some embodiments, a bonding layer 6203 is formed on the dielectric layer 6003 and the thermal control elements 400B included in the circuit wafer W3. For example, the bonding layer 6203 is disposed on (e.g., in physical contact with) the illustrated top surface S6003 of the dielectric layer 6003 and the surface S420 of the thermal control portion 420, where the dielectric layer 6003 is disposed between the bonding layer 6203 and the interconnect 500 of the circuit wafer W3. The bonding layer 6203 may be referred to as a dielectric layer or a bonding dielectric layer. The details, formation and material of the bonding layer 6203 are similar to or substantially identical to the details, formation and material of the bonding layer 6201 as described in FIG. 10, and thus are not repeated herein. An illustrated top surface S6203 of the bonding layer 6203 may be level and may have a high degree of coplanarity, as shown in FIG. 16. In some cases, the bonding layer 6203 may be considered as a part of the circuit wafer W3. Owing to the presence of the bonding layer 6203, a bonding process, which is performed later, can be more reliable due to the uniformity at the bonding surfaces.

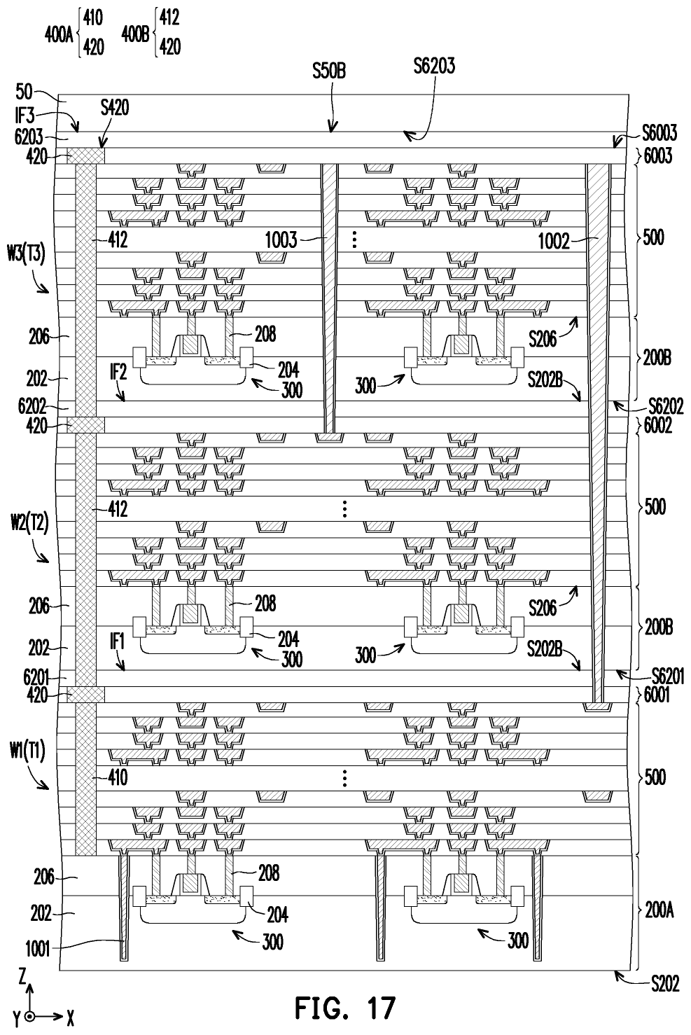

Referring to FIG. 17, in some embodiments, a carrier 50 is provided on and bonded to the circuit wafer W3 by a WoW bonding process. In some embodiments, the carrier 50 is placed over the circuit wafer W3 for bonding by pick-and-place process. The details of the carrier 50 may be similar to or substantially identical to the details of the semiconductor substrate 202 as described in FIG. 1, and thus are not repeated herein for brevity. For example, the carrier 50 is a silicon substrate being free of active components. For example, the carrier 50 is placed on (e.g., in physical contact with) the illustrated top surface S6203 of the bonding layer 6203 of the circuit wafer W3, and the carrier 50 is then bonded to the illustrated top surface S6203 of the bonding layer 6203 of the circuit wafer W3 by a bonding process including dielectric-to-dielectric bonding (such as a ‘oxide’-to-‘silicon’ bonding or a ‘nitride’-to-‘silicon’ bonding). In such embodiments, a bonding interface IF3 including a dielectric-to-dielectric bonding interface (such as a ‘oxide’-to-‘silicon’ bonding interface or a ‘nitride’-to-‘silicon’ bonding interface) exists between the carrier 50 and the circuit wafer W3 (e.g., the bonding layer 6203), and which is considered as a bonding interface of the carrier 50 and the circuit wafer W3 (e.g., the bonding layer 6203). In certain embodiments, if there is a native oxide formed on the carrier 50 (e.g., a surface S50B), the bonding interface IF3 including a dielectric-to-dielectric bonding interface further includes a ‘oxide’-to-‘oxide’ bonding interface or a ‘nitride’-to-‘oxide’ bonding interface; the disclosure is not limited thereto. After bonding, the carrier 50 may be referred to as a supporting substrate of the stacking structure including the tiers T1 to T3. In addition, due to the carrier is the silicon substrate, the carrier 50 may further be a heat dissipating element for the semiconductor device 10000A (in FIG. 21).

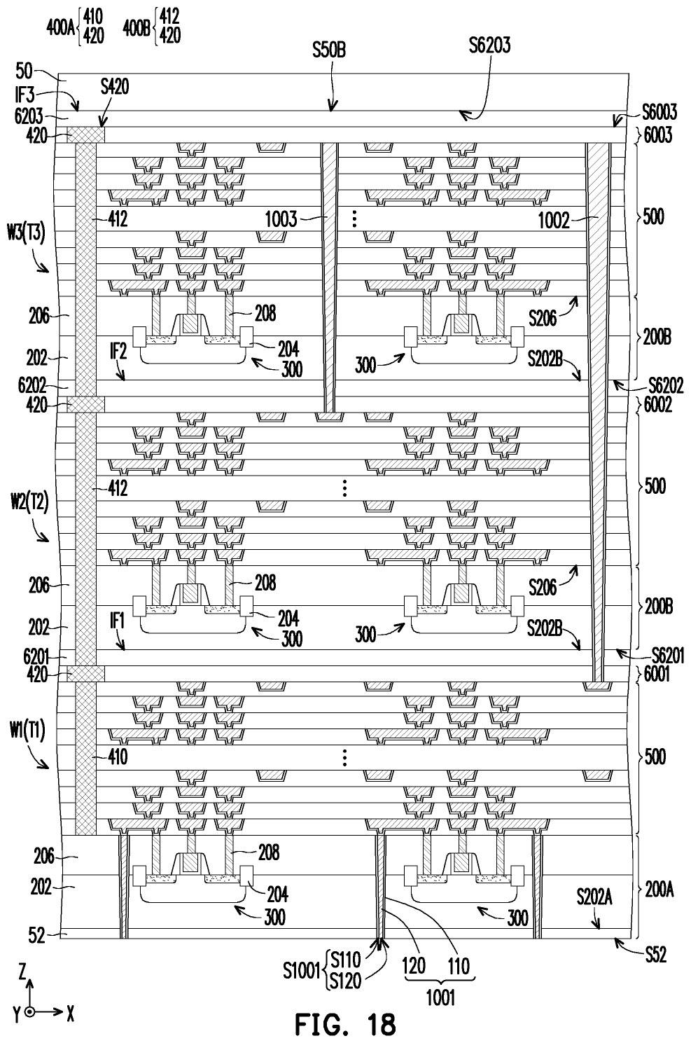

Referring to FIG. 17 and FIG. 18, in some embodiments, a planarization process is performed to the semiconductor substrate 202 of the circuit wafer W1 (in the first tier T1) so to thin down the semiconductor substrate 202 of the circuit wafer W1 and accessibly reveal the through vias 1001 therefrom. As shown in FIG. 18, a portion of the semiconductor substrate 202 and portions of liners 110 may be removed from the circuit wafer W1 of the stacking structure so to expose the conductive vias 120 therefrom. In some cases, during removing the portion of the semiconductor substrate 202 and the portions of liners 110 of the circuit wafer W1, portions of the conductive vias 120 of the circuit wafer W1 may also be slightly removed.

Then, for example, a patterning process is performed on the semiconductor substrate 202 of the circuit wafer W1, where the semiconductor substrate 202 is further partially removed so to form a semiconductor substrate 202 having a rear surface S202A, such that a portion of each of the through vias 1001 (including a portion of each of the liners 110 and a portion of each of the conductive vias 120) protrude out of the rear surface S202A of the semiconductor substrate 202 of the circuit wafer W1. The patterning process may include an etching process (such as a wet each or a dry etch) or the like. The disclosure is not limited thereto.

As shown in FIG. 18, the liners 110 may cover the entire sidewalls of the conductive vias 120 and exposes the bottoms of the conductive vias 120; however, the disclosure is not limited thereto. In one embodiment, the liners 110 may be cover only the sidewalls of the conductive vias 120 being embedded in the semiconductor substrate 202 having the rear surface S202A. That is, for example, the liners 110, which are disposed on the sidewalls of the portions of the conductive vias 120 protruding from the rear surface S202A of the semiconductor substrate 202 after the planarization process, are removed during the patterning process. In one embodiment, the liners 110 may be cover the sidewalls and the bottoms of the conductive vias 120. That is, for example, the liners 110, which are disposed on the sidewalls and the bottoms of the portions of the conductive vias 120 protruding from the rear surface S202A of the semiconductor substrate 202 after the planarization process, are remained during the patterning process. The planarization process may include a grinding process, a CMP process, an etching process, combination thereof, or the like. The etching process may include a dry etching, a wet etching, or a combination thereof.

In some embodiments, a dielectric material (not shown) is formed over the rear surface S202A of the semiconductor substrate 202 of the circuit wafer W1. In some embodiments, the dielectric material is directly and conformally formed on the semiconductor substrate 202 and the through vias 1001 of the circuit wafer W1, where the semiconductor substrate 202 and the through vias 1001 of the circuit wafer W1 are covered by and in physical contact with the dielectric material. In some embodiments, the dielectric material may be formed as a blanket layer of dielectric material. In some embodiments, the dielectric material may be a polymer layer which made of PI, PBO, BCB, or any other suitable polymer-based dielectric material. In some embodiments, the dielectric material may be Ajinomoto Buildup Film (ABF), Solder Resist (SR) film, or the like. In some embodiments, the dielectric material may be formed by a suitable fabrication technique such as spin-coating, lamination, deposition, or the like. Thereafter, another planarization process is performed on the dielectric material to form a dielectric layer 52 laterally covering the through vias 1001 protruding out of the semiconductor substrate 202 of the circuit wafer W1, where the dielectric layer 52 accessibly exposes surfaces S1001 (including a surface S110 of the liners 110 and a surface S120 of the conductive vias 120) of the through vias 1001. In some embodiments, during the another planarization process, the dielectric material laterally located next to the protruded portions of the through vias 1001 over the rear surface S202A of the semiconductor substrate 202 are remained, while the rest of the dielectric material are removed; and the remained dielectric material constitutes the dielectric layer 52.

In some embodiments, the another planarization process may include a grinding process, a CMP process, an etching process, combination thereof, or the like. The etching process may include a dry etching, a wet etching, or a combination thereof. As shown in FIG. 18, a surface S52 of the dielectric layer 52 is substantially level with the surfaces S1001 of the through vias 1001, for example. That is, the surface S52 of the dielectric layer 52 is substantially coplanar to the surfaces S1001 of the through vias 1001. In some embodiments, after each of the planarization processes, a cleaning step may be optionally performed to clean and remove the residue generated from the planarization process. However, the disclosure is not limited thereto, and the each of the planarization processes may be performed through any other suitable method.

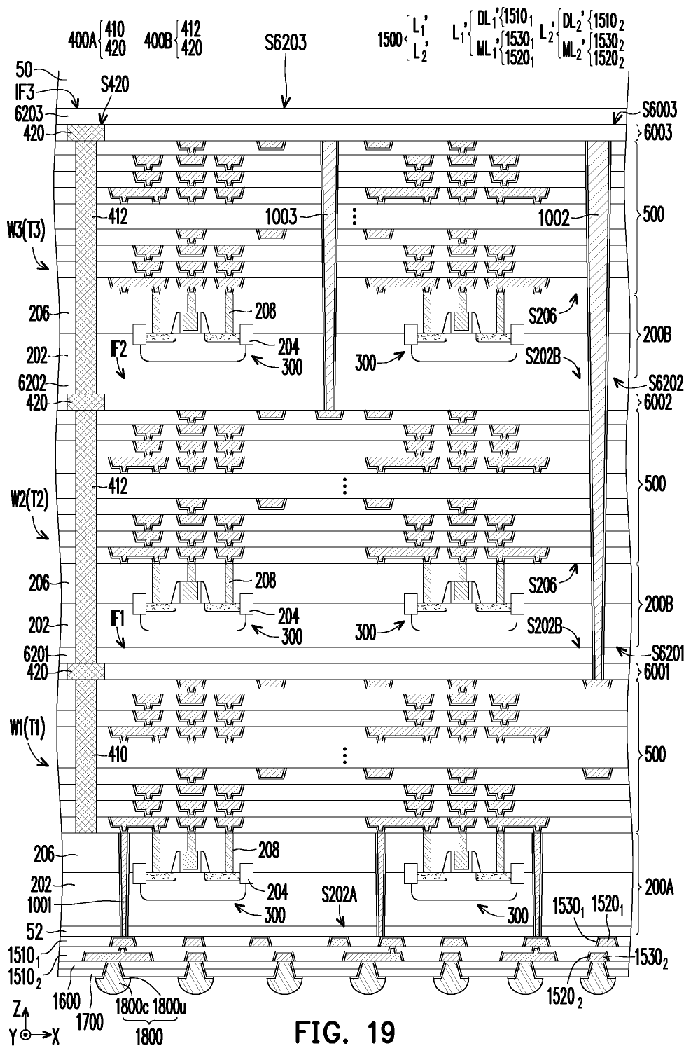

Referring to FIG. 19, in some embodiments, a redistribution circuit structure 1500 is formed over the circuit wafer W1, where the redistribution circuit structure 1500 is electrically coupled to the through vias 1001. As shown in FIG. 19 for illustrated purposes, the redistribution circuit structure 1500 includes only two build-up layers (e.g., L₁′ and L₂′), however the disclosure is not limited thereto. The number of the build-up layer included in the redistribution circuit structure 1500 may be one, two, or more, depending on the demand and/or product design requirements/layout. The build-up layer L₁′ may include a dielectric layer 1510₁, a seed layer 1520₁ and a conductive layer 1530₁, and the build-up layer L₂′ may include a dielectric layer 1510₂, a seed layer 1520₂ and a conductive layer 1530₂, as shown in FIG. 19. The details, formation and material of the dielectric layer 1510₁, the seed layer 1520₁ and the conductive layer 1530₁ included in the build-up layer L₁′ and the details, formation and material of the dielectric layer 1510₂, the seed layer 1520₂ and the conductive layer 1530₂ included in the build-up layer L₂′ are similar to the details, formation and material of the dielectric layer 510₁, the seed layer 520₁ and the conductive layer 530₁ included in the build-up layer L₁ as described in FIG. 1, and thus are not repeated herein.

The dielectric layer 1510₁ may be referred to as a dielectric structure DL₁′ of the build-up layer L₁′, and the seed layer 1520₁ and the conductive layer 1530₁ may be referred to as a metallization layer ML₁′ (or a redistribution layer) of the build-up layer L₁′. On the other hand, the dielectric layer 1510₂ may be referred to as a dielectric structure DL₂′ of the build-up layer L₂′, and the seed layer 1520₂ and the conductive layer 1530₂ may be referred to as a metallization layer ML₂′ (or a redistribution layer) of the build-up layer L₂′. The metallization layers ML₁′ and ML₂′ may be collectively referred to as a routing structure of the redistribution circuit structure 1500. In some embodiments, line dimensions (e.g., thickness and width) of the metallization layers ML₁′ and ML₂′ of the redistribution circuit structure 1500 are gradually increased along a direction from the circuit wafer W1 to the metallization layer ML₂′. In some alternative embodiments, the seed layers 1520₁, 1520₂ may be omitted.

For example, the build-up layer L₁′ is disposed on the surface S52 of the dielectric layer 52 and electrically connected to the through vias 1001 by direct contact, so to be electrically coupled to components (such as transistors 300) included in the circuit wafers W1, W2 and W3 (e.g., further through the interconnects 500 and/or the through vias 1002, 1003). In such case, the build-up layer L₂′ is disposed on the build-up layer L₁′ and electrically coupled to the through vias 1001 through the build-up layer L₁′, so to be electrically coupled to components (such as transistors 300) included in the circuit wafers W1, W2 and W3 (e.g., further through the interconnects 500 and/or the through vias 1002, 1003). That is, the redistribution circuit structure 1500 provides the routing functions to the components (such as transistors 300) included in the circuit wafers W1, W2 and W3.

Continued on FIG. 19, in some embodiments, after forming the redistribution circuit structure 1500, a dielectric layer 1600, a dielectric layer 1700 and a plurality of conductive terminals 1800 are sequentially formed over the redistribution circuit structure 1500, where the conductive terminals 1800 are disposed over and connected to the redistribution circuit structure 1500. As shown in FIG. 19, the dielectric layer 1600 may be formed on the redistribution circuit structure 1500, and a plurality of openings (not labeled) formed in and penetrating through the dielectric layer 1600 may accessibly reveal some of the redistribution circuit structure 1500 (e.g., the metallization layer ML₂′). The dielectric layer 1600 may be referred to as a passivation layer. In such cases, the dielectric layer 1700 is formed on the dielectric layer 1600, and a plurality of openings (not labeled) formed in and penetrating through the dielectric layer 1700 accessibly reveal some of the redistribution circuit structure 1500 (e.g., the metallization layer ML₂′) accessibly revealed by the dielectric layer 1600. The dielectric layer 1700 may be referred to as a post-passivation layer. The dielectric layer 1600 may be or include a silicon oxide layer, a silicon nitride layer, a silicon oxy-nitride layer or a dielectric layer formed by other suitable dielectric materials, and may be formed by deposition, such as CVD (e.g., PECVD) or the like. The disclosure is not limited thereto. The dielectric layer 1700 may be or include a PI layer, a PBO layer, or a dielectric layer formed by other suitable polymers, and may be formed by spin-coating or deposition.

In alternative embodiments, the dielectric layer 1600 may be omitted. In addition to or alternatively, the dielectric layer 1700 may be omitted. The disclosure is not limited thereto.

In some embodiments, the conductive terminals 1800 each include an under-ball metallurgy (UBM) pattern 1800u and a conductive element 1800c disposed thereon and electrically coupled thereto. As shown in FIG. 19, the conductive elements 1800c of the conductive terminals 1800 are electrically coupled to the redistribution circuit structure 1500 (e.g., the metallization layer ML₂′ accessibly revealed by the dielectric layers 1600 and 1700) through the UBM patterns 1800u of the conductive terminals 1800, for example. In the cases, the conductive terminals 1800 penetrate through the dielectric layer 1600 and the dielectric layer 1700 so to be physically connected to and electrically connected to the redistribution circuit structure 1500. In alternative embodiment, the redistribution circuit structure 1500 can be omitted, where the conductive terminals 1800 are disposed over and (e.g., physically and electrically) connected to the through vias 1001 through the dielectric layer 1600 and the dielectric layer 1700.

Each of the UBM patterns 1800u, for example, includes a metal layer, which may include a single layer or a composite layer comprising a plurality of sub-layers formed of different materials. The material of the UBM patterns 1800u may include copper, nickel, titanium, molybdenum, tungsten, titanium nitride, titanium tungsten, or alloys thereof or the like, and may be formed by an electroplating process, for example. For example, the UBM patterns 1800u each includes titanium layer and a copper layer over the titanium layer. In some embodiments, the UBM patterns 1800u are formed using, for example, sputtering, PVD, or the like. The shape and number of the UBM patterns 1800u are not limited in the disclosure.

Each of the conductive elements 1800c, for example, includes micro-bumps, metal pillars, controlled collapse chip connection (C4) bumps (for example, which may have, but not limited to, a size of about 80 μm), a ball grid array (BGA) bumps (for example, which may have, but not limited to, a size of about 400 μm), electroless nickel-immersion gold technique (ENIG) formed bumps, electroless nickel-electroless palladium-immersion gold technique (ENEPIG) formed bumps, or the like. The disclosure is not limited thereto. The shape and number of the conductive elements 1800c are not limited in the disclosure.

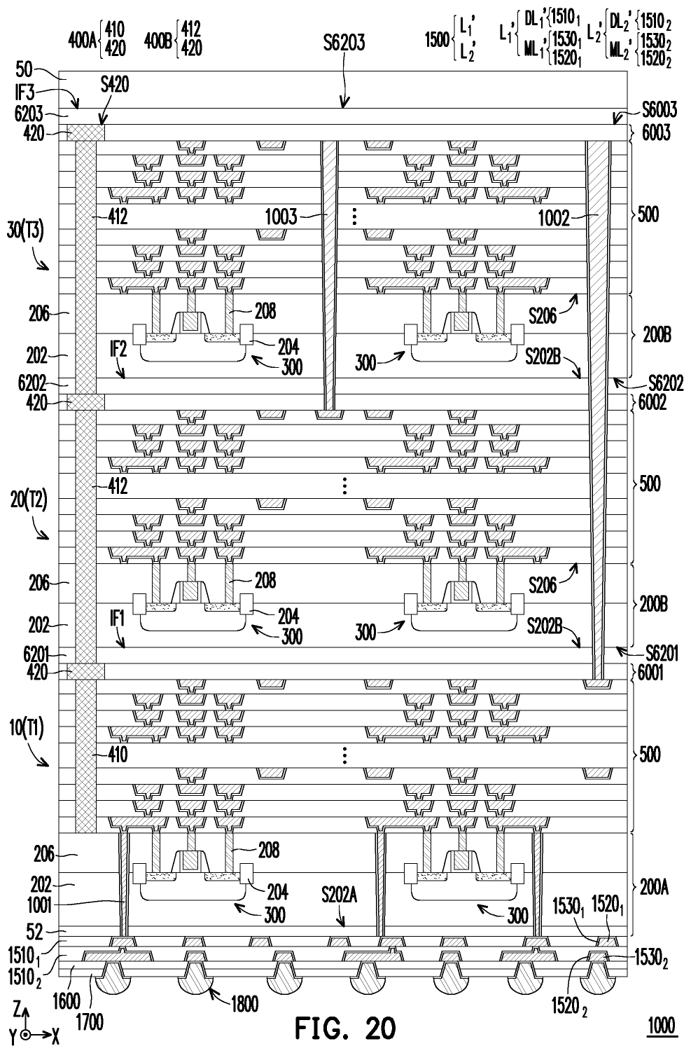

Referring to FIG. 20, in some embodiments, after forming the conductive terminals 1800, a dicing (singulation) process is performed to cut through the dielectric layer 1600, the dielectric layer 1700, the stacking structure (including the circuit wafers W1-W3) and the carrier 50 to form a plurality of stacking units 1000. In FIG. 20, only one stacking unit 1000 is shown for illustrative purposes and simplicity. The stacking units 1000 each may include the carrier 50, a semiconductor die 30 (e.g., a resultant from cutting through the circuit wafer W3) in the third tier T3 disposed over and thermally coupled to the carrier 50, a semiconductor die 20 (e.g., a resultant from cutting through the circuit wafer W2) in the second tier T2 disposed over and electrically coupled to the semiconductor die 30 in the third tier T3, a semiconductor die 10 (e.g., a resultant from cutting through the circuit wafer W1) in the first tier T1 disposed over and electrically coupled to the semiconductor die 20 in the second tier T2, the redistribution circuit structure 1500 disposed on and electrically coupled to the semiconductor die 10 in the first tier T1, the dielectric layer 1600 disposed on the redistribution circuit structure 1500, the dielectric layer 1700 disposed on the dielectric layer 1600, and the conductive terminals 1800 disposed over and electrically coupled to the redistribution circuit structure 1500 through the dielectric layers 1600 and 1700. For example, in the stacking unit 1000, a sidewall of the carrier 50, a sidewall of the semiconductor die 30, a sidewall of the semiconductor die 20, a sidewall of the semiconductor die 10, a sidewall of the redistribution circuit structure 1500, a sidewall of the dielectric layer 1600 and a sidewall of the dielectric layer 1700 are aligned to each other. That is, the sidewall of the carrier 50, the sidewall of the semiconductor die 30, the sidewall of the semiconductor die 20, the sidewall of the semiconductor die 10, the sidewall of the redistribution circuit structure 1500, the sidewall of the dielectric layer 1600 and the sidewall of the dielectric layer 1700 are together constitute a sidewall of the stacking unit 1000. In one embodiment, the dicing (singulation) process is a wafer dicing process including mechanical blade sawing or laser cutting. The disclosure is not limited thereto.

In some embodiments, some of the conductive terminals 1800 are electrically coupled to the semiconductor die 10 through the redistribution circuit structure 1500 and the through vias 1001, some of the conductive terminals 1800 are electrically coupled to the semiconductor die 20 through the redistribution circuit structure 1500, the through vias 1001 and the interconnect 500 of the semiconductor die 10 and the through vias 1002, and some of the conductive terminals 1800 are electrically coupled to the semiconductor die 30 through the redistribution circuit structure 1500, the through vias 1001 and the interconnect 500 of the semiconductor die 10 and the through vias 1002. The disclosure is not limited thereto. In alternative embodiments, some of the conductive terminals 1800 are electrically coupled to the semiconductor die 10 through the redistribution circuit structure 1500 and the through vias 1001, some of the conductive terminals 1800 are electrically coupled to the semiconductor die 30 through the redistribution circuit structure 1500, the through vias 1001 and the interconnect 500 of the semiconductor die 10 and the through vias 1002, and some of the conductive terminals 1800 are electrically coupled to the semiconductor die 20 through the redistribution circuit structure 1500, the through vias 1001 and the interconnect 500 of the semiconductor die 10, the through vias 1002, the interconnect 500 of the semiconductor die 30 and the through vias 1003.

Referring to FIG. 21, in some embodiments, a heat dissipating module is provided and coupled to the stacking unit 1000 to form the semiconductor device 10000A. In a non-limiting example, the heat dissipating module includes a lid 800 and a heat sink 900. As shown in FIG. 21, the lid 800 is disposed on (e.g., adhered to) the carrier 50 (e.g., at a surface S50 thereof) through a thermal adhesive 710 there-between, and the heat sink 900 is disposed on (e.g., adhered to) the lid 800 (e.g., at a surface S800 thereof) through a thermal adhesive 720 there-between, for example. That is, the lid 800 is thermally coupled to the stacking unit 1000 through the thermal adhesive 710, and the heat sink 900 is thermally coupled to the stacking unit 1000 through the thermal adhesive 720, the lid 800 and the thermal adhesive 710. Owing to the heat dissipating module (e.g., 800 and/or 900), the thermal dissipation of the semiconductor device 10000A is further improved. However, the disclosure is not limited thereto. In another non-limiting example, the heat dissipating module may include a lid 800 or a heat sink 900, only. In the embodiments of which the lid 800 is omitted, the heat sink 900 is thermally coupled to the stacking unit 1000 through the thermal adhesive 720 or 710. Or alternatively, the heat dissipating module can be omitted completely from the semiconductor device 10000A, if the thermal dissipation of the semiconductor device 10000A is well-controlled through the thermal control elements (e.g., 400A and 400B) embedded therein.

For example, the thermal adhesives 710, 720 are independently made of a thermally conductive material or any material which is capable of transferring heat. The thermal adhesives 710, 720 independently may be any suitable adhesive, glue, epoxy, underfill, die attach film (DAF), thermal interface material (TIM), or the like. For example, the lid 800 and the heat sink 900 are independently made of a material having high thermal conductivity between about 200 W/(m·K) to about 400 W/(m·K) or more. The lid 800 and the heat sink 900 independently may be formed from a material with high thermal conductivity, such as steel, stainless steel, copper, the like, combinations thereof, or any material having good thermal conductivity for heat spreading mechanism. In some embodiments, the lid 800 and the heat sink 900 are independently coated with another suitable material (such as a metal or metal alloy) for thermal dissipating. The lid 800 and the heat sink 900 independently may be a single contiguous material or may include multiple pieces having the same or different materials. The heat dissipating module in FIG. 21 is given for illustrative purposes, the lid 800 may be provided in any suitable form (e.g., a plate-form), while the heat sink 900 may be provided in any suitable form (a fin-form, a comb-form, etc.). The disclosure is not limited thereto.

In some embodiments, the semiconductor device 10000A include the thermal control elements (e.g., 400A and 400B) formed in the local interconnect (formed in MEOL) and the global interconnect (formed in BEOL) of the interconnect (e.g., 500) of each of the semiconductor dies (e.g., 10, 20, and/or 30), as shown in FIG. 21. However, the disclosure is not limited thereto. Alternatively, one or more thermal control elements (not shown) may be only formed in the global interconnect (formed in BEOL) of the interconnect (e.g., 500) included in each of the semiconductor dies (e.g., 10, 20, and/or 30), where the vertical portions of the thermal control elements only penetrate through the global interconnects (formed in BEOL) of the interconnects (e.g., 500).

In the disclosure, the thermal control portion 410 may be further referred to as a thermal via, see FIG. 32 through FIG. 37. In one non-limiting example, the thermal control portion 410 is a thermal via including a core portion 4010C (see FIG. 32), where the core portion 4010C is made of the thermal energy storage material 4010 as described in FIG. 4. The disclosure is not limited thereto. In another one non-limiting example, the thermal control portion 410 is a thermal via including a core portion 4010C and a shell portion 4030S laterally covering the core portion 4010C (see FIG. 33), where the shell portion 4030S is made of a thermal energy storage material other than the thermal energy storage material 4010 as described in FIG. 4. For example, the shell portion 4030S is made of a thermal energy storage material such as AlN, BN, diamond-like carbon, Al₂O₃, BeO, a combination thereof or the like, which may be formed by suitable fabrication techniques such as spin-on coating, CVD (e.g., PECVD). In some embodiments, the material of the shell portion 4030S may be a dielectric material (or layer) of a high thermal conductivity. In another one non-limiting example, the thermal control portion 410 is a thermal via including a core portion 4010C and a shell portion 4040S laterally covering the core portion 4010C (see FIG. 34), where the shell portion 4040S is made of a metal or metal alloy other than the thermal energy storage material 4010 as described in FIG. 4. For example, the shell portion 4040S is made of a metal or metal alloy such as copper or copper alloy, a combination thereof or the like, which may be formed by suitable fabrication techniques such plating or deposition. In some embodiments, the shell portion 4040S may be a conductive material (or layer) of a high thermal conductivity. In another one non-limiting example, the thermal control portion 410 is a thermal via including a core portion 4030C and a shell portion 4010S laterally covering the core portion 4030C (see FIG. 35), where the core portion 4030C is made of a thermal energy storage material other than the thermal energy storage material 4010 as described in FIG. 4, and the shell portion 4010S is made of the thermal energy storage material 4010 as described in FIG. 4. For example, the core portion 4030C is made of a thermal energy storage material such as AlN, BN, diamond-like carbon, Al₂O₃, BeO, a combination thereof or the like, which may be formed by suitable fabrication techniques such as spin-on coating, CVD (e.g., PECVD). In some embodiments, the material of the core portion 4030C may be a dielectric material (or layer) of a high thermal conductivity. In another one non-limiting example, the thermal control portion 410 is a thermal via including a core portion 4040C and a shell portion 4010S laterally covering the core portion 4030C (see FIG. 36), where the core portion 4040C is made of a metal or metal alloy other than the thermal energy storage material 4010 as described in FIG. 4. For example, the core portion 4040C is made of a metal or metal alloy such as copper or copper alloy, a combination thereof or the like, which may be formed by suitable fabrication techniques such plating or deposition. In some embodiments, the core portion 4040C may be a conductive material (or layer) of a high thermal conductivity. In one non-limiting example, the thermal control portion 410 is a thermal via including a core portion 4040C (see FIG. 37). Similarly, in the disclosure, the thermal control portion 412 may be further referred to as a thermal via, which adopted the configurations of FIG. 32 through FIG. 37. The disclosure is not limited thereto.

In the embodiments of which the thermal via including the core portion and shell portion, the thermal via may be formed by, but not limited to, conformally depositing a material of the shell portion into the opening (e.g., OP1 in FIG. 3) and over the interconnect 500 (e.g., the surface S500), forming a material of the core portion over the material of the shell portion and further filling the opening OP1, and performing a planarization process (e.g., similar to the process of FIG. 5) to remove the excess amount of the material of the core portion and/or the material of the shell portion from the surface S500 of the interconnect 500, such that the reminded materials for the core portion and the shell portion inside the opening OP1 forms the thermal via including the core portion and shell portion.

In some embodiments, the thermal control elements 400A and 400B of the semiconductor device 10000A are connected to each other and vertically aligned to each other (e.g., in the direction Z). However, the disclosure is not limited thereto. In some embodiments, a semiconductor device 10000B of FIG. 22 is similar to the semiconductor device 10000A of FIG. 21, and the difference is that, a thermal control elements 400A is adopted in each of the semiconductor dies 10, 20 and 30, where these thermal control elements 400A included in the semiconductor dies 10, 20 and 30 are not connected to each other. As shown in FIG. 22, for example, the thermal control elements 400A included in the semiconductor dies 10, 20 and 30 are not vertically aligned to each other. In other words, in a vertical projection (e.g., the XY plane) along the direction Z, the thermal control elements 400A included in the semiconductor dies 10, 20 and 30 are at least partially offset from each other. The details, formation and material of the thermal control elements 400A have been described in FIGS. 3-9 in conjunction with FIGS. 28-29, and thus are not repeated herein. Owing to the thermal conductive elements 400A, the heat generated from the hotspot (e.g., the transistors 300) of the semiconductor dies 10-30 inside the semiconductor device 10000B can be drawn towards and stored inside the thermal conductive elements 400A, which alleviate the heat spikes in the hotspot (e.g., the transistors 300) inside the semiconductor device 10000B, thereby improving the reliability of the semiconductor device 10000B.

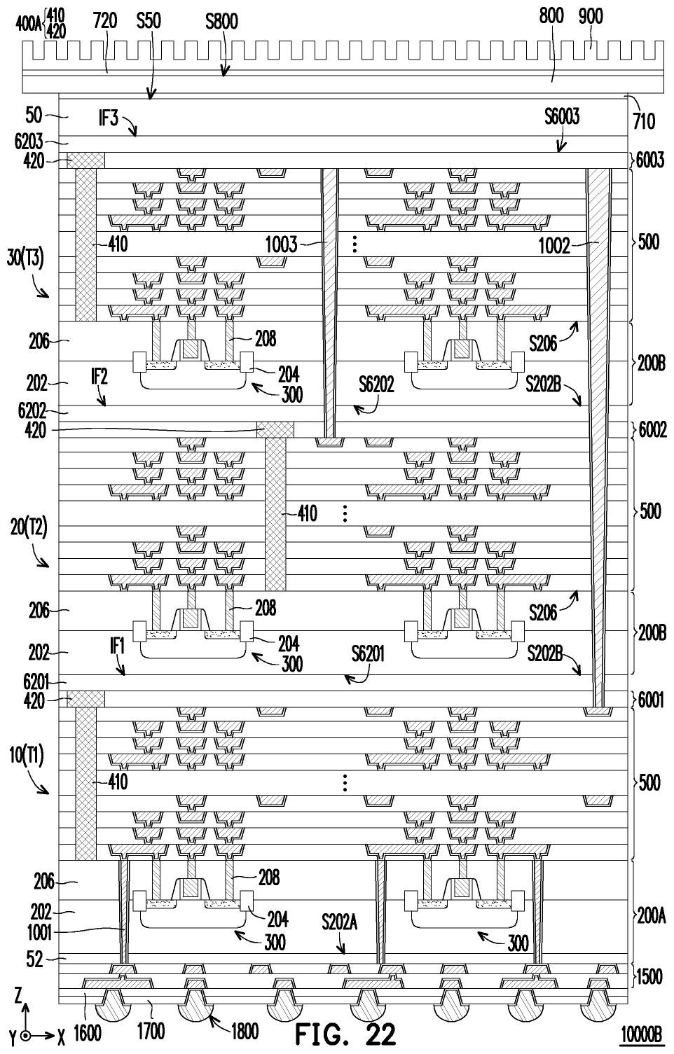

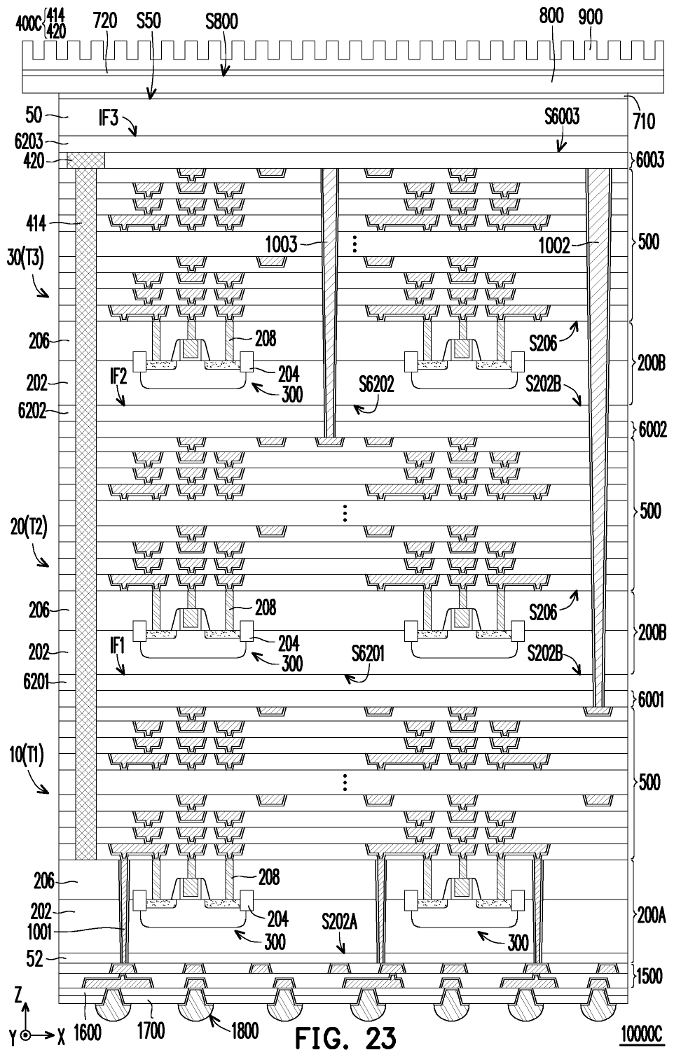

In some embodiments, the thermal control elements 400A and 400B being adopted in the semiconductor device 10000A are connected to each other and formed in separate process steps. However, the disclosure is not limited thereto. In some embodiments, a semiconductor device 10000C of FIG. 23 is similar to the semiconductor device 10000A of FIG. 21, and the difference is that, a thermal control element 400C is adopted in the semiconductor device 10000C to substitute the thermal control elements 400A and 400B connected thereto. As shown in FIG. 23, for example, the thermal control element 400C includes a thermal control portion 414 and a thermal control portion 420 physically connected to and thermally coupled to the thermal control portion 414, where the thermal control portion 414 completely penetrates through the semiconductor die 30, the semiconductor die 20 and the interconnect 500 of the semiconductor die 10, and the thermal control portion 420 completely penetrates through the dielectric layer 6003. For example, the thermal control portion 414 is in form of a pillar or a column shape and next to the hotspot (such as the transistors 300). The thermal control portion 414 may be referred to as a vertical portion of the thermal conductive element 400C, and the thermal control portion 420 may be referred to as a horizontal portion of the thermal conductive element 400C. The thermal control portion 414 is formed in an integral piece, and is next to the hotspot(s) (such as the transistors 300 of the semiconductor dies 10-30), in some embodiments. The formation and material of the thermal control portion 414 are similar to or substantially identical to the formation and material of the thermal control portions 410 as previously discussed in conjunction with FIGS. 3-5 in conjunction with FIG. 28, and the formation and material of the thermal control portion 420 have been described in FIGS. 7-9 in conjunction with FIG. 29; and thus, are not repeated herein for brevity. In some embodiments, for each thermal conductive element 400C, the thermal control portion 414 and the thermal control portion 420 are arranged in a one-to-one configuration.

In the disclosure, the thermal control portion 414 may be further referred to as a thermal via, which adopted the configurations of FIG. 32 through FIG. 37. The disclosure is not limited thereto.

In some embodiments, the thermal conductive element 400C is referred to as a thermal capacitor, a thermal storage capacitor, a thermal control component, a thermal control module, a thermal management element, a thermal management component, or a thermal management module. Only one thermal control element 400C is shown in FIG. 23 for illustrative purposes, however the disclosure is not limited thereto. The number of the thermal control element 400C (including 414 and 420) can be one, two or more (e.g., as shown in FIG. 28 and FIG. 29), which may be selected and/or designated depending on the demand and/or product design requirements/layout. For example, the number of the thermal control element 400C may be controlled by adjusting the number of the thermal control portion 414 and the respective thermal control portion 420. Owing to the thermal conductive element(s) 400C, the heat generated from the hotspot (e.g., the transistors 300) of the semiconductor dies 10-30 inside the semiconductor device 10000C can be drawn towards and stored inside the thermal conductive element(s) 400C, which alleviate the heat spikes in the hotspot (e.g., the transistors 300) inside the semiconductor device 10000C, thereby improving the reliability of the semiconductor device 10000C. For example, the thermal conductive element(s) 400C are electrically isolated from the interconnects 500 and the components (e.g., the transistors 300) of the semiconductor dies 10-30 and thermally coupled to the interconnect 500 and the components (e.g., the transistors 300) of the semiconductor dies 10-30.

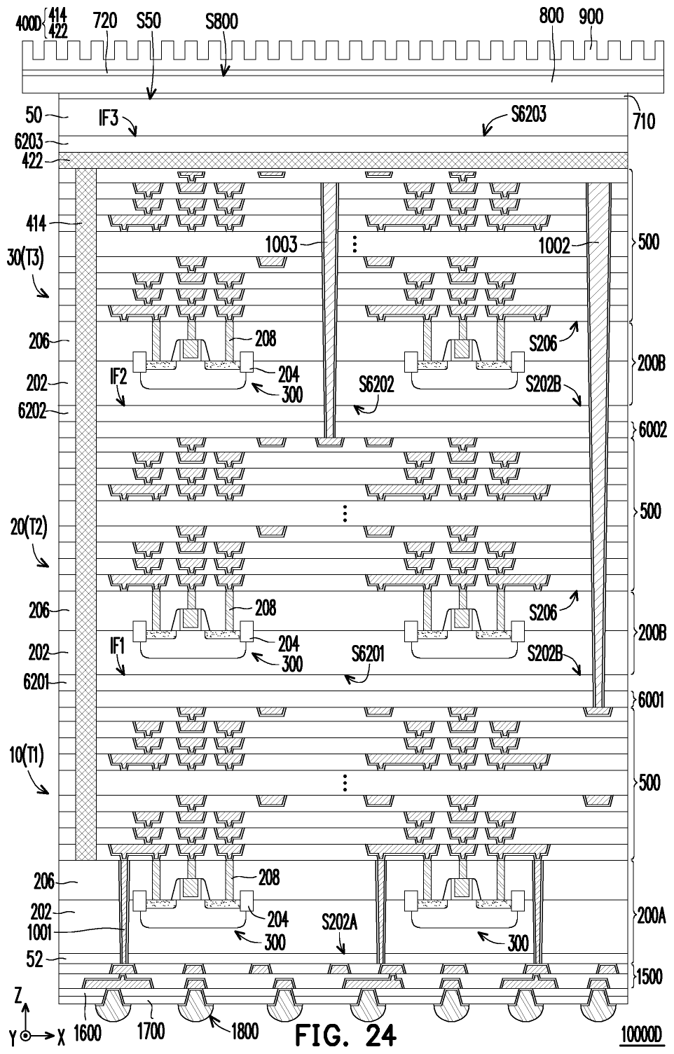

In some embodiments, in the semiconductor device 10000C, the thermal control portion 420 of the thermal control element 400C is penetrated through and laterally covered by the dielectric layer 6003, as shown in FIG. 23. However, the disclosure is not limited thereto. In some embodiments, a semiconductor device 10000D of FIG. 24 is similar to the semiconductor device 10000C of FIG. 23, and the difference is that, a thermal control element 400D is adopted in the semiconductor device 10000D to substitute the thermal control element 400C. As shown in FIG. 24, for example, the thermal control element 400D includes a thermal control portion 414 and a thermal control portion 422 physically connected to and thermally coupled to the thermal control portion 414, where the thermal control portion 414 completely penetrates through the semiconductor die 30, the semiconductor die 20 and the interconnect 500 of the semiconductor die 10, and the thermal control portion 422 is configured to completely replace the dielectric layer 6003. In such case, the bonding layer 6203 is disposed on and connected to the thermal control portion 422 of the thermal control element 400D, and the dielectric layer 6003 is excluded from the semiconductor device 10000D. The thermal control portion 414 may be referred to as a vertical portion of the thermal conductive element 400D, and the thermal control portion 422 may be referred to as a horizontal portion of the thermal conductive element 400D. The thermal control portion 414 is formed in an integral piece, and is next to the hotspot(s) (such as the transistors 300 of the semiconductor dies 10-30), in some embodiments. For example, the thermal control portion 414 is in form of a pillar or a column shape and next to the hotspot (such as the transistors 300). The thermal control portion 422 is formed in a continuous plate form overlapped with the hotspot(s) (such as the transistors 300 of the semiconductor dies 10-30) right after the formation of the thermal control portion 414 and following by the formation of the bonding layer 6203, in some embodiments (see FIG. 30). The formation and material of the thermal control portion 414 are similar to or substantially identical to the formation and material of the thermal control portion 410 as previously discussed in conjunction with FIGS. 3-5 in conjunction with FIG. 28, and the formation and material of the thermal control portion 422 are similar to or substantially identical to the formation and material of the thermal control portion 420 as described in FIGS. 7-9; and thus, are not repeated herein for brevity. Only one thermal control portion 414 being connected to the thermal control portion 422 in the thermal control element 400D is shown in FIG. 24 for illustrative purposes, however the disclosure is not limited thereto. The number of the thermal control portion 414 being connected to the thermal control portion 422 in the thermal control element 400D (including 414 and 422) can be one, two or more, which may be selected and/or designated depending on the demand and/or product design requirements/layout. In some embodiments, for each thermal conductive element 400D, the thermal control portion 414 and the thermal control portion 422 are arranged in a one-to-one configuration. In alternative embodiments, for each thermal conductive element 400D, the thermal control portion 414 and the thermal control portion 422 are arranged in a plurality-to-one configuration.

For example, the thermal conductive element 400D is electrically isolated from the interconnects 500 and the components (e.g., the transistors 300) of the semiconductor dies 10-30 and thermally coupled to the interconnect 500 and the components (e.g., the transistors 300) of the semiconductor dies 10-30. In some embodiments, the thermal conductive element 400D is referred to as a thermal capacitor, a thermal storage capacitor, a thermal control component, a thermal control module, a thermal management element, a thermal management component, or a thermal management module. Owing to the thermal conductive element 400D, the heat generated from the hotspot (e.g., the transistors 300) of the semiconductor dies 10-30 inside the semiconductor device 10000D can be drawn towards and stored inside the thermal conductive element 400D, which alleviate the heat spikes in the hotspot (e.g., the transistors 300) inside the semiconductor device 10000D, thereby improving the reliability of the semiconductor device 10000D.

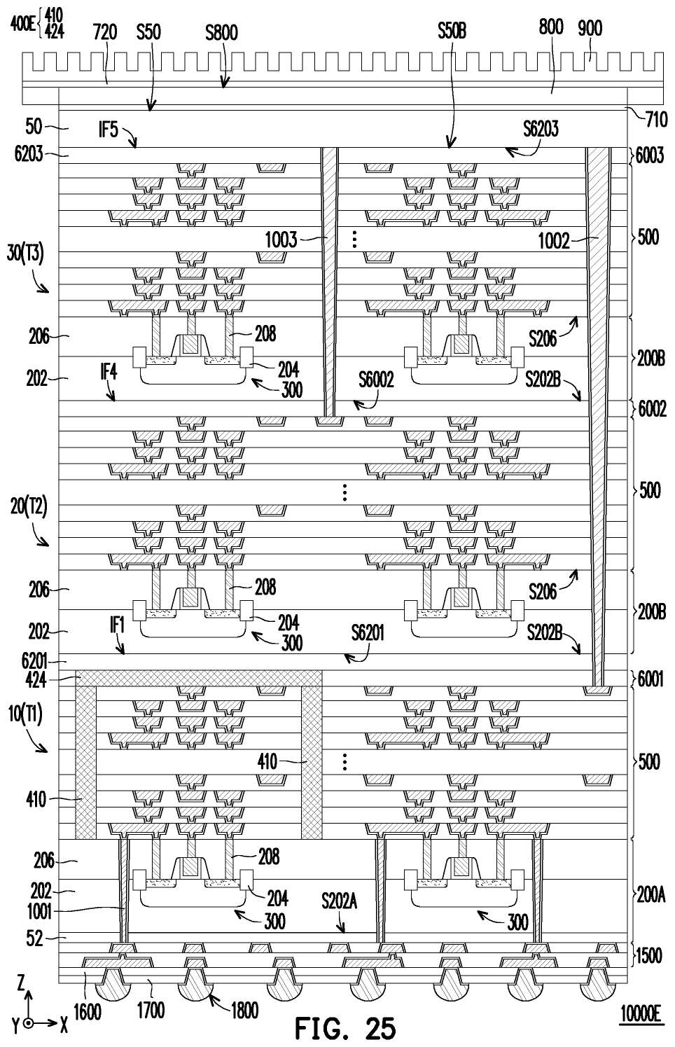

In some embodiments, the thermal control elements 400A and 400B being adopted in the semiconductor device 10000A independently have a T-shape, in the cross-section of the semiconductor device 10000A as shown in FIG. 21. However, the disclosure is not limited thereto. In some embodiments, a semiconductor device 10000E of FIG. 25 is similar to the semiconductor device 10000A of FIG. 21, and the difference is that, a thermal control element 400E is adopted in the semiconductor device 10000E, instead of the thermal control elements 400A and 400B. In some embodiments, the thermal control element 400E included in the semiconductor device 10000E has a U-shape (upside down), in the cross-section of the semiconductor device 10000E as shown in FIG. 25.

For example, the thermal control element 400E includes a plurality of thermal control portions 410 and a thermal control portion 424 thermally coupled to the plurality of thermal control portions 410, where the thermal control portions 410 each completely penetrate the interconnect 500 of the semiconductor die 10 and are arranged to surround the hotspot (e.g., 3000) of the semiconductor die 10, and the thermal control portion 424 completely penetrates the dielectric layer 6001 and physically connected to the thermal control portions 410. In such case, the thermal control portion 424 disposed on the interconnect 500 and the thermal control portions 410 and is laterally covered by the dielectric layer 6001, and the bonding layer 6201 is disposed on and connected to the thermal control portion 424 of the thermal control element 400E and the dielectric layer 6001. The thermal control portions 410 may be referred to as vertical portions of the thermal conductive element 400E, and the thermal control portion 424 may be referred to as a horizontal portion of the thermal conductive element 400E. The thermal control portions 410 are formed in a pillar form or a column form and are next to (e.g., surrounding) the hotspot(s) (such as the transistors 300 of the semiconductor die 10), in some embodiments. The thermal control portion 424 is formed in a segment, slab or plate form overlapped with the hotspot(s) (such as the transistors 300 of the semiconductor die 10) so to thermally connect the thermal control portions 410 next to (e.g., surrounding) a respective one of the hotspot(s). The formation and material of the thermal control portions 410 have been described in FIGS. 3-5 in conjunction with FIG. 28, the formation and material of the thermal control portion 424 are similar to or substantially identical to the formation and material of the thermal control portion 420 as described in FIGS. 7-9 in conjunction with FIG. 31; and thus, are not repeated herein for brevity.

Only two thermal control portions 410 being connected to the thermal control portion 424 in the thermal control element 400E is shown in FIG. 25 for illustrative purposes, however the disclosure is not limited thereto. The number of the thermal control portions 410 being connected to the thermal control portion 424 in the thermal control element 400E (including 410 and 424) can be two, three, four or more, which may be selected and/or designated depending on the demand and/or product design requirements/layout. In some embodiments, for each thermal conductive element 400E, the thermal control portions 410 and the thermal control portion 424 are arranged in a plurality-to-one configuration.

In some embodiments, the thermal conductive element 400E is referred to as a thermal capacitor, a thermal storage capacitor, a thermal control component, a thermal control module, a thermal management element, a thermal management component, or a thermal management module. Only one thermal control element 400E included in the first tier T1 is shown in FIG. 25, however the number of the thermal control element 400E may be one, two, or more and/or may be formed in at least one of the first tier T1, the second tier T2 and the third tier T3, depending on the demand and/or product design requirements/layout. The disclosure is not limited thereto. Owing to the thermal conductive element(s) 400E, the heat generated from the hotspot (e.g., the transistors 300) of the semiconductor dies 10-30 inside the semiconductor device 10000E can be drawn towards and stored inside the thermal conductive element(s) 400E, which alleviate the heat spikes in the hotspot (e.g., the transistors 300) inside the semiconductor device 10000E, thereby improving the reliability of the semiconductor device 10000E. For example, the thermal conductive element(s) 400E are electrically isolated from the interconnects 500 and the components (e.g., the transistors 300) of the semiconductor dies 10-30 and thermally coupled to the interconnect 500 and the components (e.g., the transistors 300) of the semiconductor dies 10-30.

In addition, due to no thermal control element is presented in the dielectric layer 6002 of the second tier T2 and the dielectric layer 6003 of the third tier T3 included in the semiconductor device 10000E, the bonding layer 6202 disposed on the dielectric layer 6002 and the bonding layer 6203 disposed on the dielectric layer 6003 are omitted, as the uniformity at the bonding surfaces is maintained, in some embodiments. As shown in FIG. 25, a bonding interface IF4 including a dielectric-to-dielectric bonding interface (such as a ‘oxide’-to-‘silicon’ bonding interface or a ‘nitride’-to-‘silicon’ bonding interface) may exist between the third tier T3 (e.g., the substrate 200B of the semiconductor die 30) and the second tier T2 (e.g., the dielectric layer 6002), and which may be considered as a bonding interface of the third tier T3 and the second tier T2. In certain embodiments, if there is a native oxide on the substrate 202 (e.g., a rear surface S202B) of the semiconductor die 30, the bonding interface IF4 including a dielectric-to-dielectric bonding interface further includes a ‘oxide’-to-‘oxide’ bonding interface or a ‘nitride’-to-‘oxide’ bonding interface, for example. In the case, a bonding interface IF5 including a dielectric-to-dielectric bonding interface (such as a ‘oxide’-to-‘silicon’ bonding interface or a ‘nitride’-to-‘silicon’ bonding interface) exists between the carrier 50 and the third tier T3 (e.g., the dielectric layer 6003), and which is considered as a bonding interface of the carrier 50 and the third tier T3. In certain embodiments, if there is a native oxide on the carrier 50, the bonding interface IF5 including a dielectric-to-dielectric bonding interface further includes a ‘oxide’-to-‘oxide’ bonding interface or a ‘nitride’-to-‘oxide’ bonding interface.

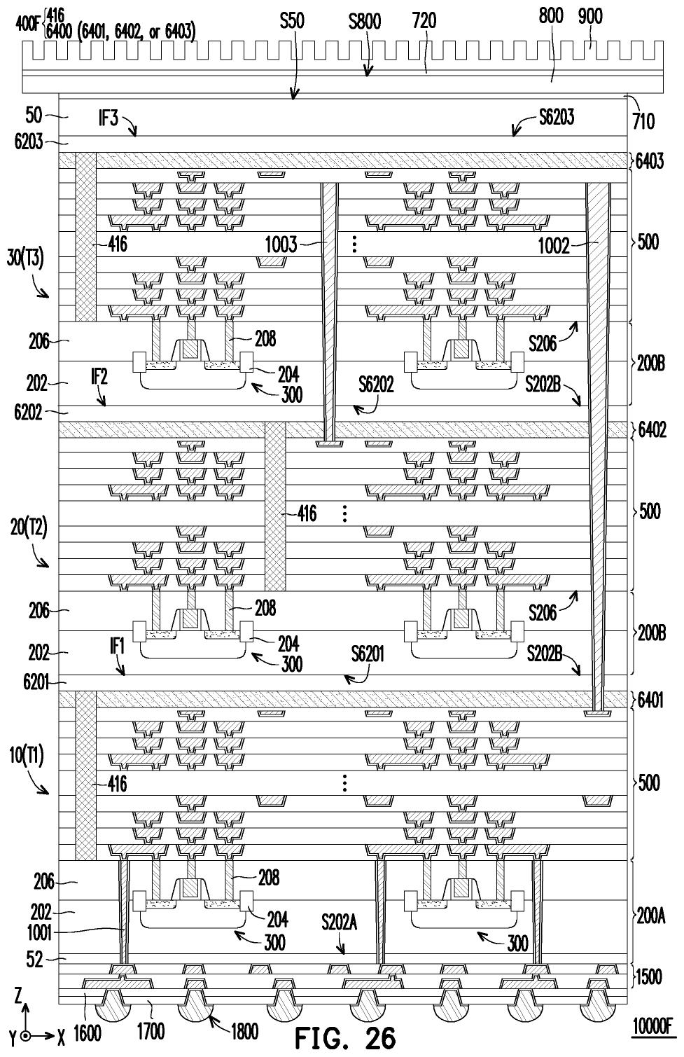

In some embodiments of the disclosure, a thermal control element 400F is adopted in a semiconductor device 10000F, as shown in FIG. 26. For example, the semiconductor device 10000F of FIG. 26 is similar to the semiconductor device 10000A of FIG. 21, and the difference is that, at least one thermal control element 400F is adopted in the semiconductor device 10000F, instead of the thermal control elements 400A and 400B. In some embodiments, each thermal control element 400F included in the semiconductor device 10000F includes a thermal control portion 416 (each referred to as a vertical portion of a respective thermal control element 400F) and a high thermal conductive layer 6400 (e.g., 6401, 6402 or 6403) (each referred to as a horizontal portion of the respective thermal control element 400F). As shown in FIG. 26, the dielectric layer 6001 is replaced with the high thermal conductive layer 6401, the dielectric layer 6002 is replaced with the high thermal conductive layer 6402, and the dielectric layer 6003 is replaced with the high thermal conductive layer 6403, where one thermal control portion 416 completely penetrates through the high thermal conductive layer 6401 and the interconnect 500 of the first tier T1 to form the thermal control element 400F (including 416 and 6401) in the first tier T1, one thermal control portion 416 completely penetrates through the high thermal conductive layer 6402 and the interconnect 500 of the second tier T2 to form the thermal control element 400F (including 416 and 6402) in the second tier T2, and one thermal control portion 416 completely penetrates through the high thermal conductive layer 6403 and the interconnect 500 of the third tier T3 to form the thermal control element 400F (including 416 and 6403) in the third tier T3, for example. In the disclosure, the thermal control portion 414 may be further referred to as a thermal via, which adopted the configurations of FIG. 32 through FIG. 36. The disclosure is not limited thereto.

In some embodiments, for each thermal conductive element 400F (e.g., including 416 and 6301; 416 and 6302; 416 and 6303), the thermal control portion 416 and the high thermal conductive layer 6400 (e.g., 6401, 6402 or 6403) are arranged in a one-to-one configuration. However, the disclosure is not limited thereto; alternatively, in each thermal conductive element 400F (e.g., including 416 and 6301; 416 and 6302; 416 and 6303), the thermal control portion 416 and the high thermal conductive layer 6400 (e.g., 6401, 6402 or 6403) are arranged in a plurality-to-one configuration.

The material of the high thermal conductive layer 6400 (e.g., 6401, 6402 and/or 6403) may be SiO₂, AlN, BN, diamond-like carbon, Al₂O₃, BeO, a combination thereof or the like, which may be formed by suitable fabrication techniques such as spin-on coating, CVD (e.g., PECVD), or the like and may be patterned using a photolithography and/or etching process. The etching process may include a dry etching, a wet etching, or a combination thereof. After the etching process, a cleaning step may be optionally performed, for example, to clean and remove the residue generated from the etching process. The formation and material of the thermal control portions 416 are similar to or substantially identical to the formation and formation of the thermal control portion 410 have been described in FIGS. 3-5 in conjunction with 28, and thus are not repeated herein.

In some embodiment, the high thermal conductive layer 6401 is formed right after the formation of the interconnect 500 of the first tier T1 and following by the formation of the thermal control portion 416, where the thermal control portion 416 penetrates through the high thermal conductive layer 6401 and the interconnect 500 of the first tier T1 so to thermally coupled to (e.g., in physical contact with) the high thermal conductive layer 6401, thereby forming the thermal conductive element 400F in the first tier T1. In some embodiment, the high thermal conductive layer 6402 is formed right after the formation of the interconnect 500 of the second tier T2 and following by the formation of the thermal control portion 416, where the thermal control portion 416 penetrates through the high thermal conductive layer 6402 and the interconnect 500 of the second tier T2 so to thermally coupled to (e.g., in physical contact with) the high thermal conductive layer 6402, thereby forming the thermal conductive element 400F in the second tier T2. In some embodiment, the high thermal conductive layer 6403 is formed right after the formation of the interconnect 500 of the third tier T3 and following by the formation of the thermal control portion 416, where the thermal control portion 416 penetrates through the high thermal conductive layer 6403 and the interconnect 500 of the third tier T3 so to thermally coupled to (e.g., in physical contact with) the high thermal conductive layer 6403, thereby forming the thermal conductive element 400F in the third tier T3.

In some embodiments, the thermal conductive elements 400F are each referred to as a thermal capacitor, a thermal storage capacitor, a thermal control component, a thermal control module, a thermal management element, a thermal management component, or a thermal management module. Owing to the thermal conductive element(s) 400F, the heat generated from the hotspot (e.g., the transistors 300) of the semiconductor dies 10-30 inside the semiconductor device 10000F can be drawn towards and stored inside the thermal conductive element(s) 400F, which alleviate the heat spikes in the hotspot (e.g., the transistors 300) inside the semiconductor device 10000F, thereby improving the reliability of the semiconductor device 10000E. For example, the thermal conductive element(s) 400F are electrically isolated from the interconnects 500 and the components (e.g., the transistors 300) of the semiconductor dies 10-30 and thermally coupled to the interconnect 500 and the components (e.g., the transistors 300) of the semiconductor dies 10-30.

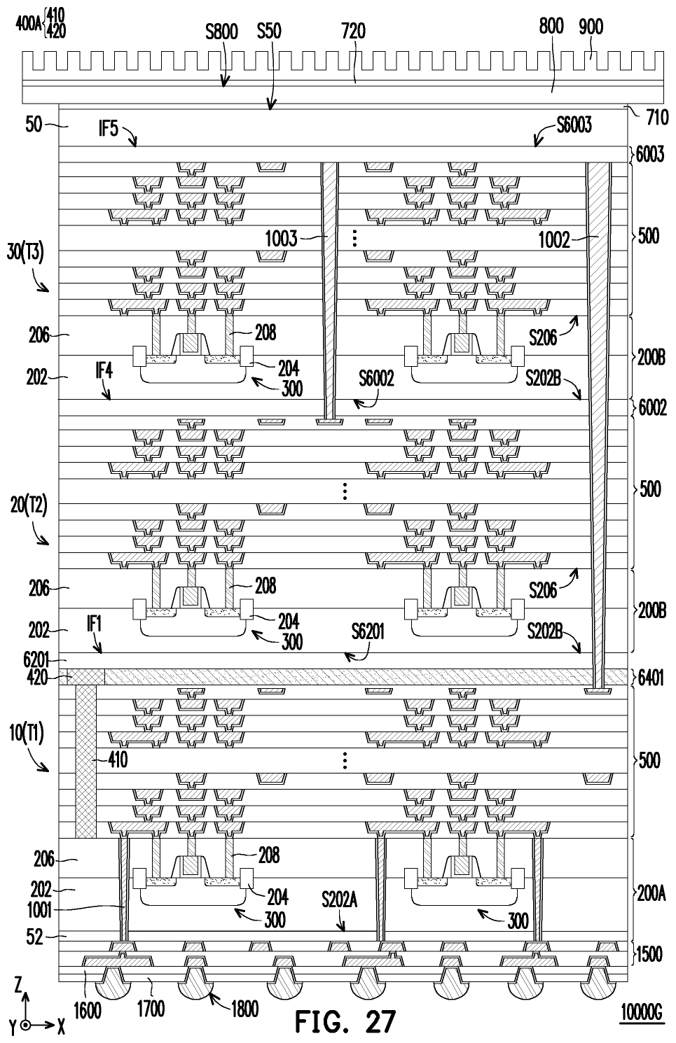

In some embodiments, the semiconductor device 10000G of FIG. 27 is similar to the semiconductor device 10000A of FIG. 21, and the difference is that, only thermal control element 400A is included in the first tier T1 of the semiconductor device 10000G, and the dielectric layer 6001 is substituted by a high thermal conductive layer (e.g., 6401). The details, formation and material of the thermal control element 400A have been described in FIG. 3-9, and the details, formation and material of the high thermal conductive layer 6401 have been described in FIG. 25; and thus, are not repeated herein for brevity. As shown in FIG. 27, the thermal control element 400A is further thermally coupled to the high thermal conductive layer 6401. Only one thermal control element 400A included in the first tier T1 is shown in FIG. 27, however the number of the thermal control element 400A may be one, two, or more and/or may be formed in at least one of the first tier T1, the second tier T2 (with the high thermal conductive layer 6402 replacing the dielectric layer 6002) and the third tier T3 (with the high thermal conductive layer 6403 replacing the dielectric layer 6003), depending on the demand and/or product design requirements/layout. The disclosure is not limited thereto. Owing to the thermal conductive element(s) 400A in addition to the high thermal conductive layer 6401 thermally coupled thereto, the heat generated from the hotspot (e.g., the transistors 300) of the semiconductor dies 10-30 inside the semiconductor device 10000G can be further drawn towards and stored inside the thermal conductive element(s) 400A and the high thermal conductive layer 6401 thermally coupled thereto, which alleviate the heat spikes in the hotspot (e.g., the transistors 300) inside the semiconductor device 10000G, thereby improving the reliability of the semiconductor device 10000G. For example, the thermal conductive element(s) 400A and the high thermal conductive layer 6401 thermally coupled to thereto are electrically isolated from the interconnects 500 and the components (e.g., the transistors 300) of the semiconductor dies 10-30 and thermally coupled to the interconnect 500 and the components (e.g., the transistors 300) of the semiconductor dies 10-30.

In addition, due to no thermal control element is presented in the dielectric layer 6002 of the second tier T2 and the dielectric layer 6003 of the third tier T3 included in the semiconductor device 10000G, the bonding layer 6202 disposed on the dielectric layer 6002 and the bonding layer 6203 disposed on the dielectric layer 6003 are omitted, as the uniformity at the bonding surfaces is maintained, in some embodiments. As shown in FIG. 27, a bonding interface IF4 including a dielectric-to-dielectric bonding interface (such as a ‘oxide’-to-‘silicon’ bonding interface or a ‘nitride’-to-‘silicon’ bonding interface) may exist between the third tier T3 (e.g., the substrate 200B of the semiconductor die 30) and the second tier T2 (e.g., the dielectric layer 6002), and which may be considered as a bonding interface of the third tier T3 and the second tier T2. In certain embodiments, if there is a native oxide on the substrate 202 (e.g., a rear surface S202B) of the semiconductor die 30, the bonding interface IF4 including a dielectric-to-dielectric bonding interface further includes a ‘oxide’-to-‘oxide’ bonding interface or a ‘nitride’-to-‘oxide’ bonding interface, for example. In the case, a bonding interface IF5 including a dielectric-to-dielectric bonding interface (such as a ‘oxide’-to-‘silicon’ bonding interface or a ‘nitride’-to-‘silicon’ bonding interface) exists between the carrier 50 and the third tier T3 (e.g., the dielectric layer 6003), and which is considered as a bonding interface of the carrier 50 and the third tier T3. In certain embodiments, if there is a native oxide on the carrier 50, the bonding interface IF5 including a dielectric-to-dielectric bonding interface further includes a ‘oxide’-to-‘oxide’ bonding interface or a ‘nitride’-to-‘oxide’ bonding interface.

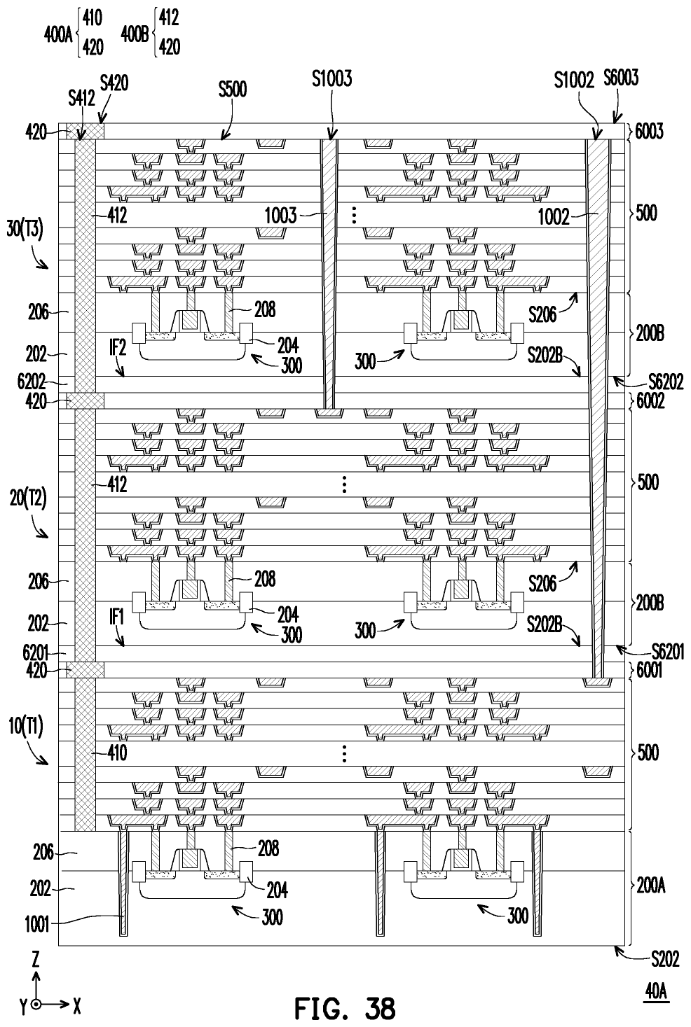

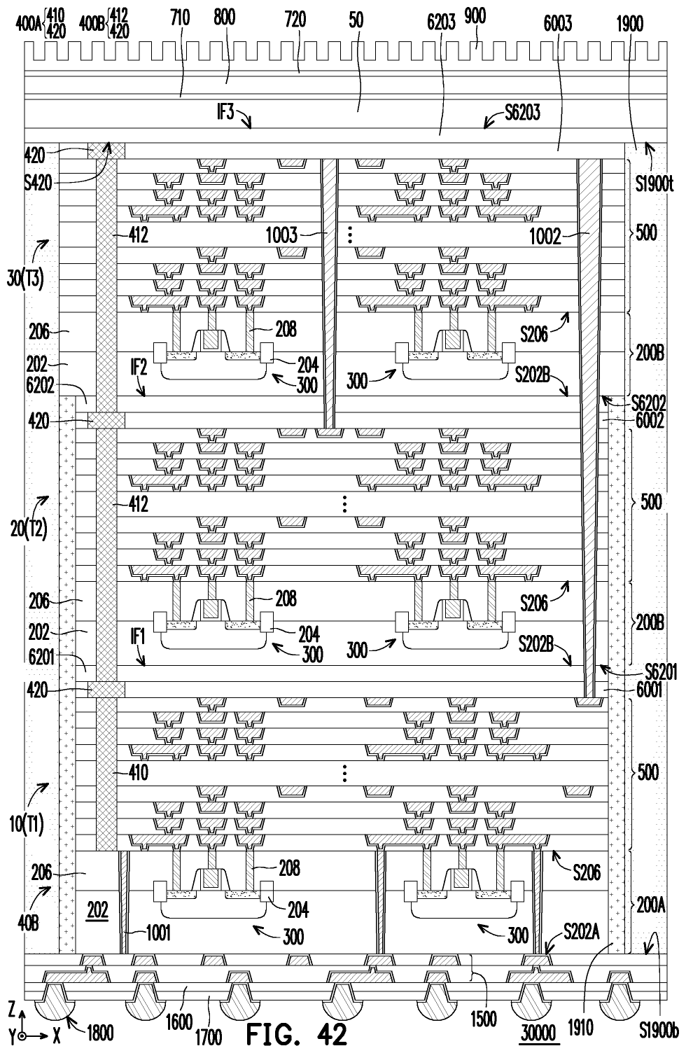

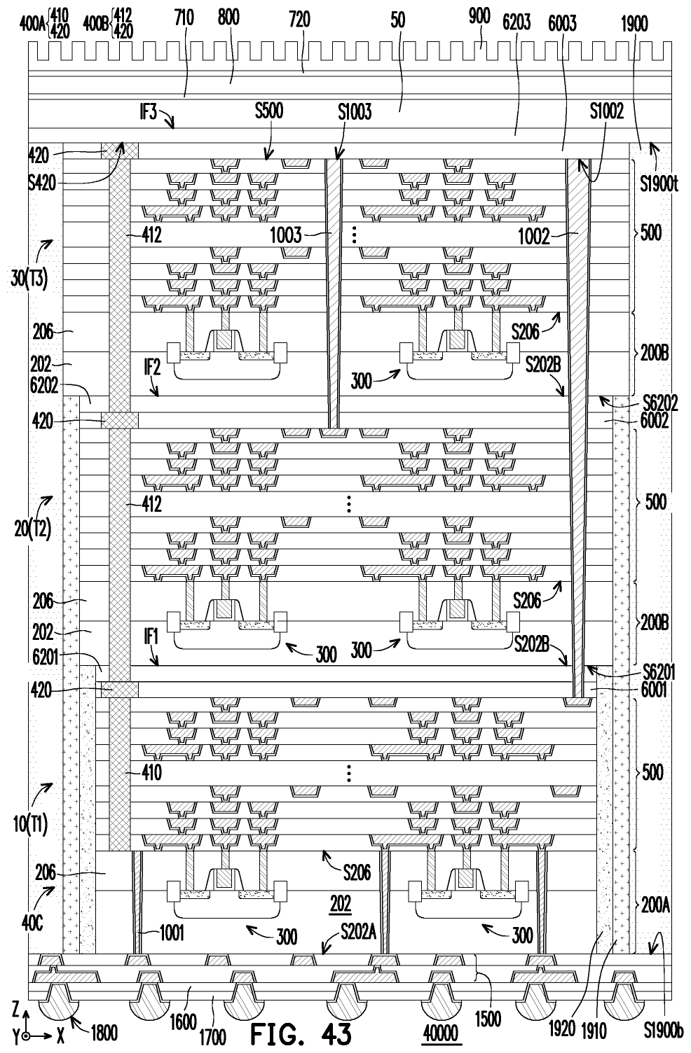

FIG. 38 to FIG. 41 are schematic cross-sectional views of various stages in a manufacturing method of a semiconductor device (e.g., 20000) in accordance with some embodiments of the disclosure. FIG. 42 through FIG. 43 are schematic cross-sectional views respectively showing a semiconductor device (e.g., 30000 or 40000) in accordance with alternative embodiments of the disclosure. The elements similar to or substantially the same as the elements described previously will use the same reference numbers, and certain details or descriptions (e.g., the materials, formation processes, positioning configurations, electrical connections, etc.) of the same elements would not be repeated herein.

Referring to FIG. 38, in some embodiments, a dielectric layer 6003 and a thermal control element 420 are sequentially formed over the illustrated top surface S500 of the interconnect 500 included in the third tier T3 of the structure depicted in FIG. 15, and a dicing (singulation) process is performed so to form a plurality of stacking units 40A. The details, formation and material of each of the dielectric layer 6003 and the thermal control element 420 have been described in FIG. 16, and thus are not repeated herein. In FIG. 38, only one stacking unit 40A is shown for illustrative purposes and simplicity. The stacking units 40A each may include a semiconductor die 30 (e.g., a resultant from cutting through the circuit wafer W3) in the third tier T3, a semiconductor die 20 (e.g., a resultant from cutting through the circuit wafer W2) in the second tier T2 disposed over and electrically coupled to the semiconductor die 30 in the third tier T3, and a semiconductor die 10 (e.g., a resultant from cutting through the circuit wafer W1) in the first tier T1 disposed over and electrically coupled to the semiconductor die 20 in the second tier T2. For example, in the stacking unit 40A, a sidewall of the semiconductor die 30, a sidewall of the semiconductor die 20, and a sidewall of the semiconductor die 10 are aligned to each other. That is, the sidewall of the semiconductor die 30, the sidewall of the semiconductor die 20, and the sidewall of the semiconductor die 10 are together constitute a sidewall of the stacking unit 40A. In one embodiment, the dicing (singulation) process is a wafer dicing process including mechanical blade sawing or laser cutting. The disclosure is not limited thereto.

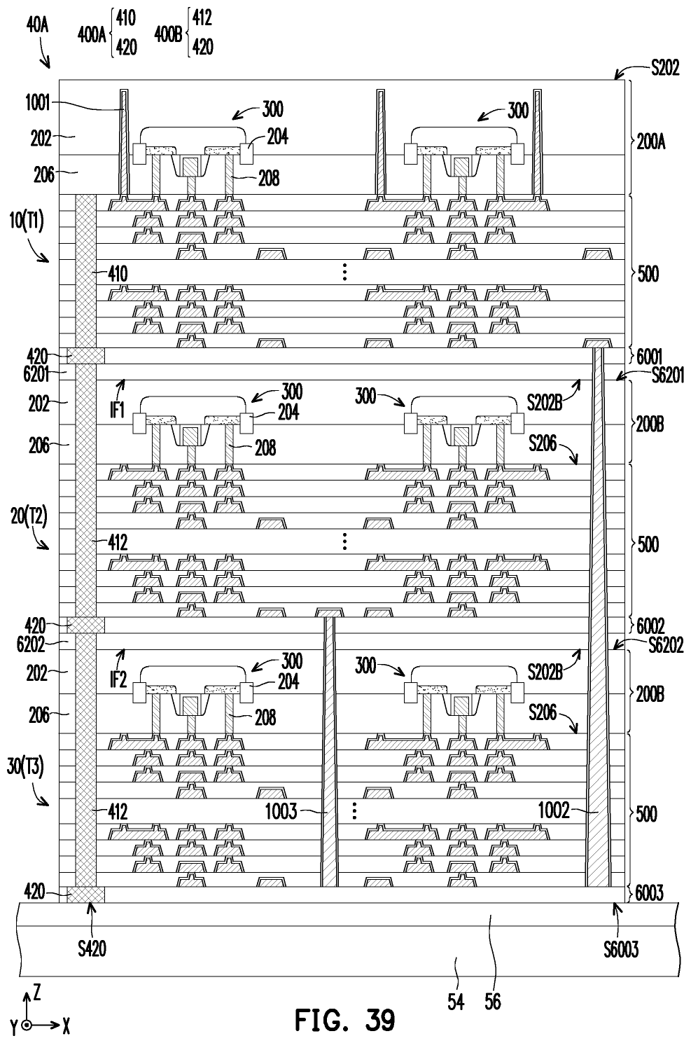

Referring to FIG. 39, in some embodiments, in some embodiments, a carrier substrate 54 is provided, and a release layer 56 is formed on the carrier substrate 54. The carrier substrate 54 may be a glass carrier substrate, a ceramic carrier substrate, or the like. The carrier substrate 54 may be a wafer, such that multiple packages can be formed on the carrier substrate 54 simultaneously. The release layer 56 may be formed of a polymer-based material, which may be removed along with the carrier substrate 54 from the overlying structures that will be formed in subsequent steps. In some embodiments, the release layer 56 is an epoxy-based thermal-release material, which loses its adhesive property when heated, such as a light-to-heat-conversion (LTHC) release coating. In other embodiments, the release layer 56 may be an ultra-violet (UV) glue, which loses its adhesive property when exposed to UV lights. The release layer 56 may be dispensed as a liquid and cured, may be a laminate film laminated onto the carrier substrate 54, or may be the like. The top surface of the release layer 56 may be leveled.

In some embodiments, at least one stacking unit 40A is picked and placed on the release layer 56 and over the carrier substrate 54. As shown in FIG. 39, only one stacking unit 40A is presented as the at least one stacking unit 40A for illustrative purposes, however, it should be noted that the number of the at least one stacking unit 40A may be one, two, three, or more than three, the disclosure is not limited thereto. For example, the illustrated top surface S500 of the interconnect 500 included in the third tier T3 is placed on (e.g., in physical contact with) the release layer 56. As shown in FIG. 39, the rear surface S202 of the semiconductor substrate 202 included in the first tier T1 may face upwards.

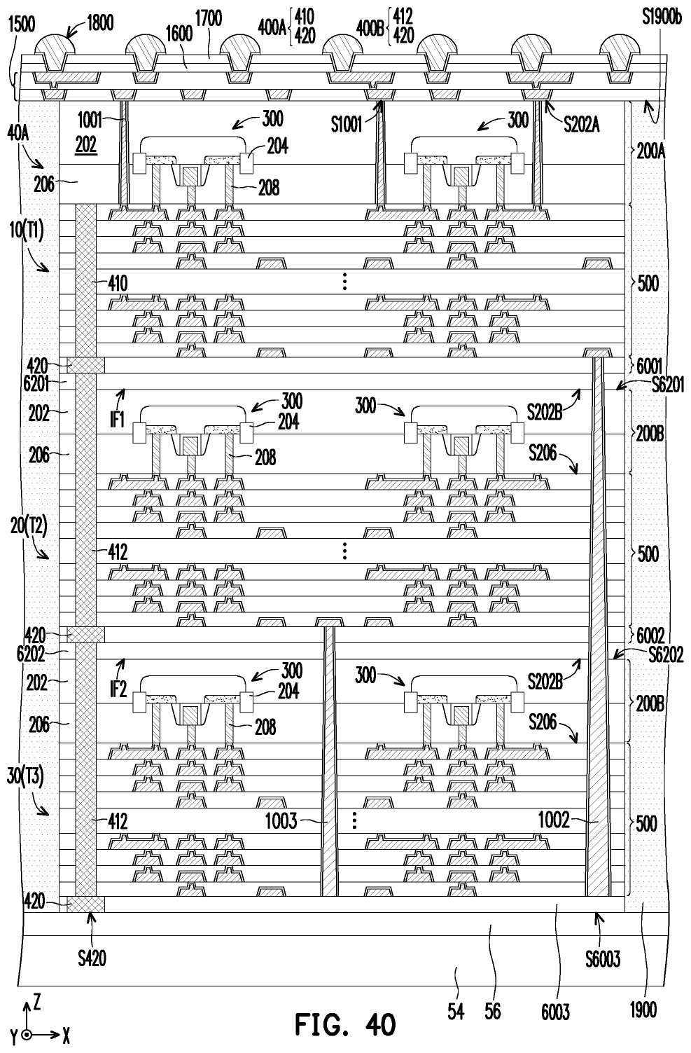

Referring to FIG. 40, in some embodiments, the stacking unit 40A is encapsulated in an insulating material. In some embodiments, an insulating encapsulation material (not shown) is formed on the stacking unit 40A and the release layer 56 over the carrier substrate 54, where the stacking unit 40A and the release layer 56 exposed by the stacking unit 40A are completely covered by the insulating encapsulation material. The insulating encapsulation material may be made of a dielectric material (such as an oxide (e.g., silicon oxide), a nitride (e.g., silicon nitride), tetra-ethyl-ortho-silicate (TEOS), or the like) or any suitable insulating materials for gap fill, and may be formed by deposition (such as a CVD process). Alternatively, the insulating encapsulation material may be a molding compound, a molding underfill, a resin (such as epoxy-based resin), or the like, which may be formed by a molding process. The molding process may include a compression molding process or a transfer molding process. The insulating encapsulation material may include polymers (such as epoxy resins, phenolic resins, silicon-containing resins, or other suitable resins) or other suitable materials. Alternatively, the insulating encapsulation material may include an acceptable insulating encapsulation material. In some embodiments, the insulating encapsulation material further includes inorganic filler or inorganic compound (e.g., silica, clay, and so on) which can be added therein to optimize coefficient of thermal expansion (CTE) of the insulating encapsulation material. The disclosure is not limited thereto.

After forming the insulating encapsulation material, a planarization process is performed on the insulating encapsulation material to form an insulating encapsulation 1900 exposing the stacking unit 40A. For example, a portion of the insulating encapsulation material is removed to form the insulating encapsulation 1900 having a surface S1900b, where the surface S1900b of the insulating encapsulation 1900 accessibly reveals the first tier T1 (e.g., a surface S202A of the semiconductor substrate 202 and the surface S1001 of the through vias 1001 exposed by the surface S202A, included in the first tier T1 of the semiconductor die 10). For example, the surface S1900b of the insulating encapsulation 1900 is substantially level with the surface S202A of the semiconductor substrate 202 and the surface S1001 of the through vias 1001 included in the first tier T1 of the stacking unit 40A. In other words, the surface S1900b of the insulating encapsulation 1900 is substantially coplanar to the surface S202A of the semiconductor substrate 202 and the surface S1001 of the through vias 1001 included in the first tier T1 of the stacking unit 40A.

In some embodiments, after the planarization process, a cleaning step may be optionally performed to clean and remove the residue generated from the planarization process. However, the disclosure is not limited thereto, and the planarization process may be performed through any other suitable method. In addition, during the planarization process, a portion of each of the semiconductor substrate 202 and the through vias 1001 in the first tier T1 of the stacking unit 40A may also be slightly removed. The disclosure is not limited thereto. As shown in FIG. 40, the stacking unit 40A may be laterally encapsulated in the insulating encapsulation 1900.

Still referring to FIG. 40, in some embodiments, after the formation of the insulating encapsulation 1900, an interconnect 1500, a dielectric layer 1600, a dielectric layer 1700 and a plurality of conductive terminals 1800 are sequentially formed over the insulating encapsulation 1900 and the stacking unit 40A laterally encapsulated in the insulating encapsulation 1900. The details, formations and materials of the interconnect 1500, the dielectric layer 1600, the dielectric layer 1700 and the plurality of conductive terminals 1800 have been discussed in FIG. 19, and thus are not repeated herein for brevity.

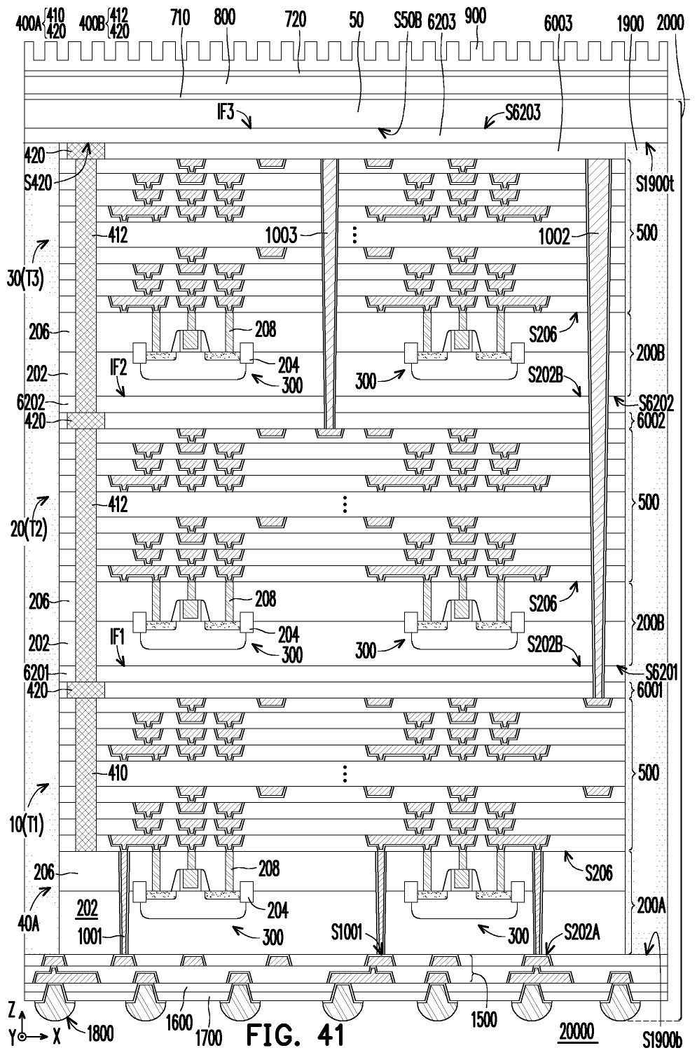

Referring to FIG. 41, in some embodiments, the carrier substrate 54 is removed. The carrier substrate 54 may be detached (or “de-bonded”) from the insulating encapsulation 1900 and the stacking unit 40A laterally encapsulated in the insulating encapsulation 1900. In some embodiments, the de-bonding includes projecting a light such as a laser light or an UV light on the release layer 56 so that the release layer 56 decomposes under the heat of the light and the carrier substrate 54 can be removed. The de-bonding accessibly exposes the insulating encapsulation 1900 (e.g., a surface S1900t opposing to the surface S1900b in the direction Z) and the stacking unit 40A (e.g., the surface S420 of the thermal control portion 420 and the illustrated top surface S6003 of the dielectric layer 6003 in the third tier T3) laterally encapsulated in the insulating encapsulation 1900, for example.

In some embodiments, after removing the carrier substrate 54 and release layer 56, a bonding layer 6203 and a carrier 50 are sequentially formed over the insulating encapsulation 1900 and the stacking unit 40A laterally encapsulated in the insulating encapsulation 1900. The bonding layer 6203 continuously extends from the stacking unit 40A to the insulating encapsulation 1900, and the carrier 50 completely covers the bonding layer 6203, for example. As shown in FIG. 41, the carrier 50 may be bonded to the surface S6203 of the bonding layer 6203 by the bonding interface IF3. The details, formation and material of the bonding layer 6203 have been discussed in FIG. 16, the details, formation and material of the carrier 50 have been discussed in FIG. 17, and thus are not repeated herein for brevity.

Still referring to FIG. 41, a dicing (singulation) process is performed to cut through the carrier 50, the bonding layer 6203, the insulating encapsulation 1900, the redistribution circuit structure 1500, the dielectric layer 1600 and the dielectric layer 1700 to form a plurality of stacking units 2000. In FIG. 41, only one stacking unit 2000 is shown for illustrative purposes and simplicity. The stacking units 2000 each may include the carrier 50, the stacking unit 40A (including a semiconductor die 30 in the third tier T3 disposed over and thermally coupled to the carrier 50, a semiconductor die 20 in the second tier T2 disposed over and electrically coupled to the semiconductor die 30 in the third tier T3, a semiconductor die 10 in the first tier T1 disposed over and electrically coupled to the semiconductor die 20 in the second tier T2), the insulating encapsulation 1900 laterally encapsulating the stacking unit 40A, the redistribution circuit structure 1500 disposed on and electrically coupled to the stacking unit 40A and extending onto the insulating encapsulation 1900, the dielectric layer 1600 disposed on the redistribution circuit structure 1500, the dielectric layer 1700 disposed on the dielectric layer 1600, and the conductive terminals 1800 disposed over and electrically coupled to the redistribution circuit structure 1500 through the dielectric layers 1600 and 1700. For example, in the stacking unit 2000, a sidewall of the carrier 50, a sidewall of the insulating encapsulation 1900, a sidewall of the redistribution circuit structure 1500, a sidewall of the dielectric layer 1600, and a sidewall of the dielectric layer 1700 are aligned to each other. That is, the sidewall of the carrier 50, the sidewall of the insulating encapsulation 1900, the sidewall of the redistribution circuit structure 1500, the sidewall of the dielectric layer 1600, and the sidewall of the dielectric layer 1700 are together constitute a sidewall of the stacking unit 2000. In one embodiment, the dicing (singulation) process is a wafer dicing process including mechanical blade sawing or laser cutting. The disclosure is not limited thereto.

Thereafter, a heat dissipating module may be sequentially formed onto the carrier 50. The lid 800 is disposed on (e.g., adhered to) the carrier 50 through a thermal adhesive 710 there-between, and the heat sink 900 is disposed on (e.g., adhered to) the lid 800 through a thermal adhesive 720 there-between, for example. The details, formations and materials of the thermal adhesive 710, the lid 800, the thermal adhesive 720 and the heat sink 900 have been discussed in FIG. 21; and thus, are not repeated herein for brevity. Up to there, the semiconductor device 20000 is manufactured. For example, in the semiconductor device 20000, a sidewall of the heat sink 900, a sidewall of the thermal adhesive 720, a sidewall of the lid 800, a sidewall of the thermal adhesive 710, and a sidewall of the stacking unit 2000 are aligned to each other. That is, the sidewall of the heat sink 900, the sidewall of the thermal adhesive 720, the sidewall of the lid 800, the sidewall of the thermal adhesive 710, and the sidewall of the stacking unit 2000 are together constitute a sidewall of the semiconductor device 20000. In one embodiment, the dicing (singulation) process is a wafer dicing process including mechanical blade sawing or laser cutting. The disclosure is not limited thereto. However, the disclosure is not limited thereto, in alternative embodiments, the sidewall of the heat sink 900, the sidewall of the thermal adhesive 720, the sidewall of the lid 800, and/or the sidewall of the thermal adhesive 710 are not aligned with the sidewall of the stacking unit 2000.

In some embodiments, the semiconductor device 30000 of FIG. 42 is similar to the semiconductor device 20000 of FIG. 41, and the difference is that the stacking unit 40A is replaced with a stacking unit 40B. As shown in FIG. 42, the stacking unit 40B may include a semiconductor die 30 in the third tier T3, a semiconductor die 20 in the second tier T2 disposed over and electrically coupled to the semiconductor die 30 in the third tier T3, a semiconductor die 10 in the first tier T1 disposed over and electrically coupled to the semiconductor die 20 in the second tier T2, and an insulating encapsulation 1910 laterally encapsulating the semiconductor dies 10 and 20. For example, in the stacking unit 40B, a sidewall of the insulating encapsulation 1910 and a sidewall of the semiconductor die 30 are aligned to each other. That is, the sidewall of the insulating encapsulation 1910 and the sidewall of the semiconductor die 30 are together constitute a sidewall of the stacking unit 40B. In one non-limiting example, at least one through via 1002 penetrates through the semiconductor dies 20 and 30 and further extending into the semiconductor die 10 to be in (e.g., physical) contact with the semiconductor dies 10, 20 and 30 for providing proper electrical connection between the semiconductor dies 10, 20 and 30, and at least one through via 1003 penetrates through the semiconductor die 30 and further extending into the semiconductor die 20 to be in (e.g., physical) contact with the semiconductor dies 20 and 30 for providing proper electrical connection between the semiconductor dies 20 and 30, as shown in FIG. 42.

The stacking unit 40B may be formed by, but not limited to, providing a circuit wafer W1′ (similar to the processes of FIGS. 1-2); forming a thermal control element 400A in the circuit wafer W1′ (similar to processes of FIGS. 3-9); forming the bonding layer 6201 to form a circuit wafer W1 (similar to the process of FIG. 10); providing a circuit wafer W2′ (similar to the process of FIG. 11); bonding the circuit wafer W2′ to the circuit structure W1 (similar to the process of FIG. 12); forming a thermal control element 400B in the circuit wafer W2′ and forming a bonding layer 6202 over the thermal control element 400B to form a circuit wafer W2 (similar to process of FIG. 13); performing a dicing process on the bonded structure of the circuit wafer W1 and the circuit wafer W2 to form a plurality of separate and individual bonded structures of semiconductor dies 10 and 20 (similar to the process of FIG. 20 or FIG. 37); providing a circuit wafer W3 with a thermal control element 400B (similar to the processes of FIGS. 14-16); bonding the bonded structure of the semiconductor dies 10 and 20 to the circuit wafer W3 by a chip-on-wafer (CoW) process; laterally encapsulating the bonded structure of the semiconductor dies 10 and 20 in the insulating encapsulation 1910 (similar to the process of FIG. 40); and performing another dicing process on the insulating encapsulation 1910 and the circuit wafer W3 to form a plurality of separate and individual stacking units 40B (similar to the process of FIG. 16 or FIG. 39). The providing the circuit wafer W3 with the thermal control element 400B may include forming a vertical portion of the thermal control element 400B (similar to the process of FIG. 14), forming at least one through via 1002 and at least one through via 1003 (similar to the process of FIG. 15), and forming a horizontal portion of the thermal control element 400B (similar to the process of FIG. 16). The formation and material of the insulating encapsulation 1910 is similar to or substantially identical to the formation and material of the insulating encapsulation 1900 as previously discussed, and thus are not repeated herein.

In some embodiments, the semiconductor device 40000 of FIG. 43 is similar to the semiconductor device 20000 of FIG. 41, and the difference is that the stacking unit 40A is replaced with a stacking unit 40C. As shown in FIG. 43, the stacking unit 40C may include a semiconductor die 30 in the third tier T3, a semiconductor die 20 in the second tier T2 disposed over and electrically coupled to the semiconductor die 30 in the third tier T3, a semiconductor die 10 in the first tier T1 disposed over and electrically coupled to the semiconductor die 20 in the second tier T2, an insulating encapsulation 1910 laterally encapsulating the semiconductor die 10, and an insulating encapsulation 1920 laterally encapsulating the semiconductor die 20 and the insulating encapsulation 1910. For example, in the stacking unit 40C, a sidewall of the insulating encapsulation 1920 and a sidewall of the semiconductor die 30 are aligned to each other. That is, the sidewall of the insulating encapsulation 1920 and the sidewall of the semiconductor die 30 are together constitute a sidewall of the stacking unit 40C. In one non-limiting example, at least one through via 1002 penetrates through the semiconductor dies 20 and 30 and further extending into the semiconductor die 10 to be in (e.g., physical) contact with the semiconductor dies 10, 20 and 30 for providing proper electrical connection between the semiconductor dies 10, 20 and 30, and at least one through via 1003 penetrates through the semiconductor die 30 and further extending into the semiconductor die 20 to be in (e.g., physical) contact with the semiconductor dies 20 and 30 for providing proper electrical connection between the semiconductor dies 20 and 30, as shown in FIG. 43.

The stacking unit 40C may be formed by, but not limited to, providing a circuit wafer W1′ (similar to the processes of FIGS. 1-2); forming a thermal control element 400A in the circuit wafer W1′ (similar to processes of FIGS. 3-9); forming the bonding layer 6201 to form a circuit wafer W1 (similar to the process of FIG. 10); performing a dicing process on the circuit wafer W1 to form a plurality of separate and individual semiconductor dies 10 (similar to the process of FIG. 20 or FIG. 37); providing a circuit wafer W2′ (similar to the process of FIG. 11); bonding at least one semiconductor die 10 to the circuit wafer W2′ by CoW bonding; laterally encapsulating the at least one semiconductor die 10 in the insulating encapsulation 1910 (similar to the process of FIG. 40); forming a thermal control element 400B in the circuit wafer W2′ and forming a bonding layer 6202 over the thermal control element 400B to form a circuit wafer W2 (similar to process of FIG. 13); performing a dicing process on the bonded structure of the at least one semiconductor die 10 and the circuit wafer W2 to form a plurality of separate and individual bonded structures of semiconductor dies 10 and 20 (similar to the process of FIG. 20 or FIG. 37); providing a circuit wafer W3 with a thermal control element 400B (similar to the processes of FIGS. 14-16); bonding the bonded structure of the semiconductor dies 10 and 20 to the circuit wafer W3 by a CoW process; laterally encapsulating the bonded structure of the semiconductor dies 10 and 20 in the insulating encapsulation 1920 (similar to the process of FIG. 40); and performing another dicing process on the insulating encapsulation 1920 and the circuit wafer W3 to form a plurality of separate and individual stacking units 40C (similar to the process of FIG. 16 or FIG. 39). The providing the circuit wafer W3 with the thermal control element 400B may include forming a vertical portion of the thermal control element 400B (similar to the process of FIG. 14), forming at least one through via 1002 and at least one through via 1003 (similar to the process of FIG. 15), and forming a horizontal portion of the thermal control element 400B (similar to the process of FIG. 16). The formation and material of the insulating encapsulation 1920 is similar to or substantially identical to the formation and material of the insulating encapsulation 1900 as previously discussed, and thus are not repeated herein.

The semiconductor devices 10000A, 10000B, 10000C, 10000D, 10000E, 10000F, 10000G, 20000, 30000, 40000, and/or modifications thereof individually may be in a die-form or a chip-form. Although in the above embodiments, only three tiers are included in each semiconductor device of the disclosure, the number of the tiers included in each semiconductor device of the disclosure may be two or more than two based on the demand and/or product design requirements/layout. In some embodiments, the thermal energy storage material 4010 and/or the thermal energy storage material 4020, individually, may be referred to a thermal energy moderating material.

In some embodiments, the semiconductor dies (10, 20 and 30) included in the semiconductor devices 10000A, 10000B, 10000C, 10000D, 10000E, 10000F, 10000G, 20000, 30000, 40000, and/or modifications thereof are referred to as semiconductor chips or integrated circuits, which independently include a digital chip, an analog chip, or a mixed signal chip. In some embodiments, the semiconductor dies (10, 20 and 30) included in the semiconductor devices 10000A, 10000B, 10000C, 10000D, 10000E, 10000F, 10000G, 20000, 30000, 40000, and/or modifications thereof are, independently, a logic die such as a central processing unit (CPU), a graphics processing unit (GPU), a neural network processing unit (NPU), a deep learning processing unit (DPU), a tensor processing unit (TPU), a system-on-a-chip (SoC), a system-on-integrated circuit (SoIC), an application processor (AP), and a microcontroller; a power management die such as a power management integrated circuit (PMIC) die; a wireless and radio frequency (RF) die; a baseband (BB) die; a sensor die such as a photo/image sensor chip; a micro-electro-mechanical-system (MEMS) die; a signal processing die such as a digital signal processing (DSP) die; a front-end die such as an analog front-end (AFE) dies; an application-specific die such as an application-specific integrated circuit (ASIC), a field-programmable gate array (FPGA); a combination thereof; or the like. In alternative embodiments, the semiconductor dies (10, 20 and 30) included in the semiconductor devices 10000A, 10000B, 10000C, 10000D, 10000E, 10000F, 10000G, 20000, 30000, 40000, and/or modifications thereof are, independently, a memory die with a controller or without a controller, where the memory die includes a single-form die such as a dynamic random access memory (DRAM) die, a static random access memory (SRAM) die, a resistive random-access memory (RRAM), a magnetoresistive random-access memory (MRAM), a NAND flash memory, or a wide I/O (WIO) memory; a pre-stacked memory cube such as a hybrid memory cube (HMC) module, a high bandwidth memory (HBM) module; a combination thereof; or the like. In further alternative embodiments, the semiconductor dies (10, 20 and 30) included in the semiconductor devices 10000A, 10000B, 10000C, 10000D, 10000E, 10000F, 10000G, 20000, 30000, 40000, and/or modifications thereof are, independently, an artificial intelligence (AI) engine such as an AI accelerator; a computing system such as an AI server, a high-performance computing (HPC) system, a high power computing device, a cloud computing system, a networking system, an edge computing system, a immersive memory computing system (ImMC), a SoIC system, etc.; a combination thereof; or the like. In some other embodiments, the semiconductor dies (10, 20 and 30) included in the semiconductor devices 10000A, 10000B, 10000C, 10000D, 10000E, 10000F, 10000G, 20000, 30000, 40000, and/or modifications thereof are, independently, an electrical and/or optical input/output (I/O) interface die, an integrated passives die (IPD), a voltage regulator die (VR), a local silicon interconnect die (LSI) with or without deep trench capacitor (DTC) features, a local silicon interconnect die with multi-tier functions such as electrical and/or optical network circuit interfaces, IPD, VR, DTC, or the like.

The types of the semiconductor dies (10, 20 and 30) included in the semiconductor devices 10000A, 10000B, 10000C, 10000D, 10000E, 10000F, 10000G, 20000, 30000, 40000, and/or modifications thereof may be selected and designated based on the demand and/or product design requirements/layout, and thus are not specifically limited in the disclosure. In the disclosure, as long as hotspot(s) of the semiconductor device are thermally coupled to (e.g., physically near to) thermal control elements (e.g., 400A, 400B, 400C, 400D, 400E, and/or 400F), the heat spikes in the semiconductor device of the disclosure can be alleviated, thereby improving the reliability of the semiconductor device of the disclosure. For example, in the semiconductor device 10000E of FIG. 25 and the semiconductor device 10000G of FIG. 27, the semiconductor dies 10 and 20 are or include memory dies or low-power logic dies and the semiconductor die 30 is or includes a high-power logic die, therefore the first tier T1 and the second tier T2 can be free of thermal control elements. For other examples, in the semiconductor devices 10000A (FIG. 21), 1000B (FIG. 22), 10000C (FIG. 23), 10000D (FIG. 24) and 10000F (FIG. 26), the semiconductor dies 10, 20 and 30 are or include a high-power logic die, therefore each tier can include one or more thermal control elements. For a non-limiting example, in a semiconductor device of the disclosure, at least one of the semiconductor dies 10, 20 and 30 may be or include a high-power logic die, and thus the respective tier(s) may include one or more than one thermal control element, where the rest of the tiers may be free of thermal control element.

The disclosure is not limited thereto. In the disclosure, the thermal control elements (e.g., 400A, 400B, 400C, 400D, 400E, and/or 400F), which may be in any combination(s) or taken alone of (with or without the high thermal conductive layer (e.g., 6401, 6402 and/or 6403)), can be adopted to alleviate the heat spikes in the semiconductor device of the disclosure, thereby improving the reliability of the semiconductor device of the disclosure.

The semiconductor devices 10000A, 10000B, 10000C, 10000D, 10000E, 10000F, 10000G, 20000, 30000, 40000, and/or modifications thereof individually may be further mounted onto another electronical component or onto a circuit structure, such as a mother board, a package substrate, a printed circuit board (PCB), a printed wiring board, and/or other carrier that is capable of carrying integrated circuits. Or, the semiconductor devices 10000A, 10000B, 10000C, 10000D, 10000E, 10000F, 10000G, 20000, 30000, 40000, and/or modifications thereof and/or modifications thereof may be or may be part of an integrated Fan-Out (InFO) package, an InFO package having a Package-on-Package (PoP) structure, a chip-on-wafer-on-substrate (CoWoS) package, a flip chip package of an InFO package, or the like. The disclosure is not limited thereto. The conductive terminals 1800 may be referred to as connectors or terminals of the semiconductor devices 10000A, 10000B, 10000C, 10000D, 10000E, 10000F, 10000G, 20000, 30000, 40000, and/or modifications thereof and/or modifications thereof.

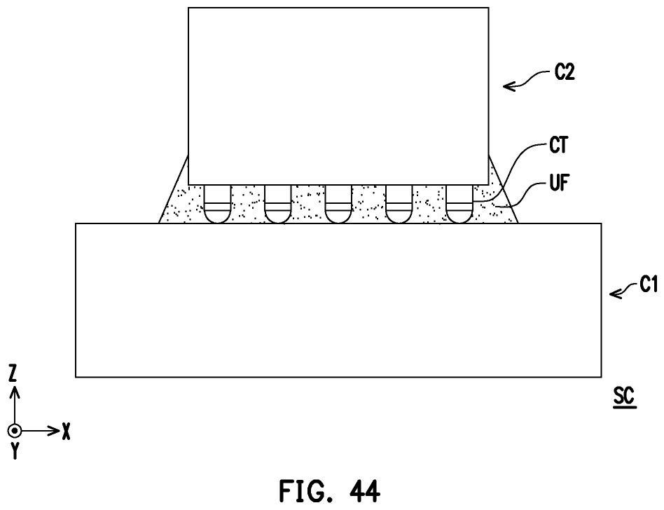

FIG. 44 is a schematic cross-sectional view showing an application of a semiconductor device (e.g., the semiconductor devices 10000A, 10000B, 10000C, 10000D, 10000E, 10000F, 10000G, 20000, 30000, 40000, and/or modifications thereof) in accordance with some embodiments of the disclosure. The elements similar to or substantially the same as the elements described previously will use the same reference numbers, and certain details or descriptions (e.g., the materials, formation processes, positioning configurations, electrical connections, etc.) of the same elements would not be repeated herein.

Referring to FIG. 44, in some embodiments, a component assembly SC including a first component C1 and a second component C2 disposed over the first component C1 is provided. The first component C1 may be or may include a circuit structure, such as a mother board, a package substrate, another PCB, a printed wiring board, and/or other carrier that is capable of carrying integrated circuits. In some embodiments, the second component C2 mounted on the first component C1 is similar to one of the semiconductor devices 10000A, 10000B, 10000C, 10000D, 10000E, 10000F, 10000G, 20000, 30000, 40000, and/or modifications thereof. For example, one or more second components C2 (e.g., 10000A, 10000B, 10000C, 10000D, 10000E, 10000F, 10000G, 20000, 30000, 40000, and/or modifications thereof) may be electrically coupled to the first component C1 through a plurality of terminals CT. The terminals CT may be the conductive terminals 1800. In some embodiments, an underfill UF is formed between the gap of the first component C1 and the second component C2 to at least laterally cover the terminals CT. Alternatively, the underfill UF is omitted. The underfill UF may be any acceptable material, such as a polymer, epoxy resin, molding underfill, or the like, for example. In one embodiment, the underfill UF may be formed by underfill dispensing, a capillary flow process, or any other suitable method. Owing to the underfill UF, a bonding strength between the first component C1 and the second component C2 is enhanced.

In accordance with some embodiments, a semiconductor device includes a semiconductor substrate, an interconnect, and at least one thermal via. The semiconductor substrate includes at least one active component. The interconnect is disposed over and electrically coupled to the at least one active component. The at least one thermal via penetrates through the interconnect and is thermally coupled to the at least one active component, where a thermal conductivity of the at least one thermal via is different than a thermal conductivity of a dielectric layer of the interconnect.

In accordance with some embodiments, a semiconductor device includes a redistribution circuit structure, a die stack, and at least one thermal control element. The die stack is disposed over and electrically coupled to the redistribution circuit structure, and includes a first tier and a second tier. The first tier includes a first substrate including at least one first active component and a first interconnect disposed over and electrically coupled to the at least one first active component. The second tier is disposed over and electrically coupled to the first tier, and includes a second substrate including at least one second active component and a second interconnect disposed over and electrically coupled to the at least one second active component. The first tier is between the second tier and the redistribution circuit structure. The at least one thermal control element is disposed over the redistribution circuit structure and thermally coupled to the die stack, and includes at least one thermal via vertically extending inside the die stack, where a thermal conductivity of the at least one thermal via is different than a thermal conductivity of dielectric layers of the first interconnect and the second interconnect.

In accordance with some embodiments, a method of manufacturing a semiconductor device includes the following steps: providing a semiconductor substrate including at least one active component; forming an interconnect disposed over the semiconductor substrate, the interconnect being electrically coupled to the at least one active component; patterning the interconnect to form an opening penetrating through the interconnect; and forming a thermal via in the opening, the thermal via being thermally coupled to the at least one active component and penetrating through the interconnect, where a thermal conductivity of the thermal via is different than a thermal conductivity of a dielectric layer of the interconnect.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A semiconductor device, comprising:
a semiconductor substrate, comprising at least one active component;
an interconnect, disposed over and electrically coupled to the at least one active component; and
at least one thermal via, penetrating through the interconnect and thermally coupled to the at least one active component, wherein a thermal conductivity of the at least one thermal via is different than a thermal conductivity of a dielectric layer of the interconnect.

2. The semiconductor device of claim 1, wherein the at least one thermal via comprises a core portion, and a material of the core portion comprises a solid-solid phase change material.

3. The semiconductor device of claim 2, wherein the at least one thermal via further comprises a shell portion surrounding the core portion, and a material of the shell portion comprises a dielectric material of a high thermal conductivity and is different from the material of the core portion.

4. The semiconductor device of claim 2, wherein the at least one thermal via further comprises a shell portion surrounding the core portion, and a material of the shell portion comprises a conductive material of a high thermal conductivity and is different from the material of the core portion.

5. The semiconductor device of claim 1, wherein the at least one thermal via comprises a core portion and a shell portion surrounding the core portion, wherein a material of the shell portion comprises a solid-solid phase change material, and a material of the core portion comprises a dielectric material of a high thermal conductivity and is different from the material of the shell portion.

6. The semiconductor device of claim 1, wherein the at least one thermal via comprises a core portion and a shell portion surrounding the core portion, wherein a material of the shell portion comprises a solid-solid phase change material, and a material of the core portion comprises a conductive material of a high thermal conductivity and is different from the material of the shell portion.

7. The semiconductor device of claim 1, wherein the at least one thermal via comprises a core portion, and a material of the core portion comprises a metal or a metal alloy.

8. The semiconductor device of claim 1, further comprising:
at least one thermal control element, disposed next to and thermally coupled to the at least one active component, and comprising:
at least one vertical portion; and
a horizontal portion, disposed on and connected to the at least one vertical portion, wherein a material of the horizontal portion comprises a solid-solid phase change material,
wherein the horizontal portion is disposed on the interconnect, and the at least one vertical portion comprises the at least one thermal via.

9. The semiconductor device of claim 8, wherein the at least one vertical portion comprises two or more vertical portions connecting to an edge of the horizontal portion, and the horizontal portion is overlapped with the at least one active component in a cross-section of the semiconductor device along a stacking direction of the semiconductor substrate and interconnect.

10. A semiconductor device, comprising:
a redistribution circuit structure;
a die stack, disposed over and electrically coupled to the redistribution circuit structure, and comprising:
a first tier, comprising:
a first substrate, comprising at least one first active component; and
a first interconnect, disposed over and electrically coupled to the at least one first active component; and
a second tier, disposed over and electrically coupled to the first tier, and comprising:
a second substrate, comprising at least one second active component; and
a second interconnect, disposed over and electrically coupled to the at least one second active component;
wherein the first tier is between the second tier and the redistribution circuit structure, and
at least one thermal control element, disposed over the redistribution circuit structure and thermally coupled to the die stack, and comprising:
at least one thermal via, vertically extending inside the die stack, wherein a thermal conductivity of the at least one thermal via is different than a thermal conductivity of dielectric layers of the first interconnect and the second interconnect.

11. The semiconductor device of claim 10, wherein the at least one thermal via penetrates through the first interconnect, the second substrate and the second interconnect and thermally coupled to the at least one first active component and the at least one second active component.

12. The semiconductor device of claim 10, wherein the at least one thermal via comprises:
at least one first thermal via, penetrating through the first interconnect and thermally coupled to the at least one first active component; and
at least one second thermal via, penetrating through the second substrate and the second interconnect and thermally coupled to the at least one second active component.

13. The semiconductor device of claim 12, wherein the at least one first thermal via is offset from the at least one second thermal via in a cross-section of the semiconductor device along a stacking direction of the die stack and the redistribution circuit structure.

14. The semiconductor device of claim 10, wherein the at least one thermal via comprises at least one of:
two or more first thermal vias, penetrating through the first interconnect and thermally coupled to the at least one first active component, wherein the two or more first thermal vias are arranged to disposed at opposite sides of the at least one first active component in a cross-section of the semiconductor device along a stacking direction of the die stack and the redistribution circuit structure;
two or more second thermal vias, penetrating through the second interconnect and thermally coupled to the at least one second active component, wherein the two or more second thermal vias are arranged to disposed at opposite sides of the at least one second active component in a cross-section of the semiconductor device along a stacking direction of the die stack and the redistribution circuit structure; and
two or more first thermal vias penetrating through the first interconnect and thermally coupled to the at least one first active component and two or more second thermal vias penetrating through the second interconnect and thermally coupled to the at least one second active component, wherein in a cross-section of the semiconductor device along a stacking direction of the die stack and the redistribution circuit structure, the two or more first thermal vias are arranged to disposed at opposite sides of the at least one first active component, and the two or more second thermal vias are arranged to disposed at opposite sides of the at least one second active component.

15. The semiconductor device of claim 10, further comprising:
a first insulating encapsulation, laterally encapsulating the die stack and cover a portion of the redistribution circuit structure exposed by the die stack.

16. The semiconductor device of claim 15, further comprising:
a second insulating encapsulation, laterally encapsulating the first tier and the second tier of the die stack and separating the first tier and the second tier of the die stack from the first insulating encapsulation.

17. The semiconductor device of claim 10, wherein the die stack further comprises:
a third tier, disposed over the second tier and electrically coupled to the first tier and the second tier, the second tier being between the first tier and the third tier, and comprising:
a third substrate, comprising at least one third active component; and
a third interconnect, disposed over and electrically coupled to the at least one third active component,
wherein the at least one thermal via vertically extends through the third interconnect.

18. A method of manufacturing a semiconductor device, comprising:
providing a semiconductor substrate comprising at least one active component;
forming an interconnect disposed over the semiconductor substrate, the interconnect being electrically coupled to the at least one active component;
patterning the interconnect to form an opening penetrating through the interconnect; and
forming a thermal via in the opening, the thermal via being thermally coupled to the at least one active component and penetrating through the interconnect, wherein a thermal conductivity of the thermal via is different than a thermal conductivity of a dielectric layer of the interconnect.

19. The method of claim 18, wherein forming the thermal via in the opening comprising:
depositing a thermal energy storage material layer over the interconnect and filling the opening; and
performing a planarization process to remove an excess amount of the thermal energy storage material above the opening, so to form the thermal via in the opening.

20. The method of claim 18, wherein forming the thermal via in the opening comprising:
depositing a first thermal energy storage material layer over the interconnect and extending into the opening;
depositing a second thermal energy storage material layer over the first thermal energy storage material layer and filling the opening; and
performing a planarization process to remove excess amounts of the first thermal energy storage material and the second thermal energy storage material above the opening, so to form the thermal via in the opening, where the thermal via comprise a core portion of the second thermal energy storage material and a shell portion of the first thermal energy storage material, the shell portion surrounds the core portion,
wherein the first thermal energy storage material is different from the second thermal energy storage material.
